(19) United States
(12) Patent Application Publication
(10) Pub. No.: US 2025/0081430 A1
(43) Pub. Date: Mar. 6, 2025

(54) SEMICONDUCTOR MEMORY DEVICE AND METHOD OF FABRICATING THE SAME

(71) Applicant: Samsung Electronics Co., Ltd., Suwon-si (KR)

(72) Inventors: Tae Young EOM, Suwon-si (KR); Chan-Sic YOON, Suwon-si (KR); Hyung Min KO, Suwon-si (KR); Ha Lim NOH, Suwon-si (KR); Hee Cheol SHIN, Suwon-si (KR)

(21) Appl. No.: 18/740,045

(22) Filed: Jun. 11, 2024

(30) Foreign Application Priority Data
Sep. 5, 2023 (KR) 10-2023-0117460

(51) Int. Cl. H10B 12/00

(52) U.S. Cl. CPC H10B 12/315; H10B 12/0335; H10B 12/482; H10B 12/50; H10B 12/485

(57) ABSTRACT

A semiconductor memory device includes: a substrate including a cell area, a peripheral area, and a boundary area; a storage pad connected to an active area in the cell area; a capacitor including a lower electrode, a first electrode support layer supporting the lower electrode, a capacitor dielectric, and an upper electrode; a peripheral gate on the peripheral area of the substrate; first peripheral contact plugs on both sides of the peripheral gate and connected to the substrate; a first interlayer insulating layer on the storage pad and the first peripheral contact plugs; a second interlayer insulating layer on the first interlayer insulating layer; and a first insulating layer on the second interlayer insulating layer, wherein the first insulating layer extends on the boundary area of the substrate, and a height of the first insulating layer is equal to or less than a height of the first electrode support layer.

This application claims the benefit under 35 U.S.C. § 119 of Korean Patent Application No. 10-2023-0117460, filed on Sep. 5, 2023, in the Korean Intellectual Property Office, the disclosure of which is incorporated herein in its entirety by reference.

### BACKGROUND

### 1. Field

The present disclosure relates to a semiconductor memory device and a method of fabricating the same, and more particularly, to a semiconductor memory device including a plurality of intersecting wiring lines and buried contacts and a method of fabricating the semiconductor memory device.

### 2. Description of the Related Art

As semiconductor devices become more highly integrated, individual circuit patterns are becoming more miniaturized to implement more semiconductor devices in the same area. That is, as the degree of integration of semiconductor devices increases, design rules for components of the semiconductor devices are reduced.

In a highly scaled semiconductor device, a process of forming a plurality of wiring lines and a plurality of buried contacts interposed between the wiring lines is becoming increasingly complicated and difficult.

### SUMMARY

Aspects of the present disclosure provide a semiconductor memory device with improved reliability and performance.

Aspects of the present disclosure also provide a method of fabricating a semiconductor memory device with improved reliability and performance.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device including: a substrate which includes a cell area, a peripheral area defined around the cell area, and a boundary area between the cell area and the peripheral area, wherein the cell area comprises an active area defined by an element isolation layer; a storage pad connected to the active area in the cell area; a capacitor which includes a lower electrode connected to the storage pad, a first electrode support layer supporting the lower electrode, a capacitor dielectric layer extending along the lower electrode, and an upper electrode on the capacitor dielectric layer; a peripheral gate on the peripheral area of the substrate; first peripheral contact plugs on both sides of the peripheral gate, the first peripheral contact plugs being connected to the substrate; a first interlayer insulating layer on the storage pad and the first peripheral contact plugs, a first peripheral wiring line being formed in the first interlayer insulating layer; a second interlayer insulating layer on the first interlayer insulating layer, a second peripheral contact plug connected to the first peripheral wiring line being formed in the second interlayer insulating layer; and a first insulating layer on the second interlayer insulating layer, a second peripheral wiring line being formed in the first insulating layer, wherein the first insulating layer extends on the boundary area of the substrate such that a sidewall of the first insulating layer contacts the upper electrode, and a height of the first insulating layer is equal to or less than a height of the first electrode support layer.

According to another aspect of the present disclosure, there is provided a semiconductor memory device including: a substrate which includes a cell area, a peripheral area defined around the cell area, and a boundary area between the cell area and the peripheral area, wherein the cell area includes an active area defined by an element isolation layer; a storage pad connected to the active area in the cell area; a capacitor which includes a lower electrode connected to the storage pad, the lower electrode extending perpendicular to the substrate, and an electrode support structure supporting the lower electrode, wherein the electrode support structure comprises a first electrode support layer and a second electrode support layer on the first electrode support layer; a peripheral gate on the peripheral area of the substrate; first peripheral contact plugs on both sides of the peripheral gate, the first peripheral contact plugs being connected to the substrate; a first interlayer insulating layer on the storage pad and the first peripheral contact plugs, a first peripheral wiring line being formed in the first interlayer insulating layer; a second interlayer insulating layer on the first interlayer insulating layer, a second peripheral contact plug connected to the first peripheral wiring line being formed in the second interlayer insulating layer; a first insulating layer on the second interlayer insulating layer, a second peripheral wiring line being formed in the first insulating layer; and a third peripheral contact plug on the first insulating layer of the peripheral area, the third peripheral contact plug being connected to the second peripheral wiring line, wherein a height of the first insulating layer on the boundary area is equal to or less than a height of the first electrode support layer, a height of the first insulating layer on the peripheral area is equal to or less than the height of the first insulating layer on the boundary area, and a lower surface of the third peripheral contact plug contacts an upper surface of the first insulating layer on the peripheral area.

According to another aspect of the present disclosure, there is provided a semiconductor memory device including: a substrate which includes a cell area and a peripheral area defined around the cell area, wherein the cell area includes an active area defined by an element isolation layer; a cell isolation layer in the substrate to define the cell area; a bit line on the cell area of the substrate, the bit line including a cell conductive line and a cell line capping layer on the cell conductive line; a cell gate electrode in the cell area of the substrate, the cell gate electrode crossing the cell conductive line; a storage pad on a side surface of the bit line, the storage pad being connected to the active area in the cell area; a capacitor which includes a lower electrode connected to the storage pad, an electrode support layer supporting the lower electrode, a capacitor dielectric layer extending along a profile of the lower electrode and upper and lower surfaces of the electrode support layer, and an upper electrode on the capacitor dielectric layer; a peripheral gate on the peripheral area of the substrate; first peripheral contact plugs on both sides of the peripheral gate, the first peripheral contact plugs being connected to the substrate; a first interlayer insulating layer on the storage pad and the first peripheral contact plugs, a first peripheral wiring line being formed in the first interlayer insulating layer; a second interlayer insulating layer on the first interlayer insulating layer, a second peripheral contact plug connected to the first peripheral wiring line being formed in the second interlayer insulating layer; and a first insulating layer on the second interlayer insulating layer, a second peripheral wiring line being formed in the first insulating layer, wherein at least a portion of each of the second interlayer insulating layer and the first insulating layer extends on the cell isolation layer, wherein the electrode support layer and the first insulating layer are at the same height, and wherein each of the electrode support layer and the first insulating layer comprises carbonitride.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic layout view of a semiconductor memory device according to embodiments;

FIG. 2 is a schematic layout view of an R1 area in FIG. 1;

FIG. 3 is a schematic layout view of an R2 area in FIG. 1;

FIG. 4 is a plan view of the semiconductor memory device according to the embodiments;

FIG. 5 is a cross-sectional view taken along line A-A of FIG. 1;

FIG. 6 is a cross-sectional view taken along line B-B of FIG. 3;

FIG. 7 is a cross-sectional view taken along line C-C of FIG. 3;

FIG. 8 is a plan view of a semiconductor memory device according to embodiments;

FIG. 9 is a view of the semiconductor memory device according to the embodiments;

FIG. 10 is a view of a semiconductor memory device according to embodiments;

FIG. 11 is a view of a semiconductor memory device according to embodiments;

FIGS. 12 and 13 are views of a semiconductor memory device according to embodiments;

FIGS. 14 and 15 are views of a semiconductor memory device according to embodiments;

FIG. 16 is a layout view of a semiconductor memory device according to embodiments;

FIG. 17 is a perspective view of the semiconductor memory device according to the embodiments;

FIG. 18 is a cross-sectional view taken along lines D-D and E-E of FIG. 16;

FIG. 19 is a layout view of a semiconductor memory device according to embodiments;

FIG. 20 is a perspective view of the semiconductor memory device according to the embodiments;

FIGS. 21 through 39 are views illustrating intermediate steps of a method of fabricating a semiconductor memory device according to embodiments;

FIGS. 40 through 54 are views illustrating intermediate steps of a method of fabricating a semiconductor memory device according to embodiments;

FIGS. 55 through 75 are views illustrating intermediate steps of a method of fabricating a semiconductor memory device according to embodiments;

FIGS. 76 through 90 are views illustrating intermediate steps of a method of fabricating a semiconductor memory device according to embodiments; and

FIGS. 91 through 110 are views illustrating intermediate steps of a method of fabricating a semiconductor memory device according to embodiments.

### DETAILED DESCRIPTION

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

An element described as “on” another element may be above and in contact with the other element, or the element may be above the other element with intervening elements therebetween.

The various pads described herein may be connected to internal circuitry within the device to which they are connected, and may transmit signals and/or supply voltages to and/or from the device to which they are attached. For example, substrate pads disposed on the package substrate may connect to rerouting and other electrical lines disposed within the package substrate, and the pads disposed on the semiconductor chips may connect to an integrated circuit of one or more of the semiconductor chips. The various pads described herein may generally have a planar surface at a location for connecting to a terminal for external communications outside of the device to which the pads are connected. The pads may be formed of a conductive material, such a metal, for example.

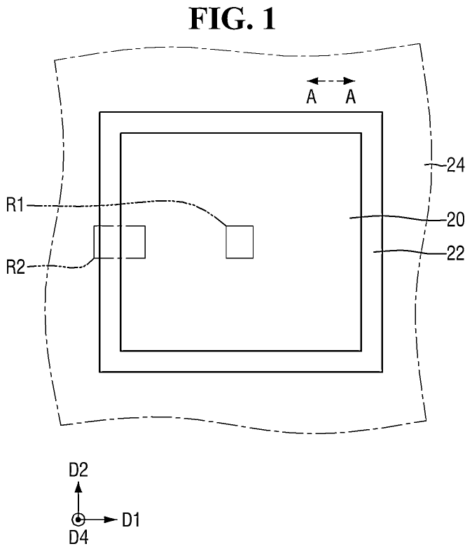

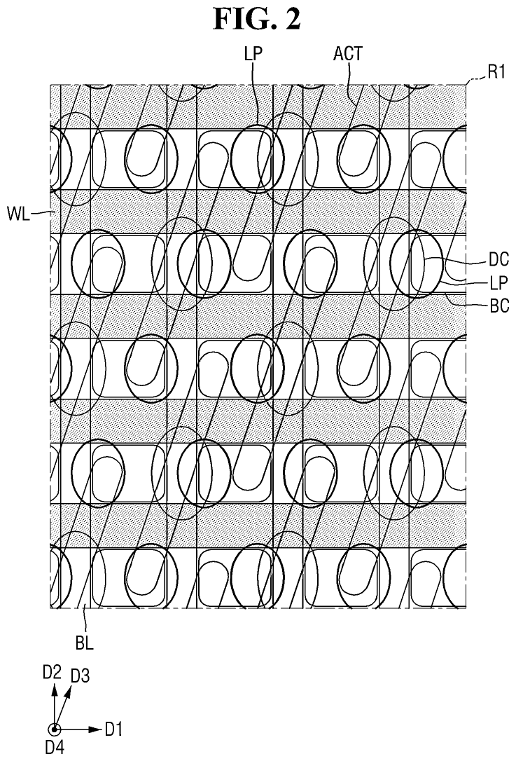

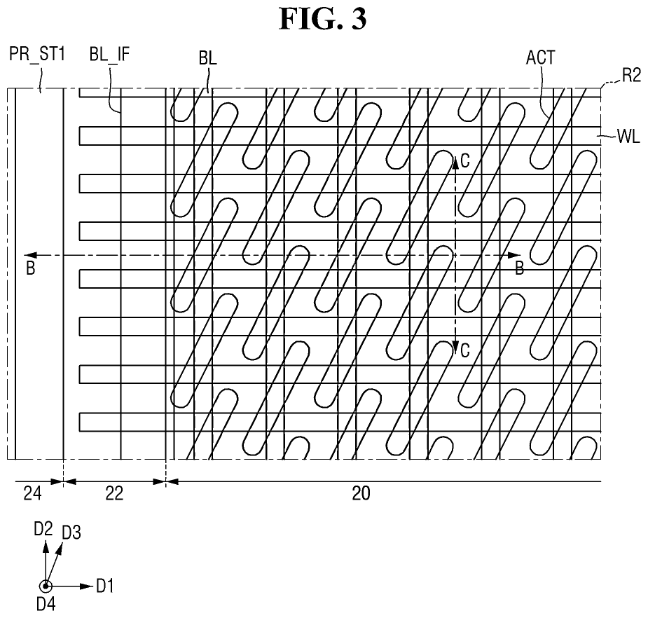

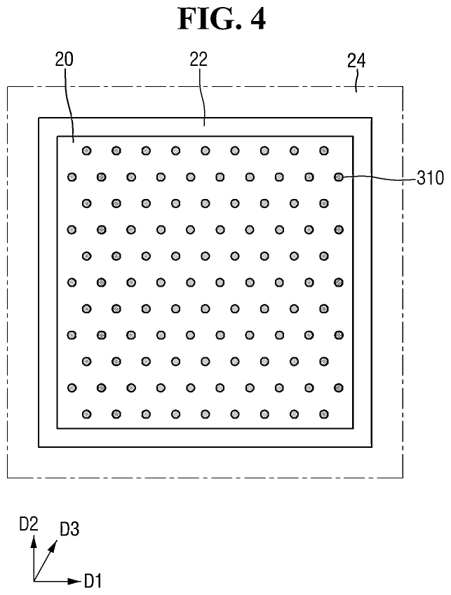

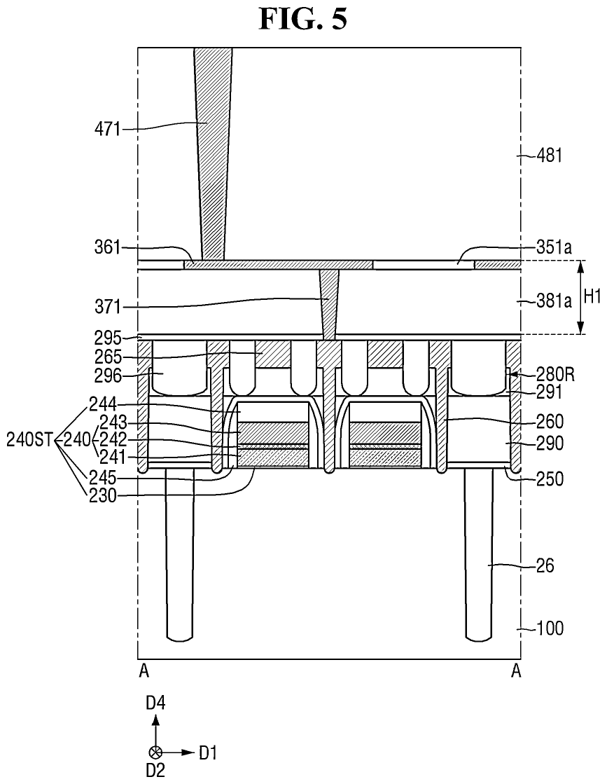

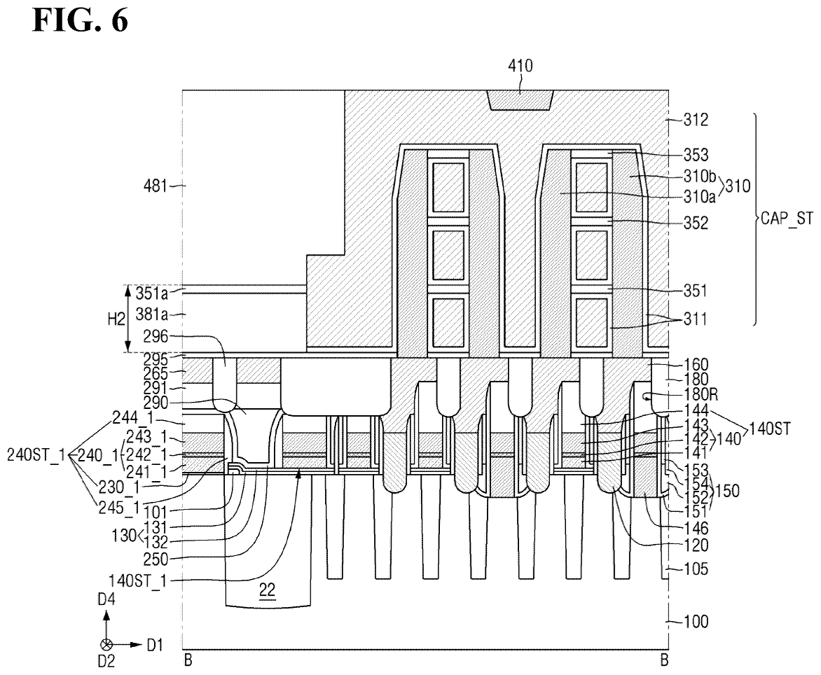

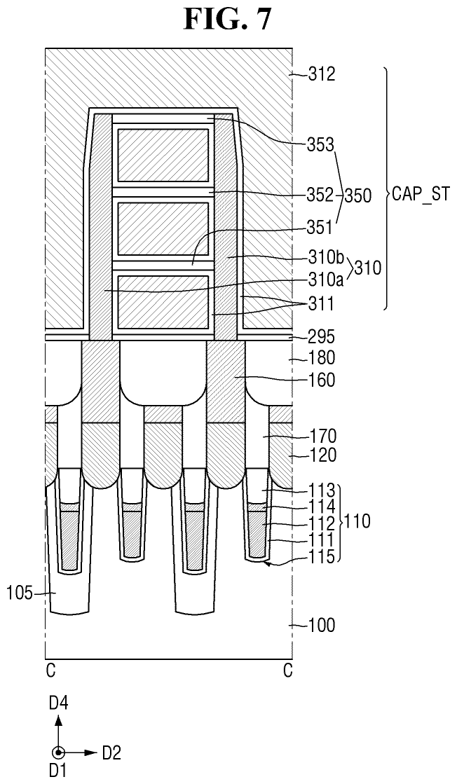

FIG. 1 is a schematic layout view of a semiconductor memory device according to embodiments. FIG. 2 is a schematic layout view of an area R1 in FIG. 1. FIG. 3 is a schematic layout view of an area R2 in FIG. 1. FIG. 4 is a plan view of the semiconductor memory device according to the embodiments. FIG. 5 is a cross-sectional view taken along line A-A of FIG. 1. FIG. 6 is a cross-sectional view taken along line B-B of FIG. 3. FIG. 7 is a cross-sectional view taken along line C-C of FIG. 3.

For reference, FIG. 5 may be an example cross-sectional view of a transistor formation area in a peripheral area 24.

Although a dynamic random access memory (DRAM) is illustrated as an example in the drawings of the semiconductor memory device according to the embodiments, the present disclosure is not limited thereto.

Referring to FIGS. 1 through 3, the semiconductor memory device according to the embodiments may include a cell area 20, a cell element isolation layer 22, and the peripheral area 24.

The cell element isolation layer 22 may be formed along the perimeter of the cell area 20. The cell element isolation layer 22 may separate the cell area 20 from the peripheral area 24. The peripheral area 24 may be defined around the cell area 20. In some embodiments, a boundary area may refer to an area on the cell element isolation layer 22 between the cell area 20 and the peripheral area 24.

The cell area 20 may include a plurality of cell active areas ACT. The cell active areas ACT may be defined by cell element isolation layers 105 (see FIGS. 6 and 7) formed in a substrate 100 (see FIGS. 5 through 7). As design rules of semiconductor memory devices are reduced, the cell active areas ACT may be disposed in the shape of diagonal or oblique bars as illustrated in the drawings. For example, the cell active areas ACT may extend in a third direction D3 oblique to first and second horizontal directions D1 and D2.

A plurality of gate electrodes may extend in a first direction D1 to cross the cell active areas ACT. The gate electrodes may extend parallel to each other. The gate electrodes may be, for example, a plurality of word lines WL. The word lines WL may be arranged at equal intervals. A width of each word line WL or a gap between the word lines WL may be determined according to the design rules.

Each of the cell active areas ACT may be divided into three parts by two word lines WL extending in the first direction D1. Each of the cell active areas ACT may include a storage connection region and a bit line connection region. The bit line connection region may be located in the middle of each cell active area ACT, and the storage connection region may be located at each end of the cell active area ACT.

A plurality of bit lines BL may be disposed on the word lines WL to extend in a second direction D2 orthogonal to the word lines WL. The bit lines BL may extend parallel to each other. The bit lines BL may be disposed at equal intervals. A width of each bit line BL or a gap between the bit lines BL may be determined according to the design rules.

A boundary bit line BL_IF may extend parallel to the bit lines BL in the second direction D2. At least a portion of the boundary bit line BL_IF may overlap the cell element isolation layer 22 in the first direction D1. Unlike in the drawings, the semiconductor memory device according to the embodiments may not include the boundary bit line BL_IF.

A boundary peripheral gate PR_ST1 may extend parallel to the boundary bit line BL_IF in the second direction D2. The boundary peripheral gate PR_ST1 may be disposed at a boundary between the cell element isolation layer 22 and the peripheral area 24. Unlike in the drawings, the boundary peripheral gate PR_ST1 of the semiconductor memory device according to the embodiments may extend in the first direction D1. In addition, the semiconductor memory device according to the embodiments may not include the boundary peripheral gate PR_ST1.

The semiconductor memory device according to the embodiments may include various contact arrays formed on the cell active areas ACT. The various contact arrays may include, for example, direct contacts DC, buried contacts BC, and landing pads LP.

Here, the direct contacts DC may be contacts that electrically connect the cell active areas ACT to the bit lines BL. The buried contacts BC may be contacts that connect the cell active areas ACT to lower electrodes 310 (see FIGS. 6 and 7) of a capacitor structure CAP_ST (see FIGS. 6 and 7). Due to the arrangement structure, a contact area between each buried contact BC and a cell active area ACT may be small. Accordingly, a conductive landing pad LP may be introduced to increase the contact area between each buried contact BC and a cell active area ACT and to increase the contact area between each buried contact BC and a lower electrode 310 (see FIGS. 6 and 7) of the capacitor structure CAP_ST (see FIGS. 6 and 7).

The landing pads LP may be disposed between the cell active areas ACT and the buried contacts BC or between the buried contacts BC and the lower electrodes 310 (see FIGS. 6 and 7) of the capacitor structure CAP_ST (see FIGS. 6 and 7). In the semiconductor memory device according to the embodiments, the landing pads LP may be disposed between the buried contacts BC and the lower electrodes 310 (see FIGS. 6 and 7) of the capacitor structure CAP_ST (see FIGS. 6 and 7). The contact area increased by the introduction of the landing pads LP may reduce the contact resistance between the active areas ACT and the lower electrodes 310 (see FIGS. 6 and 7) of the capacitor structure CAP_ST (see FIGS. 6 and 7).

Each direct contact DC may be connected to the bit line connection region. Each buried contact BC may be connected to the storage connection region. Since the buried contacts BC are disposed at both end portions of each cell active area ACT, the landing pads LP may be disposed adjacent to both ends of each active area ACT to partially overlap the buried contacts BC. In other words, each buried contact BC may be formed to overlap a cell active area ACT and a cell element isolation layer 105 (see FIGS. 6 and 7) located between adjacent word lines WL and between adjacent bit lines BL.

The word lines WL may be buried in the substrate 100. The word lines WL may cross the cell active areas ACT between the direct contacts DC or between the buried contacts BC. As illustrated in the drawings, two word lines WL may cross one cell active area ACT. Since the cell active areas ACT extend along the third direction D3, the word lines WL may be at an angle of less than 90 degrees to the active areas ACT.

The direct contacts DC and the buried contacts BC may be disposed symmetrically. Therefore, the direct contacts DC and the buried contacts BC may lie on a straight line along the first direction D1 and the second direction D2. Unlike the direct contacts DC and the buried contacts BC, the landing pads LP may be disposed in a zigzag pattern in the second direction D2 in which the bit lines BL extend. In addition, the landing pads LP may be disposed to overlap the same side of each bit line BL in the first direction D1 in which the word lines WL extend. For example, each landing pad LP in a first line extending in the first direction D1 may overlap a left side of a corresponding bit line BL, and each landing pad LP in a second line extending in the first direction D1 may overlap a right side of the corresponding bit line BL.

Referring to FIGS. 1 through 7, the semiconductor memory device according to the embodiments may include a plurality of cell gate structures 110 (e.g., cell gates), a plurality of bit line structures 140ST (e.g., bit lines), a plurality of storage pads 160, the capacitor structure CAP_ST, peripheral gate structures 240ST (e.g., peripheral gates), first peripheral contact plugs 260, a first interlayer insulating layer 296, a second interlayer insulating layer 381a, a first insulating layer 351a, and a third peripheral contact plug 471.

The substrate 100 may include the cell area 20, the cell element isolation layer 22, and the peripheral area 24. The substrate 100 may be a silicon substrate or silicon-on-insulator (SOI). Alternatively, the substrate 100 may be formed of or include, but is not limited to, silicon germanium, silicon germanium on insulator (SGOI), indium antimonide, lead telluride, indium arsenide, indium phosphide, gallium arsenide, or gallium antimonide.

The cell gate structures 110, the bit line structures 140ST, the storage pads 160, and the capacitor structure CAP_ST may be disposed in the cell area 20. The peripheral gate structures 240ST and the first peripheral contact plugs 260 may be disposed in the peripheral area 24.

The cell element isolation layers 105 may be disposed in the substrate 100 of the cell area 20. The cell element isolation layers 105 may have a shallow trench isolation (STI) structure having superior element isolation characteristics. The cell element isolation layers 105 may define the cell active areas ACT in the cell area 20. Each of the cell active areas ACT defined by the cell element isolation layers 105 may be shaped like a long island including a short axis and a long axis as illustrated, e.g., in FIG. 2. The cell active areas ACT may be oblique at an angle of less than 90 degrees with respect to the word lines WL formed in the cell element isolation layers 105. In addition, the cell active areas ACT may be oblique at an angle of less than 90 degrees with respect to the bit lines BL formed on the cell element isolation layers 105.

A cell boundary isolation layer having an STI structure may be formed in the cell element isolation layer 22. The cell area 20 may be defined by the cell element isolation layer 22.

Each of the cell element isolation layers 105 and the cell element isolation layer 22 may be formed of or include, but is not limited to, at least one of a silicon oxide layer, a silicon nitride layer, and a silicon oxynitride layer. Although each of the cell element isolation layers 105 and the cell element isolation layer 22 is formed as one insulating layer in FIGS. 6 and 7, this is only an example used for ease of description, and the present disclosure is not limited to this example. Each of the cell element isolation layers 105 and the cell element isolation layer 22 may be formed as one insulating layer or as a plurality of insulating layers depending on a width of the cell element isolation layer 105 or the cell element isolation layer 22.

In FIG. 6, upper surfaces of the cell element isolation layers 105, an upper surface of the substrate 100, and an upper surface of the cell element isolation layer 22 lie on the same plane. However, this is only an example used for ease of description, and the present disclosure is not limited to this example.

The cell gate structures 110 may be formed in the substrate 100 and the cell element isolation layers 105 (see, e.g., FIG. 7). The cell gate structures 110 may be formed to cross the cell element isolation layers 105 and the cell active areas ACT defined by the cell element isolation layers 105. Each of the cell gate structures 110 may include a cell gate trench 115 formed in the substrate 100 or a cell element isolation layer 105, a cell gate insulating layer 111, a cell gate electrode 112, a cell gate capping pattern 113, and a cell gate capping conductive layer 114. Here, the cell gate electrode 112 may correspond to a word line WL. Unlike in the drawings, each of the cell gate structures 110 may also not include the cell gate capping conductive layer 114.

The cell gate insulating layer 111 may extend along sidewalls and a bottom surface of the cell gate trench 115. The cell gate insulating layer 111 may extend along the profile of at least a portion of the cell gate trench 115. The cell gate insulating layer 111 may be formed of or include, for example, at least one of silicon oxide, silicon nitride, silicon oxynitride, and a high-k material having a higher dielectric constant than the silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be formed on the cell gate insulating layer 111. The cell gate electrode 112 may fill a portion of the cell gate trench 115. The cell gate capping conductive layer 114 may extend along an upper surface of the cell gate electrode 112.

The cell gate electrode 112 may be formed of or include include at least one of a metal, a metal alloy, a conductive metal nitride, a conductive metal carbonitride, a conductive metal carbide, a metal silicide, a doped semiconductor material, a conductive metal oxynitride, and a conductive metal oxide. The cell gate electrode 112 may include, but is not limited to, at least one of, for example, TiN, TaC, TaN, TiSiN, TaSiN, TaTiN, TiAIN, TaAIN, WN, Ru, TiAl, TiAIC-N, TiAIC, TIC, TaCN, W, Al, Cu, Co, Ti, Ta, Ni, Pt, Ni—Pt, Nb, NbN, NbC, Mo, MON, MOC, WC, Rh, Pd, Ir, Ag, Au, Zn, V, RuTiN, TiSi, TaSi, NiSi, CoSi, IrOx, RuOx, and combinations thereof. The cell gate capping conductive layer 114 may be formed of or include, but is not limited to, polysilicon or polysilicon-germanium.

The cell gate capping pattern 113 may be disposed on the cell gate electrode 112 and the cell gate capping conductive layer 114. The cell gate capping pattern 113 may fill the cell gate trench 115 remaining after the cell gate electrode 112 and the cell gate capping conductive layer 114 are formed. Although the cell gate insulating layer 111 extends along sidewalls of the cell gate capping pattern 113 in the drawings, the present disclosure is not limited thereto. The cell gate capping pattern 113 may be formed of or include, for example, at least one of silicon nitride (SiN), silicon oxynitride (SiON), silicon oxide (SiO₂), silicon carbonitride (SiCN), silicon oxycarbonitride (SiOCN), and combinations thereof.

Although not illustrated, an impurity doped region may be formed on at least one side of each of the cell gate structures 110. The impurity doped region may be a source/drain region of a transistor.

Each of the bit line structures 140ST may include a cell conductive line 140 and a cell line capping layer 144. The cell conductive line 140 may be disposed on the substrate 100 and the cell element isolation layers 105 in which the cell gate structures 110 are formed. The cell conductive line 140 may cross the cell element isolation layers 105 and the cell active areas ACT defined by the cell element isolation layers 105. The cell conductive line 140 may be formed to cross the cell gate structures 110. Here, the cell conductive line 140 may correspond to a bit line BL.

The cell conductive line 140 may be a multilayer. For example, the cell conductive line 140 may include a first cell conductive layer 141, a second cell conductive layer 142, and a third cell conductive layer 143. The first through third cell conductive layers 141 through 143 may be sequentially stacked on the substrate 100 and the cell element isolation layers 105. Although the cell conductive line 140 is illustrated as a triple layer, the present disclosure is not limited thereto.

Each of the first through third cell conductive layers 141 through 143 may include, for example, at least one of a semiconductor material doped with impurities, a conductive silicide compound, a conductive metal nitride metal, and a metal alloy. For example, the first cell conductive layer 141 may include a doped semiconductor material, the second cell conductive layer 142 may include at least one of a conductive silicide compound and a conductive metal nitride, and the third cell conductive layer 143 may include at least one of a metal and a metal alloy, but the present disclosure is not limited thereto.

A bit line contact 146 may be formed between the cell conductive line 140 and the substrate 100. That is, the cell conductive line 140 may be formed on the bit line contact 146. For example, the bit line contact 146 may be formed at a point where the cell conductive line 140 crosses a middle portion of a cell active area ACT shaped like a long island (see, e.g., the point in FIG. 3 at which the bit line BL crosses the cell active area ACT). The bit line contact 146 may be formed between the bit line connection region of the cell active area ACT and the cell conductive line 140.

The bit line contact 146 may electrically connect the cell conductive line 140 to the substrate 100. Here, the bit line contact 146 may correspond to a direct contact DC. The bit line contact 146 may include, for example, at least one of a semiconductor material doped with impurities, a conductive silicide compound, a conductive metal nitride, and a metal.

In FIG. 6, in each area overlapping an upper surface of the bit line contact 146, the cell conductive line 140 may include the second cell conductive layer 142 and the third cell conductive layer 143. In each area not overlapping the upper surface of the bit line contact 146, the cell conductive line 140 may include the first through third cell conductive layers 141 through 143.

Although the bit line contact 146 is not disposed between the cell conductive line 140 closest to the cell element isolation layer 22 and the substrate 100, the present disclosure is not limited thereto. Unlike in the drawings, the bit line contact 146 may also be disposed between the substrate 100 and the cell conductive line 140 closest to the cell element isolation layer 22.

The cell line capping layer 144 may be disposed on the cell conductive line 140. The cell line capping layer 144 may extend in the second direction D2 along an upper surface of the cell conductive line 140. Here, the cell line capping layer 144 may be formed of or include, for example, at least one of a silicon nitride layer, silicon oxynitride, silicon carbonitride, and silicon oxycarbonitride. In the semiconductor memory device according to the embodiments, the cell line capping layer 144 may include, for example, a silicon nitride layer. Although the cell line capping layer 144 is illustrated as a single layer, the present disclosure is not limited thereto. Unlike in the drawings, for example, the cell line capping layer 144 may have a double-layer structure. For another example, the cell line capping layer 144 may have a triple-layer structure. For another example, the cell line capping layer 144 may have a quadruple-layer or more structure.

A cell insulating layer 130 may be formed on the substrate 100 and the cell element isolation layers 105. More specifically, the cell insulating layer 130 may be formed on portions of the substrate 100 on which the bit line contacts 146 and storage contacts 120 are not formed and on the cell element isolation layers 105 and the cell element isolation layer 22. The cell insulating layer 130 may be formed between the substrate 100 and the cell conductive lines 140 and between the cell element isolation layers 105 and the cell conductive lines 140.

The cell insulating layer 130 may be a single layer. However, as illustrated in the drawings, the cell insulating layer 130 may also be a multilayer including a first cell insulating layer 131 and a second cell insulating layer 132. For example, the first cell insulating layer 131 may be formed of or include a silicon oxide layer, and the second cell insulating layer 132 may be formed of or include a silicon nitride layer. However, the present disclosure is not limited thereto. Unlike in the drawings, the cell insulating layer 130 may be, but is not limited to, a triple layer including a silicon oxide layer, a silicon nitride layer, and a silicon oxide layer.

A cell buffer layer 101 may be disposed between the cell insulating layer 130 and the cell element isolation layer 22. The cell buffer layer 101 may be formed of or include, but is not limited to, a silicon oxide layer.

Bit line spacers 150 may be disposed on sidewalls of the cell conductive lines 140 and the cell line capping layers 144. In portions around some cell conductive lines 140 on which the bit line contacts 146 are formed, the bit line spacers 150 may be disposed on the substrate 100 and the cell element isolation layers 105. The bit line spacers 150 may be disposed on the sidewalls of the cell conductive lines 140, the cell line capping layers 144, and the bit line contacts 146.

However, in portions around the other cell conductive lines 140 on which the bit line contacts 146 are not formed, the bit line spacers 150 may be disposed on the cell insulating layer 130.

Each of the bit line spacers 150 may be a single layer. However, as illustrated in the drawings, each of the bit line spacers 150 may also be a multilayer including first through fourth bit line spacers 151 through 154. For example, the first through fourth bit line spacers 151 through 154 may be formed of or include, but are not limited to, at least one of a silicon oxide layer, a silicon nitride layer, a silicon oxynitride layer (SiON), a silicon oxycarbonitride layer (SiOCN), air, and combinations thereof.

For example, the second bit line spacers 152 may not be disposed on the cell insulating layer 130, but may be disposed on the sidewalls of the bit line contacts 146. In FIGS. 5 and 6, the bit line structures 140ST may extend long in the second direction D2. The bit line spacers 150 may be disposed on long sidewalls extending long in the second direction D2 among the sidewalls of each bit line structure 140ST.

In FIG. 6, a dummy bit line structure 140ST_1 may be disposed on the cell element isolation layer 22. The dummy bit line structure 140ST_1 may have the same structure as the bit line structures 140ST. That is, the dummy bit line structure 140ST_1 may include a cell conductive line 140 and a cell line capping layer 144. Here, the cell conductive line 140 of the dummy bit line structure 140ST_1 may correspond to the boundary bit line BL_IF.

Fence patterns 170 may be disposed on the substrate 100 and the cell element isolation layers 105. The fence patterns 170 may overlap the cell gate structures 110 formed in the substrate 100 and the cell element isolation layers 105. Each of the fence patterns 170 may be disposed between adjacent bit line structures 140ST extending in the second direction D2. The fence patterns 170 may be formed of or include, for example, at least one of silicon oxide, silicon nitride, silicon oxynitride, and combinations thereof.

Each of the storage contacts 120 may be disposed between the cell conductive lines 140 adjacent to each other in the first direction D1. Each of the storage contacts 120 may be disposed between the fence patterns 170 adjacent to each other in the second direction D2. Each of the storage contacts 120 may overlap the substrate 100 and a cell element isolation layer 105 between adjacent cell conductive lines 140. The storage contacts 120 may be connected to the storage connection regions of the cell active areas ACT. Here, the storage contacts 120 may correspond to the buried contacts BC.

For example, the storage contacts 120 may be formed of or include at least one of a semiconductor material doped with impurities, a conductive silicide compound, a conductive metal nitride, and a metal.

The storage pads 160 may be formed on the storage contacts 120. The storage pads 160 may be electrically connected to the storage contacts 120. The storage pads 160 may be connected to the storage connection regions of the cell active areas ACT. Here, the storage pads 160 may correspond to the landing pads LP.

The storage pads 160 may partially overlap upper surfaces of the bit line structures 140ST. The storage pads 160 may be formed of or include include, for example, at least one of a semiconductor material doped with impurities, a conductive silicide compound, a conductive metal nitride, a conductive metal carbide, a metal, and a metal alloy.

A pad isolation insulating layer 180 may be disposed on the storage pads 160 and the bit line structures 140ST. For example, the pad isolation insulating layer 180 may be disposed on the cell line capping layers 144. The pad isolation insulating layer 180 may define the storage pads 160 that form a plurality of isolation regions. The pad isolation insulating layer 180 may not cover upper surfaces of the storage pads 160. The pad isolation insulating layer 180 may fill pad isolation recesses 180R. The pad isolation recesses 180R may separate adjacent storage pads 160 from each other. For example, a height of the upper surface of each storage pad 160 from the upper surface of the substrate 100 may be equal to a height of an upper surface of the pad isolation insulating layer 180 from the upper surface of the substrate 100.

The pad isolation insulating layer 180 may be formed of or include an insulating material and may electrically separate the storage pads 160 from each other. For example, the pad isolation insulating layer 180 may include, for example, at least one of a silicon oxide layer, a silicon nitride layer, a silicon oxynitride layer, a silicon oxycarbonitride layer, and a silicon carbonitride layer.

Peripheral element isolation layers 26 may be formed in the substrate 100 of the peripheral area 24. The peripheral element isolation layers 26 may define a peripheral active area in the peripheral area 24. Although upper surfaces of the peripheral element isolation layers 26 lie on the same plane as the upper surface of the substrate 100 in the drawings, the present disclosure is not limited thereto. The peripheral element isolation layers 26 may be formed of or include, but are not limited to, at least one of, for example, a silicon oxide layer, a silicon nitride layer, and a silicon oxynitride layer.

The peripheral gate structures 240ST may be disposed on the substrate 100 of the peripheral area 24. The peripheral gate structures 240ST may be disposed on the peripheral active area defined by the peripheral element isolation layers 26.

Each of the peripheral gate structures 240ST may include a peripheral gate insulating layer 230, a peripheral gate conductive layer 240, and a peripheral capping layer 244 sequentially stacked on the substrate 100. Each of the peripheral gate structures 240ST may include peripheral spacers 245 disposed on sidewalls of the peripheral gate conductive layer 240 and sidewalls of the peripheral capping layer 244.

The peripheral gate conductive layer 240 may include first through third peripheral conductive layers 241 through 243 sequentially stacked on the peripheral gate insulating layer 230. For example, no additional conductive layer may be disposed between the peripheral gate conductive layer 240 and the peripheral gate insulating layer 230. For another example, unlike in the drawings, an additional conductive layer, such as a work function conductive layer, may be disposed between the peripheral gate conductive layer 240 and the peripheral gate insulating layer 230.

Although two peripheral gate structures 240ST are disposed between adjacent peripheral element isolation layers 26 in the drawings, this is only an example used for ease of description, and the present disclosure is not limited to this example.

As shown, e.g., in FIG. 6, a block conductive structure 240ST_1 may be disposed between the cell area 20 and the peripheral area 24. Although a portion of the block conductive structure 240ST_1 overlaps the cell element isolation layer 22 in the drawings, the present disclosure is not limited thereto. The block conductive structure 240ST_1 may be a conductive structure closest to the dummy bit line structure 140ST_1 in the first direction D1.

The block conductive structure 240ST_1 may include a block gate insulating layer 230_1, a block conductive line 240_1, and a block capping layer 244_1 sequentially stacked on the substrate 100. The block conductive structure 240ST_1 may include block spacers 245_1 disposed on sidewalls of the block conductive line 240_1 and sidewalls of the block capping layer 244_1. Here, the block conductive line 240_1 may correspond to the boundary peripheral gate PR_ST1.

The block conductive line 240_1 may include first through third block conductive layers 241_1, 242_1, and 243_1 sequentially stacked on the block gate insulating layer 230_1. The stacked structure of the block conductive line 240_1 between the block gate insulating layer 230_1 and the block capping layer 244_1 may be the same as the stacked structure of each peripheral gate conductive layer 240.

The peripheral gate structures 240ST and the block conductive structure 240ST_1 may be formed at the same level. Here, the “same level” means that the elements are formed by the same fabrication process. The peripheral gate conductive layers 240 and the block conductive line 240_1 may have the same stacked structure as the cell conductive lines 140.

The first peripheral conductive layers 241 and the first block conductive layer 241_1 may be formed of or include the same material as the first cell conductive layers 141. The second peripheral conductive layers 242 and the second block conductive layer 242_1 may be formed of or include the same material as the second cell conductive layers 142. The third peripheral conductive layers 243 and the third block conductive layer 243_1 may be formed of or include the same material as the third cell conductive layers 143.

The peripheral gate insulating layers 230 and the block gate insulating layer 230_1 may be formed of or include the same material. The peripheral gate insulating layers 230 and the block gate insulating layer 230_1 may include, for example, at least one of silicon oxide, silicon nitride, silicon oxynitride, and a high-k material having a higher dielectric constant than the silicon oxide.

The peripheral spacers 245 and the block spacers 245_1 may be formed of or include the same material. The peripheral spacers 245 and the block spacers 245_1 may include, for example, at least one of silicon nitride, silicon oxynitride, silicon oxide, silicon carbonitride, silicon oxycarbonitride, and combinations thereof. Although each of the peripheral spacers 245 and the block spacers 245_1 is illustrated as a single layer, this is only an example used for ease of description, and the present disclosure is not limited to this example. Each of the peripheral spacers 245 and the block spacers 245_1 may also be a multilayer.

The peripheral capping layers 244 and the block capping layer 244_1 may be formed of or include the same material. The peripheral capping layers 244 and the block capping layer 244_1 may include, for example, at least one of silicon nitride, silicon oxynitride, and silicon oxide.

A lower etch stop layer 250 may be disposed on the substrate 100. The lower etch stop layer 250 may be formed along the profiles of the peripheral gate structures 240ST and the profile of the block conductive structure 240ST_1. The lower etch stop layer 250 may extend along sidewalls of the dummy bit line structure 140ST_1. The lower etch stop layer 250 may be formed of or include, for example, at least one of a silicon nitride layer, silicon oxynitride, silicon carbonitride, and silicon oxycarbonitride.

A lower peripheral interlayer insulating layer 290 may be disposed on the lower etch stop layer 250. The lower peripheral interlayer insulating layer 290 may be disposed around the peripheral gate structures 240ST. The lower peripheral interlayer insulating layer 290 may be disposed on the cell element isolation layer 22 between the dummy bit line structure 140ST_1 and the block conductive structure 240ST_1.

The lower peripheral interlayer insulating layer 290 may be formed of or include an oxide-based insulating material. An upper surface of the lower peripheral interlayer insulating layer 290 may lie on the same plane as an upper surface of the lower etch stop layer 250 extending along upper surfaces of the peripheral gate structures 240ST.

An upper peripheral interlayer insulating layer 291 is disposed on the peripheral gate structures 240ST and the lower peripheral interlayer insulating layer 290. The upper peripheral interlayer insulating layer 291 may cover the peripheral gate structures 240ST and the lower peripheral interlayer insulating layer 290. For example, a height of an upper surface of the upper peripheral interlayer insulating layer 291 from the upper surface of the substrate 100 may be equal to a height of the upper surface of each cell line capping layer 144 from the upper surface of the substrate 100.

The upper peripheral interlayer insulating layer 291 may be formed of or include a different material from the lower peripheral interlayer insulating layer 290. The upper peripheral interlayer insulating layer 291 may include, for example, a nitride-based insulating material. For example, the upper peripheral interlayer insulating layer 291 may include silicon nitride.

The first peripheral contact plugs 260 may be disposed on both sides of each peripheral gate structure 240ST. The first peripheral contact plugs 260 may extend through the upper peripheral interlayer insulating layer 291 and the lower peripheral interlayer insulating layer 290 to the substrate 100 of the peripheral area 24. The first peripheral contact plugs 260 are connected to the substrate 100 of the peripheral area 24. A first peripheral wiring line 265 may be disposed on the upper peripheral interlayer insulating layer 291. The first peripheral contact plugs 260 and the first peripheral wiring line 265 may be separated by wiring isolation recesses 280R. The wiring isolation recesses 280R may have various widths.

The first peripheral contact plugs 260 and the first peripheral wiring line 265 may be formed of or include the same material as the storage pads 160. The first peripheral contact plugs 260 and the first peripheral wiring line 265 may be formed at the same level as the storage pads 160.

Upper surfaces of the first peripheral contact plugs 260 may lie on the same plane as an upper surface of the first peripheral wiring line 265. The upper surface of the first peripheral wiring line 265 may lie on the same plane as the upper surfaces of the storage pads 160.

The first interlayer insulating layer 296 may be disposed over the cell area 20 and the peripheral area 24. The first interlayer insulating layer 296 may be disposed on the storage pads 160, the first peripheral contact plugs 260, and the first peripheral wiring line 265. The first interlayer insulating layer 296 may be disposed on the upper peripheral interlayer insulating layer 291.

An upper etch stop layer 295 may be provided on the first interlayer insulating layer 296. The upper etch stop layer 295 may extend along an upper surface of the first interlayer insulating layer 296, the upper surface of the first peripheral wiring line 265, the upper surface of the pad isolation insulating layer 180, and the upper surfaces of the storage pads 160. The upper etch stop layer 295 may be formed of or include at least one of a silicon nitride layer, silicon oxynitride, silicon carbonitride, and silicon oxycarbonitride.

The first interlayer insulating layer 296 may fill the wiring isolation recesses 280R. In FIG. 5, the first interlayer insulating layer 296 may entirely fill the wiring isolation recesses 280R.

The first interlayer insulating layer 296 may be formed of or include a nitride-based insulating material. The first interlayer insulating layer 296 may include, for example, at least one of silicon nitride, silicon carbonitride, silicon oxycarbonitride, and silicon boron nitride (SiBN).

The lower electrodes 310 may be disposed on the substrate 100. The lower electrodes 310 may be disposed on the storage pads 160. The lower electrodes 310 may be connected to the storage pads 160.

For example, each of the lower electrodes 310 may have a pillar shape. The lower electrodes 310 may extend long in a thickness direction of the substrate 100, that is, in a vertical direction D4 as shown, e.g., in FIGS. 6 and 7. A length by which the lower electrodes 310 extend in the thickness direction of the substrate 100 may be longer than a length by which the lower electrodes 310 extend in horizontal directions D1 through D3 parallel to the substrate 100.

For example, the lower electrodes 310 may be repeatedly aligned along the first direction D1 and the second direction D2. The first direction D1 and the second direction D2 may be orthogonal to each other, but the present disclosure is not limited thereto. The lower electrodes 310 repeatedly aligned in the first direction D1 may also be repeatedly aligned in the second direction D2. The lower electrodes 310 repeatedly aligned in the second direction D2 may not be linearly arranged along the second direction D2. The lower electrodes 310 repeatedly aligned in the second direction D2 may be arranged in a zigzag pattern. The lower electrodes 310 may be linearly arranged along the third direction D3.

The lower electrodes 310 may be formed of or include, but are not limited to, a doped semiconductor material, a conductive metal nitride (e.g., titanium nitride, tantalum nitride, niobium nitride or tungsten nitride), a metal (e.g., ruthenium, iridium, titanium or tantalum), or a conductive metal oxide (e.g., iridium oxide or niobium oxide). In the semiconductor device according to the embodiments, the lower electrodes 310 may include titanium nitride (TiN). Alternatively, in the semiconductor device according to the embodiments, the lower electrodes 310 may include niobium nitride (NbN).

The lower electrodes 310 may include first lower electrodes 310a and second lower electrodes 310b disposed on the storage pads 160, respectively. The first lower electrodes 310a and the second lower electrodes 310b may be spaced apart from each other. For example, a capacitor dielectric layer 311 and an upper electrode 312 may be disposed between a first lower electrode 310a and a second lower electrode 310b. For another example, the capacitor dielectric layer 311, an electrode support structure 350, and the upper electrode 312 may be disposed between a first lower electrode 310a and a second lower electrode 310b.

The electrode support structure 350 may include a first support layer 351, a second support layer 352, and a third support layer 353. In some embodiments, the number of support layers included in the electrode support structure 350 is three, but the present disclosure is not limited thereto.

The first support layer 351 may be disposed on the first interlayer insulating layer 296. The first support layer 351 may be spaced apart from the first interlayer insulating layer 296 and the storage pads 160. The first support layer 351 may be disposed between the first and second lower electrodes 310a and 310b adjacent to each other. The first support layer 351 may contact the first and second lower electrodes 310a and 310b.

The second support layer 352 may be disposed on the first support layer 351. The second support layer 352 may be spaced apart from the first support layer 351. The second support layer 352 may be disposed between the first and second lower electrodes 310a and 310b adjacent to each other. The second support layer 352 may contact the first and second lower electrodes 310a and 310b.

The third support layer 353 may be disposed on the second support layer 352. The third support layer 353 may be spaced apart from the first and second support layers 351 and 352. The third support layer 353 may be disposed between the first and second lower electrodes 310a and 310b adjacent to each other. The third support layer 353 may contact the first and second lower electrodes 310a and 310b.

The electrode support structure 350 may be formed of or include an insulating material. For example, the electrode support structure 350 may include at least one of silicon nitride, silicon carbonitride, silicon boron nitride, silicon carbonate, silicon oxynitride, silicon oxide, and silicon oxycarbonitride. In some embodiments, each of the first through third support layers 351 through 353 may include silicon carbonitride (SiCN).

The capacitor dielectric layer 311 may be formed on the lower electrodes 310, the first interlayer insulating layer 296, the storage pads 160, and the first through third support layers 351 through 353. The capacitor dielectric layer 311 may extend along the profiles of the lower electrodes 310. The capacitor dielectric layer 311 may extend along upper and lower surfaces of the first support layer 351, upper and lower surfaces of the second support layer 352, and upper and lower surfaces of the third support layer 353.

The capacitor dielectric layer 311 may extend along the first interlayer insulating layer 296. Specifically, the capacitor dielectric layer 311 may extend along an upper surface of the upper etch stop layer 295 between the storage pads 160. The capacitor dielectric layer 311 may directly contact the upper surface of the upper etch stop layer 295?.

The capacitor dielectric layer 311 may be formed of or include, for example, silicon oxide, silicon nitride, silicon oxynitride, or a high-k material including metal. Although the capacitor dielectric layer 311 is illustrated as a single layer, this is only an example used for ease of description, and the present disclosure is not limited to this example.

In the semiconductor device according to the embodiments, the capacitor dielectric layer 311 may include a structure in which zirconium oxide, aluminum oxide, and zirconium oxide are sequentially stacked.

In the semiconductor device according to the embodiments, the capacitor dielectric layer 311 may include a dielectric layer including hafnium (Hf). In the semiconductor memory device according to the embodiments, the capacitor dielectric layer 311 may have a stacked structure of a ferroelectric material layer and a paraelectric material layer.

The ferroelectric material layer may have ferroelectric properties. The ferroelectric material layer may be thick enough to have ferroelectric properties. The thickness range of the ferroelectric material layer having ferroelectric properties may vary according to a ferroelectric material.

For example, the ferroelectric material layer may include a monometal oxide. The ferroelectric material layer may include a monometal oxide layer. Here, the monometal oxide may be a binary compound composed of one metal and oxygen. The ferroelectric material layer including the monometal oxide may have an orthorhombic crystal system.

In an example, the metal included in the monometal oxide layer may be hafnium (Hf). The monometal oxide layer may be a hafnium oxide (HfO) layer. Here, the hafnium oxide layer may have a chemical formula that conforms to stoichiometry or may have a chemical formula that does not conform to stoichiometry.

In another example, the metal included in the monometal oxide layer may be one of rare earth metals belonging to lanthanoids. The monometal oxide layer may be a rare earth metal oxide layer belonging to lanthanoids. Here, the rare earth metal oxide layer belonging to lanthanoids may have a chemical formula that conforms to stoichiometry or may have a chemical formula that does not conform to stoichiometry. When the ferroelectric material layer includes the monometal oxide layer, it may have a thickness of, e.g., 1 to 10 nm.

For example, the ferroelectric material layer may include a bimetal oxide. The ferroelectric material layer may include a bimetal oxide layer. Here, the bimetal oxide may be a ternary compound composed of two metals and oxygen. The ferroelectric material layer including the bimetal oxide may have an orthorhombic crystal system.

The metals included in the bimetal oxide layer may be, for example, hafnium (Hf) and zirconium (Zr). The bimetal oxide layer may be a hafnium zirconium oxide layer (HfₓZr₍₁₋ₓ₎O). In the bimetal oxide layer, x may be 0.2 to 0.8. Here, the hafnium zirconium oxide layer (HfₓZr₍₁₋ₓ₎O) may have a chemical formula that conforms to stoichiometry or may have a chemical formula that does not conform to stoichiometry.

When the ferroelectric material layer includes the bimetal oxide layer, it may have a thickness of, e.g., 1 to 20 nm.

For example, the paraelectric material layer may be, but is not limited to, a dielectric layer including zirconium (Zr) or a stacked layer including zirconium (Zr). Even if the chemical formula is the same, ferroelectric properties or paraelectric properties may be exhibited depending on the crystal structure of a dielectric material.

A paraelectric material may have a positive dielectric constant, and a ferroelectric material may have a negative dielectric constant in a specific section. That is, the paraelectric material may have a positive capacitance, and the ferroelectric material may have a negative capacitance.

Generally, when two or more capacitors having positive capacitances are connected in series, the sum of the capacitances decreases. However, when a capacitor having a negative capacitance and a capacitor having a positive capacitance are connected in series, the sum of the capacitances increases.

The upper electrode 312 may be disposed on the capacitor dielectric layer 311. The upper electrode 312 may extend along the profile of the capacitor dielectric layer 311. The upper electrode 312 may be formed of or include, but is not limited to, a doped semiconductor material, a conductive metal nitride (e.g., titanium nitride, tantalum nitride, niobium nitride or tungsten nitride), a metal (e.g., ruthenium, iridium, titanium or tantalum), or a conductive metal oxide (e.g., iridium oxide or niobium oxide). In the semiconductor device according to the embodiments, the upper electrode 312 may include titanium nitride (TiN). Alternatively, in the semiconductor device according to the embodiments, the upper electrode 312 may include niobium nitride (NbN).

The second interlayer insulating layer 381a may be disposed on the first interlayer insulating layer 296. The second interlayer insulating layer 381a extends on the cell element isolation layer 22 to contact a sidewall of the upper electrode 312. Although not specifically shown, the capacitor dielectric layer 311 may extend along a boundary between the first interlayer insulating layer 296 and the second interlayer insulating layer 381a.

A second peripheral contact plug 371 may be formed in the second interlayer insulating layer 381a (see, e.g., FIG. 5). The second peripheral contact plug 371 may extend through the second interlayer insulating layer 381a to the upper etch stop layer 295 of the peripheral area 24. The second peripheral contact plug 371 is connected to the first peripheral wiring line 265 in the peripheral area 24. A second peripheral wiring line 361 may be disposed on the second interlayer insulating layer 381a and spaced apart from other second peripheral wiring lines 361.

The first insulating layer 351a may be disposed on the second interlayer insulating layer 381a. The second peripheral wiring line 361 may be formed in the first insulating layer 351a. The first insulating layer 351a extends on the cell element isolation layer 22 to contact a sidewall of the upper electrode 312.

A third interlayer insulating layer 481 may be disposed on the first insulating layer 351a. The third interlayer insulating layer 481 extends on the substrate 100 to contact the sidewall of the upper electrode 312.

The third peripheral contact plug 471 may extend through the third interlayer insulating layer 481 to the first insulating layer 351a in the peripheral area 24. The third peripheral contact plug 471 is connected to the second peripheral wiring line 361 in the peripheral area 24.

The second interlayer insulating layer 381a and the third interlayer insulating layer 481 may be formed of or include, but are not limited to, an oxide-based insulating material.

In some embodiments, a height of the first insulating layer 351a on the cell element isolation layer 22 may be equal to or less than a height of the first support layer 351. In addition, the height of the first insulating layer 351a on the peripheral area 24 may be equal to or less than the height of the first support layer 351. Referring to FIGS. 5 and 6, the first support layer 351, the first insulating layer 351a on the cell element isolation layer 22, and the first insulating layer 351a in the peripheral area 24 may be disposed at the same height in a fourth direction D4. In other words, the first support layer 351, the first insulating layer 351a on the cell element isolation layer 22, and the first insulating layer 351a on the peripheral area 24 may be disposed at the same level in the fourth direction D4.

For example, a height H1 from the upper surface of the upper etch stop layer 295 to an upper surface of the first insulating layer 351a on the peripheral area 24 in the fourth direction D4 may be equal to a height H2 from the upper surface of the upper etch stop layer 295 to the upper surface of the first support layer 351 in the fourth direction D4.

For example, the height H1 from the upper surface of the upper etch stop layer 295 to the upper surface of the first insulating layer 351a on the peripheral area 24 in the fourth direction D4 may be equal to the height H2 from the upper surface of the upper etch stop layer 295 to the upper surface of the first insulating layer 351a on the cell element isolation layer 22 in the fourth direction D4.

In addition, in some embodiments, a height of the second peripheral wiring line 361 may be equal to or less than the height of the first support layer 351. Referring to FIGS. 5 and 6, the second peripheral wiring line 361 and the first support layer 351 may be disposed at the same height in the fourth direction D4. In other words, the second peripheral wiring line 361 and the first support layer 351 may be disposed at the same level in the fourth direction D4.

In addition, in some embodiments, a lower surface of the third peripheral contact plug 471 may be disposed on the upper surface of the first insulating layer 351a in the peripheral area 24. The lower surface of the third peripheral contact plug 471 may contact the upper surface of the first insulating layer 351a in the peripheral area 24.

The lower surface of the third peripheral contact plug 471 may be disposed at the same height as the upper surface of the first support layer 351, the upper surface of the first insulating layer 351a, and an upper surface of the second peripheral wiring line 361 in the fourth direction D4. In other words, the lower surface of the third peripheral contact plug 471 may be disposed at the same level as the upper surfaces of the first support layer 351, the upper surface of the first insulating layer 351a, and the upper surface of the second peripheral wiring line 361 in the fourth direction D4.

For example, the first support layer 351, the first insulating layer 351a on the cell element isolation layer 22, and the first insulating layer 351a on the peripheral area 24 may each be formed of or include at least one of silicon nitride, silicon carbonitride, and silicon boron nitride, silicon carbonate, silicon oxynitride, silicon oxide, and silicon oxycarbonitride. In some embodiments, the first support layer 351, the first insulating layer 351a on the cell element isolation layer 22, and the first insulating layer 351a on the peripheral area 24 may each include silicon carbonitride (SiCN).

According to some embodiments, since the first support layer 351 is used as an insulating layer of the second peripheral wiring line 361, the second peripheral wiring line 361 can be formed at the same level as the first support layer 351. Since a plurality of peripheral wiring line layers can be formed in the peripheral area 24, the difficulty of an etching process for forming the peripheral contact plug 471 can be reduced.

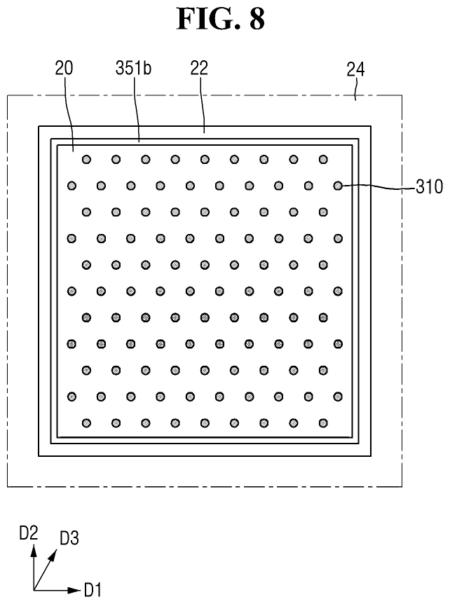

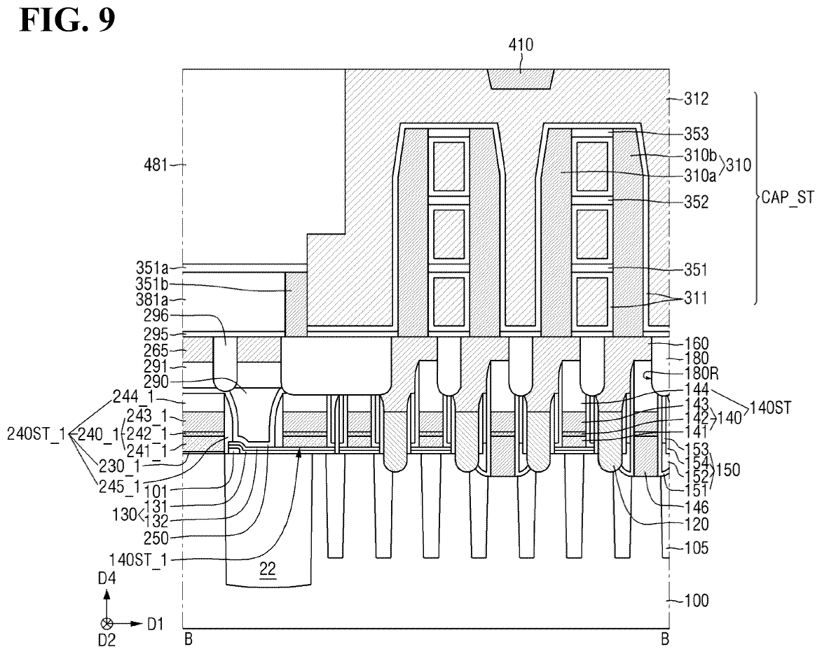

FIG. 8 is a plan view of a semiconductor memory device according to embodiments. FIG. 9 is a view of the semiconductor memory device according to the embodiments. For ease of description, the following description will focus on differences from the semiconductor memory device described above with reference to FIGS. 1 through 7.

Referring to FIGS. 8 and 9, the semiconductor memory device according to the embodiments may further include a barrier structure 351b.

The barrier structure 351b may be disposed between a cell area 20 and a peripheral area 24. The barrier structure 351b may be formed on a cell element isolation layer 22.

The barrier structure 351b may be disposed under a first insulating layer 351a. The barrier structure 351b may be disposed between a sidewall of a second interlayer insulating layer 381a and a sidewall of an upper electrode 312.

The barrier structure 351b may be formed of or include a metal material. For example, the barrier structure 351b may include, but is not limited to, tungsten (W). However, the barrier structure 351b may not be electrically connected to a first peripheral wiring line 265.

According to some embodiments, the second interlayer insulating layer 381a on the cell element isolation layer 22 may be excessively etched in a process of forming a capacitor structure CAP_ST. For example, the second interlayer insulating layer 381a, which is an oxide layer, may be excessively etched in a process of removing an oxide layer to form the upper electrode 312. However, if the barrier structure 351b is formed, the second interlayer insulating layer 381a for forming a second peripheral wiring line 361 can be protected. Consequently, the difficulty of an etching process for forming a third peripheral contact plug 471 can be reduced.

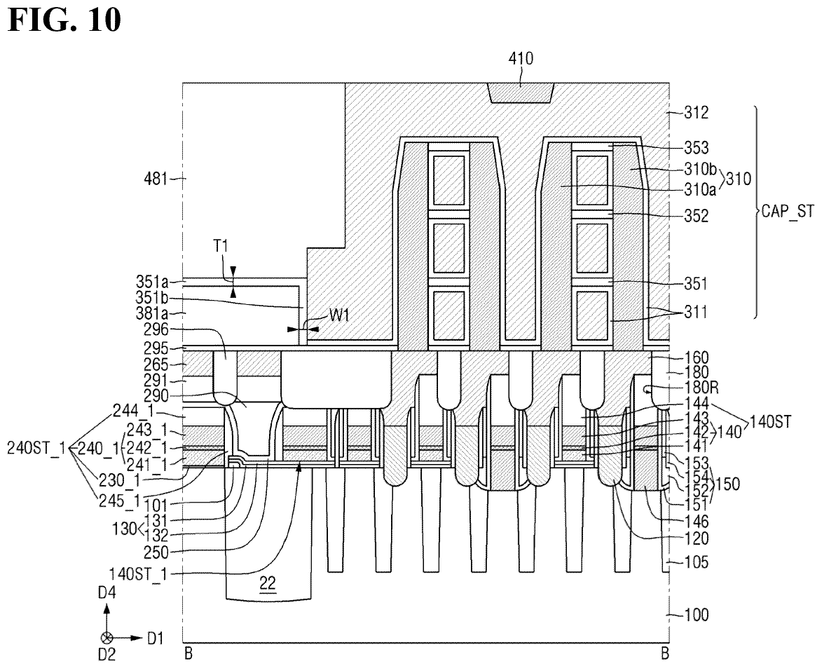

FIG. 10 is a view of a semiconductor memory device according to embodiments. For ease of description, the following description will focus on differences from the semiconductor memory devices described above with reference to FIGS. 1 through 9.

Referring to FIG. 10, the semiconductor memory device according to the embodiments may further include a barrier structure 351b.

The barrier structure 351b may be disposed between a cell area 20 and a peripheral area 24. The barrier structure 351b may be formed on a cell element isolation layer 22.

The barrier structure 351b may be disposed under a first insulating layer 351a. The barrier structure 351b may be disposed between a sidewall of a second interlayer insulating layer 381a and a sidewall of an upper electrode 312.

A width W1 of the barrier structure 351b in the first direction D1 may be substantially equal to a thickness T1 of the first insulating layer 351a on the cell element isolation layer 22 in the fourth direction D4.

The barrier structure 351b may be formed of or include an insulating material. For example, the barrier structure 351b may include the same material as the first insulating layer 351a on the cell element isolation layer 22, but the present disclosure is not limited thereto.

As used herein, two elements formed integrally with each other refer to a structure to be continuously integrated, without a discontinuous boundary surface (for example, a grain boundary), in which two elements formed by a different process are not simply in contact (discontinuity), but are formed of the same material by the same process.

The barrier structure 351b may be formed integrally with the first insulating layer 351a on the cell element isolation layer 22.

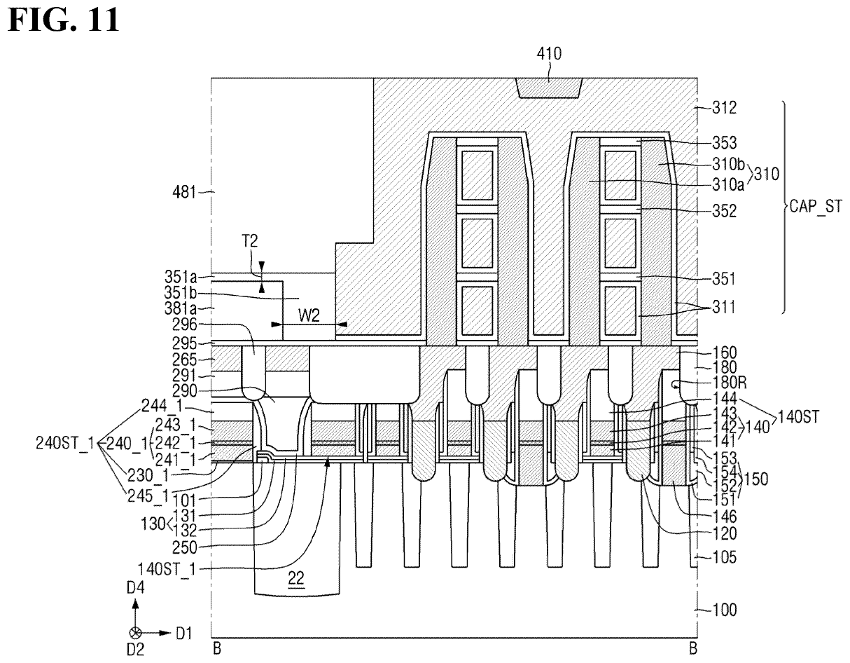

FIG. 11 is a view of a semiconductor memory device according to embodiments. For ease of description, the following description will focus on differences from the semiconductor memory devices described above with reference to FIGS. 1 through 10.

Referring to FIG. 11, the semiconductor memory device according to the embodiments may further include a barrier structure 351b.

The barrier structure 351b may be disposed between a cell area 20 and a peripheral area 24. The barrier structure 351b may be formed on a cell element isolation layer 22.

The barrier structure 351b may be disposed under a first insulating layer 351a. The barrier structure 351b may be disposed between a sidewall of a second interlayer insulating layer 381a and a sidewall of an upper electrode 312.

A width W2 of the barrier structure 351b in the first direction D1 may be greater than a thickness T2 of the first insulating layer 351a on the cell element isolation layer 22 in the fourth direction D4.

The barrier structure 351b may be formed of or include an insulating material. For example, the barrier structure 351b may include the same material as the first insulating layer 351a on the cell element isolation layer 22, but the present disclosure is not limited thereto.

The barrier structure 351b may be formed integrally with the first insulating layer 351a on the cell element isolation layer 22.

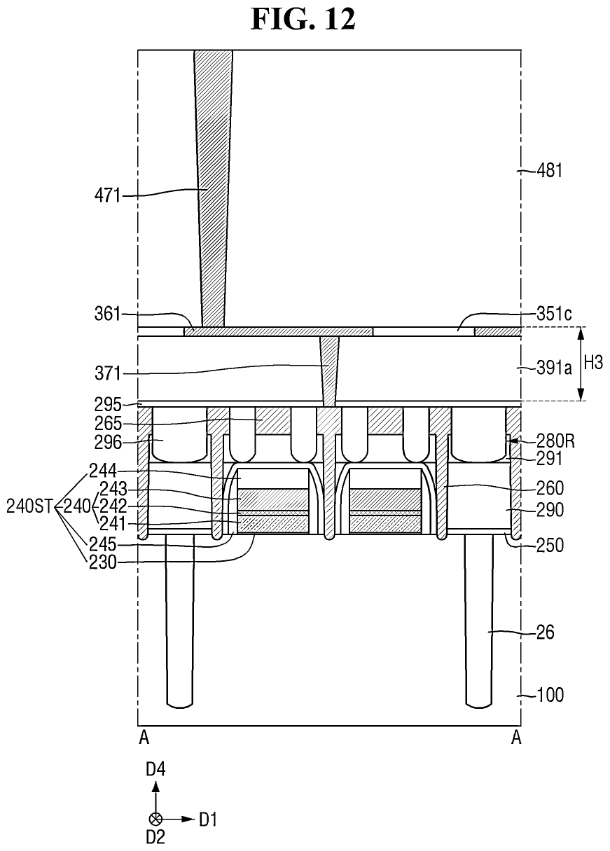

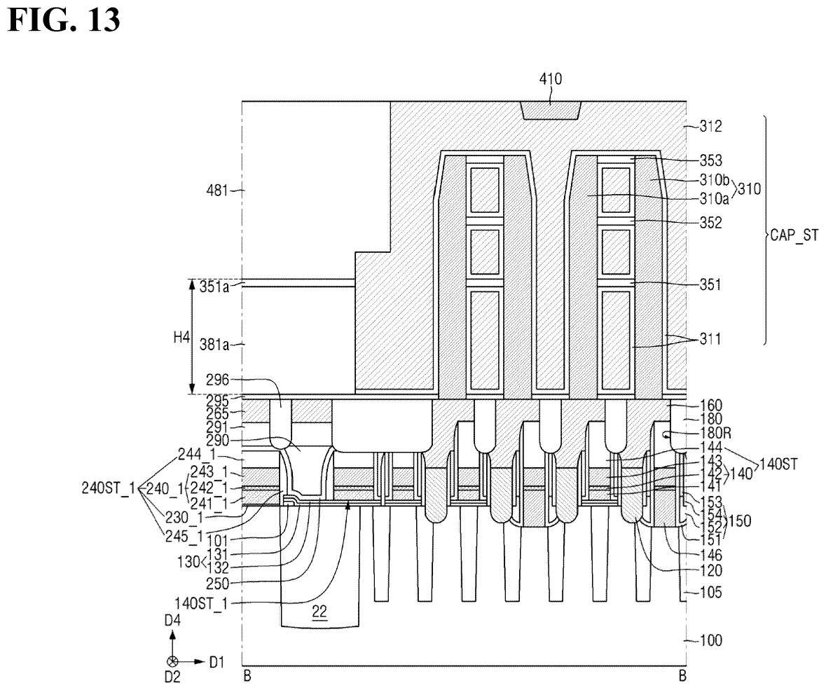

FIGS. 12 and 13 are views of a semiconductor memory device according to embodiments. For ease of description, the following description will focus on differences from the semiconductor memory devices described above with reference to FIGS. 1 through 11.

Referring to FIGS. 12 and 13, the semiconductor memory device may include an intermediate insulating layer 391a formed on an upper etch stop layer 295 in a peripheral area 24. The intermediate insulating layer 391a may not be formed on a cell area 20 and a cell element isolation layer 22.

A lower insulating layer 351c on the intermediate insulating layer 391a may be disposed at a lower height than a first support layer 351 on a second interlayer insulating layer 381a in the fourth direction D4. A second peripheral wiring line 361 may be disposed at a lower height than the first support layer 351 in the fourth direction D4.

The lower insulating layer 351c in the peripheral area 24 may be disposed at a lower height than a first insulating layer 351a on the cell element isolation layer 22.

For example, a height H3 from an upper surface of the upper etch stop layer 295 to an upper surface of the lower insulating layer 351c in the peripheral area 24 in the fourth direction D4 may be smaller than a height H4 from the upper surface of the upper etch stop layer 295 to an upper surface of the first insulating layer 351a on the cell element isolation layer 22 in the fourth direction D4.

For example, the height H3 from the upper surface of the upper etch stop layer 295 to the upper surface of the lower insulating layer 351c in the peripheral area 24 in the fourth direction D4 may be smaller than the height H4 from the upper surface of the upper etch stop layer 295 to an upper surface of the first support layer 351 in the fourth direction D4.

A lower surface of a third peripheral contact plug 471 may be disposed at a lower height than the upper surface of the first insulating layer 351a on the cell element isolation layer 22 in the fourth direction D4.

The lower insulating layer 351c in the peripheral area 24 may be formed of or include a different material from the first insulating layer 351a on the cell element isolation layer 22. For example, the lower insulating layer 351c in the peripheral area 24 may include silicon boron nitride (SiBN), and the first insulating layer 351a on the cell element isolation layer 22 may include silicon carbonitride (SiCN).

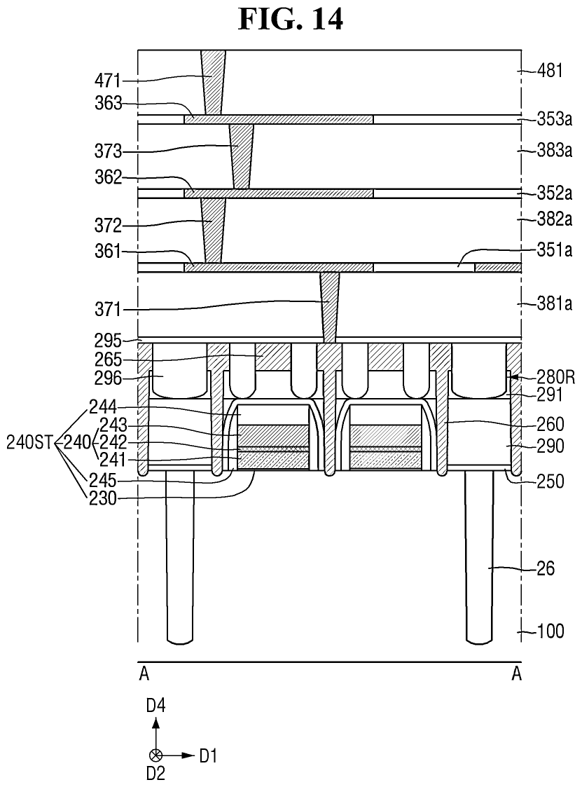

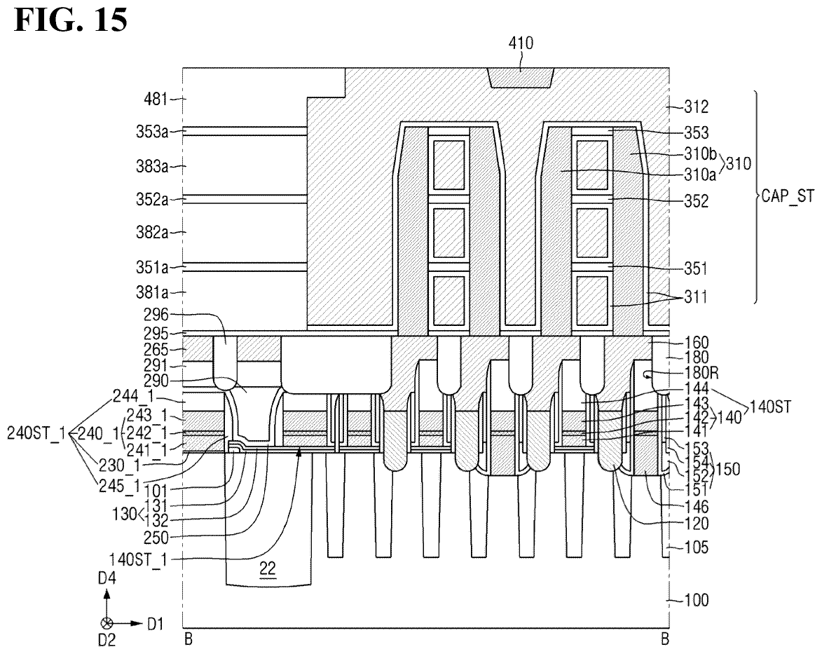

FIGS. 14 and 15 are views of a semiconductor memory device according to embodiments. For ease of description, the following description will focus on differences from the semiconductor memory devices described above with reference to FIGS. 1 through 13.

Referring to FIGS. 14 and 15, the semiconductor memory device according to the embodiments may further include a fourth interlayer insulating layer 382a, a second insulating layer 352a, a fifth interlayer insulating layer 383a, a third insulating layer 353a between a second interlayer insulating layer 381a and a third interlayer insulating layer 481.

The fourth interlayer insulating layer 382a may be disposed on a first insulating layer 351a, and a fourth peripheral contact plug 372 connected to a second peripheral wiring line 361 may be formed. The second insulating layer 352a may be disposed on the fourth interlayer insulating layer 382a, and a third peripheral wiring line 362 connected to the fourth peripheral contact plug 372 may be formed.

The fifth interlayer insulating layer 383a may be disposed on the second insulating layer 352a, and a fifth peripheral contact plug 373 connected to the third peripheral wiring line 362 may be formed. The third insulating layer 353a may be disposed on the fifth interlayer insulating layer 383a, and a fourth peripheral wiring line 363 connected to the fifth peripheral contact plug 373 may be formed.

The third interlayer insulating layer 481 may be disposed on the third insulating layer 353a, and a third peripheral contact plug 471 connected to the fourth peripheral wiring line 363 may be formed.

A first support layer 351, the first insulating layer 351a on a cell element isolation layer 22, and the first insulating layer 351a in a peripheral area 24 may be disposed at the same height.

A second support layer 352, the second insulating layer 352a on the cell element isolation layer 22, and the second insulating layer 352a in the peripheral area 24 may be disposed at the same height.

A third support layer 353, the third insulating layer 353a on the cell element isolation layer 22, and the third insulating layer 353a in the peripheral area 24 may be disposed at the same height.

In some embodiments, the second support layer 352, the second insulating layer 352a on the cell element isolation layer 22, and the second insulating layer 352a in the peripheral area 24 may each be formed of or include silicon carbonitride (SiCN). The third support layer 353, the third insulating layer 353a on the cell element isolation layer 22, and the third insulating layer 353a in the peripheral area 24 may each be formed of or include silicon carbonitride (SiCN).

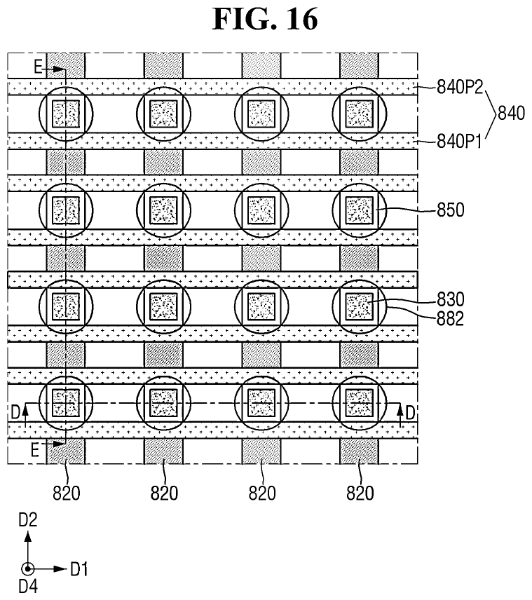

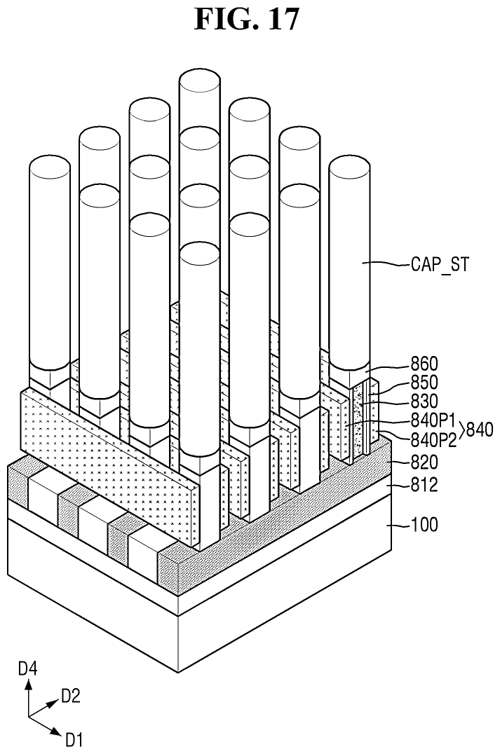

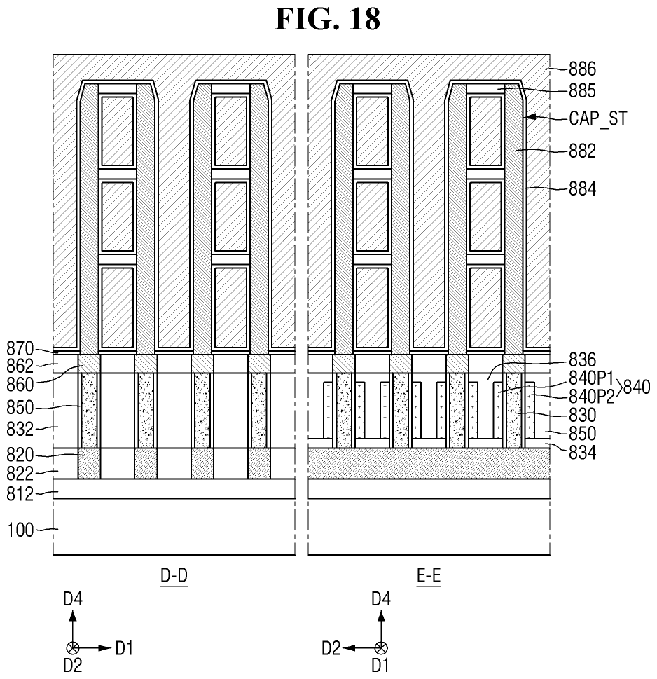

FIG. 16 is a layout view of a semiconductor memory device according to embodiments. FIG. 17 is a perspective view of the semiconductor memory device according to the embodiments. FIG. 18 is a cross-sectional view taken along lines D-D and E-E of FIG. 16.

For reference, FIG. 16 may be an enlarged view of the R1 area (cell area) of FIG. 1. In addition, in the semiconductor memory device in which FIG. 16 is applied to the cell area, a cross section of a boundary portion of the cell area (e.g., B-B of FIG. 3) is different from FIG. 6.

Referring to FIGS. 16 through 18, the semiconductor memory device according to the embodiments includes a substrate 100, a plurality of first conductive lines 820, channel layers 830, gate electrodes 840, a gate insulating layer 850, and a capacitor structure CAP_ST. The semiconductor memory device according to the embodiments may be a memory device including a vertical channel transistor. The vertical channel transistor may refer to a structure in which a channel length of a channel layer 830 extends along a vertical direction from the substrate 100.

A lower insulating layer 812 may be disposed on the substrate 100. The first conductive lines 820 may be spaced apart from each other in the first direction D1 and extend in the second direction D2 on the lower insulating layer 812. A plurality of first insulating patterns 822 may be disposed on the lower insulating layer 812 to fill spaces between the first conductive lines 820. The first insulating patterns 822 may extend in the second direction D2. Upper surfaces of the first insulating patterns 822 may be disposed at the same level as upper surfaces of the first conductive lines 820. The first conductive lines 820 may function as bit lines.

The first conductive lines 820 may be formed of or include a doped semiconductor material, a metal, a conductive metal nitride, a conductive metal silicide, a conductive metal oxide, or a combination thereof. For example, the first conductive lines 820 may be made of, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. Each of the first conductive lines 820 may include a single layer or multiple layers of the above materials. In example embodiments, the first conductive lines 820 may include graphene, carbon nanotubes, or a combination thereof.

The channel layers 830 may be arranged in a matrix form on the first conductive lines 820 and spaced apart from each other in the first direction D1 and the second direction D2. The channel layers 830 may have a first width in the first direction D1 and a first height in the fourth direction D4, and the first height may be greater than the first width. Here, the fourth direction D4 may be a direction intersecting the first direction D1 and the second direction D2 and, for example, perpendicular to an upper surface of the substrate 100. For example, the first height may be, but is not limited to, about 2 to 10 times the first width. A bottom portion of each channel layer 830 may function as a third source/drain region (not illustrated), and an upper portion of each channel layer 830 may function as a fourth source/drain region (not illustrated). A portion of each channel layer 830 between the third and fourth source/drain regions may function as a channel region (not illustrated).

In example embodiments, the channel layers 830 may be formed of or include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. Each of the channel layers 830 may include a single layer or multiple layers of the oxide semiconductor. In some examples, the channel layers 830 may have a bandgap energy greater than that of silicon. For example, the channel layers 830 may have a bandgap energy of about 1.5 to 5.6 eV. For example, the channel layers 830 may have optimal channel performance when having a bandgap energy of about 2.0 to 4.0 eV. For example, the channel layers 830 may be polycrystalline or amorphous, but the present disclosure is not limited thereto. In example embodiments, the channel layers 830 may include graphene, carbon nanotubes, or a combination thereof.

The gate electrodes 840 may extend in the first direction D1 on both sidewalls of the channel layers 830. Each of the gate electrodes 840 may include a first sub-gate electrode 840P1 facing first sidewalls of the channel layers 830, and a second sub-gate electrode 840P2 facing second sidewalls opposite the first sidewalls of the channel layers 830. Since one channel layer 830 is disposed between the first sub-gate electrode 840P1 and the second sub-gate electrode 840P2, the semiconductor device may have a dual-gate transistor structure. However, the technical spirit of the present disclosure is not limited thereto, and the second sub-gate electrode 840P2 may also be omitted, and only the first sub-gate electrode 840P1 facing the first sidewalls of the channel layers 830 may be formed to implement a single-gate transistor structure. The material included in the gate electrodes 840 may be the same as that of the cell gate electrodes 112 described above.

The gate insulating layer 850 may surround the sidewalls of the channel layers 830 and may be interposed between the channel layers 830 and the gate electrodes 840. For example, as illustrated in FIG. 16, the sidewalls of the channel layers 830 may all be surrounded by the gate insulating layer 850, and portions of sidewalls of the gate electrodes 840 may contact the gate insulating layer 850. In embodiments, the gate insulating layer 850 may extend in a direction (e.g., the first direction D1) in which the gate electrodes 840 extend, and only two sidewalls facing the gate electrodes 840 among the sidewalls of each channel layer 830 may contact the gate insulating layer 850. In example embodiments, the gate insulating layer 850 may be made of a silicon oxide layer, a silicon oxynitride layer, a high-k material having a higher dielectric constant than the silicon oxide layer, or a combination thereof.

A plurality of second insulating patterns 832 may extend on the first insulating patterns 822 along the second direction D2. The channel layers 830 may be disposed between two adjacent second insulating patterns 832 among the second insulating patterns 832. In addition, a first buried layer 834 and a second buried layer 836 may be disposed in a space between two adjacent channel layers 830 between two adjacent second insulating patterns 832. The first buried layer 834 may be disposed at the bottom of the space between the two adjacent channel layers 830. The second buried layer 836 may be formed on the first buried layer 834 to fill the remaining space between the two adjacent channel layers 830. An upper surface of the second buried layer 836 may be disposed at the same level as an upper surface of each channel layer 830, and the second buried layer 836 may cover an upper surface of each second gate electrode 840. Alternatively, the second insulating patterns 832 may be formed as material layers continuous with the first insulating patterns 822, or the second buried layer 836 may be formed as a material layer continuous with the first buried layer 834.

Capacitor contacts 860 may be disposed on the channel layers 830. The capacitor contacts 860 may vertically overlap the channel layers 830 and may be arranged in a matrix form and spaced apart from each other in the first direction D1 and the second direction D2. The capacitor contacts 860 may be made of, but not limited to, doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof. An upper insulating layer 862 may be disposed on the second insulating patterns 832 and the second buried layer 836 to surround sidewalls of the capacitor contacts 860.

A cell etch stop layer 870 may be disposed on the upper insulating layer 862. The capacitor structure CAP_ST may be disposed on the cell etch stop layer 870. The cell etch stop layer 870 may correspond to the upper etch stop layer 295 of FIG. 7.

The capacitor structure CAP_ST may include lower electrodes 882, a capacitor dielectric layer 884, an upper electrode 886, and an electrode support structure 885. The lower electrodes 882 may penetrate the cell etch stop layer 870 and may be electrically connected to upper surfaces of the capacitor contacts 860. The lower electrodes 882 may be formed as a pillar type extending in the fourth direction D4, but the present disclosure is not limited thereto. In example embodiments, the lower electrodes 882 may vertically overlap the capacitor contacts 860 and may be arranged in a matrix form and spaced apart from each other in the first direction D1 and the second direction D2. Alternatively, landing pads (not illustrated) may be further disposed between the capacitor contacts 860 and the lower electrodes 882, so that the lower electrodes 882 are arranged in a hexagonal shape. The electrode support structure 885 may support the lower electrodes 882 and connect lower electrodes 882 to each other.

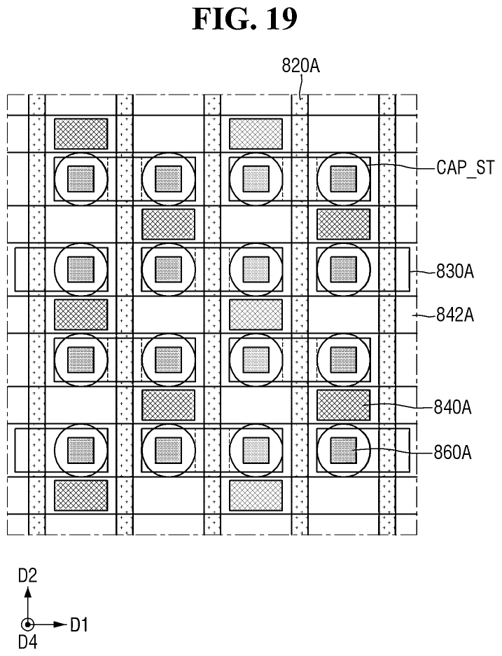

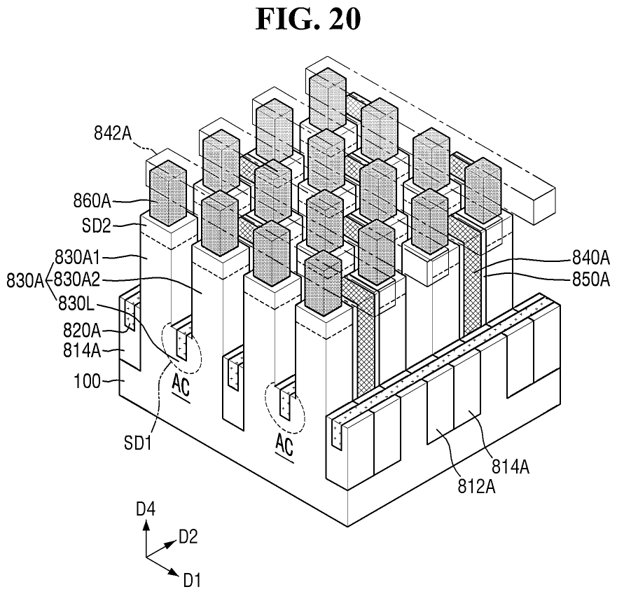

FIG. 19 is a layout view of a semiconductor memory device according to embodiments. FIG. 20 is a perspective view of the semiconductor memory device according to the embodiments.

Referring to FIGS. 19 and 20, the semiconductor memory device according to the embodiments may include a substrate 100, a plurality of first conductive lines 820A, channel structures 830A, contact gate electrodes 840A, a plurality of second conductive lines 842A, and a capacitor structure CAP_ST. The semiconductor memory device according to the embodiments may be a memory device including a vertical channel transistor.

A plurality of active areas AC may be defined in the substrate 100 by first element isolation patterns 812A and second element isolation patterns 814A. The channel structures 830A may be disposed in the active areas AC, respectively. Each of the channel structures 830A may include first and second active pillars 830A1 and 830A2 extending in a vertical direction and a connection portion 830L connected to a bottom portion of the first active pillar 830A1 and a bottom portion of the second active pillar 830A2. A first source/drain region SD1 may be disposed in the connection portion 830L. A second source/drain region SD2 may be disposed on each of the first and second active pillars 830A1 and 830A2. Each of the first active pillar 830A1 and the second active pillar 830A2 may form an independent unit memory cell.

The first conductive lines 820A may extend in a direction intersecting the active areas AC, for example, may extend in the second direction D2. One of the first conductive lines 820A may be disposed on the connection portion 830L between the first active pillar 830A1 and the second active pillar 830A2. The first conductive line 820A may be disposed on the first source/drain region SD1. Another first conductive line 820A adjacent to the first conductive line 820A may be disposed between two channel structures 830A. One of the first conductive lines 820A may function as a common bit line included in two unit memory cells formed by the first active pillar 830A1 and the second active pillar 830A2 disposed on both sides of the first conductive line 820A.

One contact gate electrode 840A may be disposed between two channel structures 830A adjacent to each other in the second direction D2. For example, a contact gate electrode 840A may be disposed between the first active pillar 830A1 included in one channel structure 830A and the second active pillar 830A2 of another channel structure 830A adjacent to the channel structure 830A. One contact gate electrode 840A may be shared by the first active pillar 830A1 and the second active pillar 830A2 disposed on both sidewalls thereof. A gate insulating layer 850A may be disposed between each contact gate electrode 840A and the first active pillar 830A1 and between each contact gate electrode 840A and the second active pillar 830A2. The second conductive lines 842A may extend on upper surfaces of the contact gate electrodes 840A in the first direction D1. The second conductive lines 842A may function as word lines of the semiconductor device.

Capacitor contacts 860A may be disposed on the channel structures 830A. The capacitor contacts 860A may be disposed on the second source/drain regions SD2, and the capacitor structure CAP_ST may be disposed on the capacitor contacts 860A.

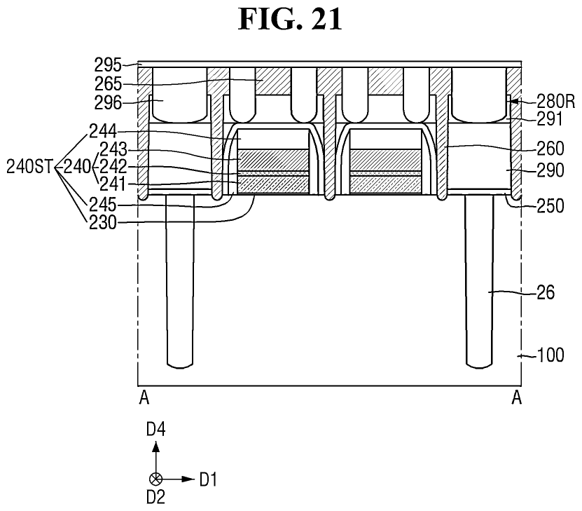

FIGS. 21 through 39 are views illustrating intermediate steps of a method of fabricating a semiconductor memory device according to embodiments. A description of the same elements and features as those described using FIGS. 1 through 7 will be given briefly or omitted.

For reference, FIGS. 21 through 39 are views illustrating a method of fabricating the semiconductor memory device illustrated in FIGS. 1 through 7.

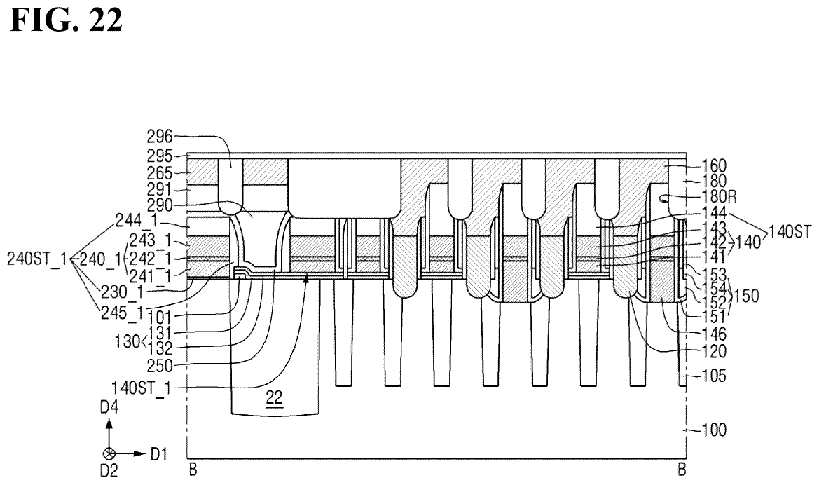

Referring to FIGS. 21 and 22, a substrate 100 including a cell area 20, a peripheral area 24, and a cell element isolation layer 22 is provided.

Cell gate structures 110 may be formed in the substrate 100 of the cell area 20. The cell gate structures 110 may extend in the first direction D1. Each of the cell gate structures 110 may include a cell gate trench 115, a cell gate insulating layer 111, a cell gate electrode 112, a cell gate capping pattern 113, and a cell gate capping conductive layer 114.

Next, a cell insulating layer 130 may be formed on the cell area 20. The cell insulating layer 130 may expose the peripheral area 24 of the substrate 100.

Next, bit line structures 140ST may be formed on the cell area 20 of the substrate 100. Each of the bit line structures 140ST may include a cell conductive line 140 and a cell line capping layer 144.

Peripheral gate structures 240ST may be formed on the peripheral area 24 of the substrate 100. Each of the peripheral gate structures 240ST may include a peripheral gate insulating layer 230, a peripheral gate conductive layer 240, a peripheral capping layer 244, and peripheral spacers 245.

Next, storage pads 160 may be formed on side surfaces of the bit line structures 140ST. The storage pads 160 may be separated by pad isolation recesses 180R. In addition, first peripheral contact plugs 260 may be formed on both sides of each peripheral gate structure 240ST. A first peripheral wiring line 265 may be formed on the peripheral gate structures 240ST. The first peripheral contact plugs 260 and the first peripheral wiring line 265 may be separated by wiring isolation recesses 280R.

For example, the storage pads 160, the first peripheral contact plugs 260, and the first peripheral wiring line 265 may be formed simultaneously.

An upper etch stop layer 295 may be formed on the first peripheral wiring line 265 and a first interlayer insulating layer 296. The upper etch stop layer 295 may be formed on the storage pads 160 and a pad isolation insulating layer 180.

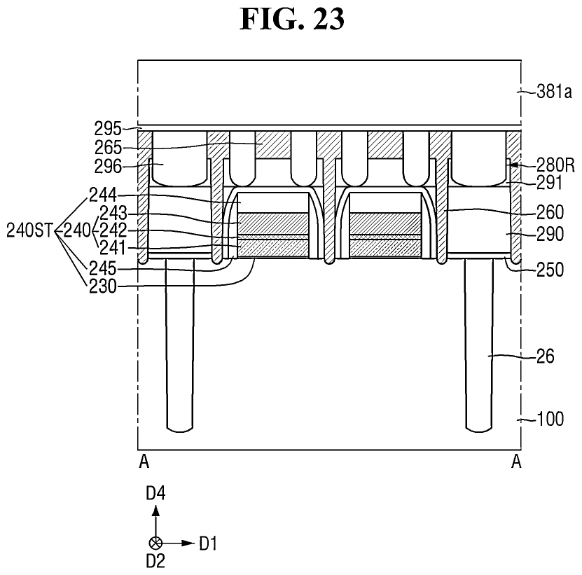

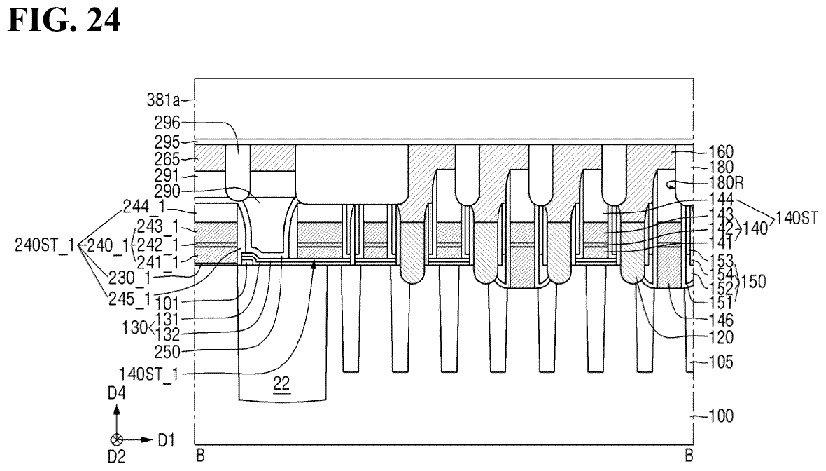

Referring to FIGS. 23 and 24, a second interlayer insulating layer 381a may be formed on the upper etch stop layer 295. For example, the second interlayer insulating layer 381a may be formed of or include oxide.

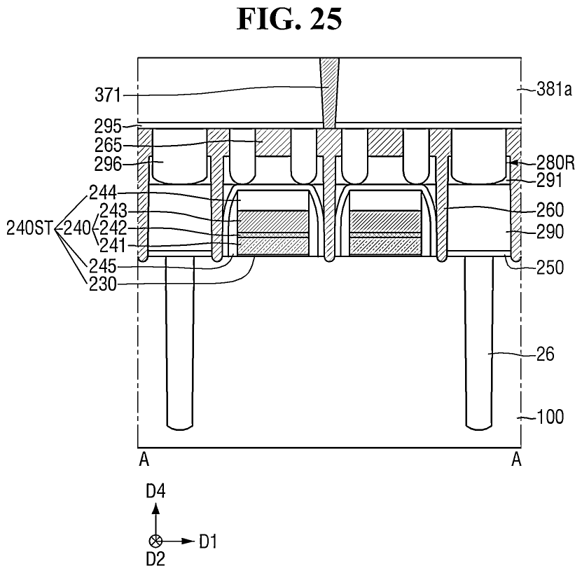

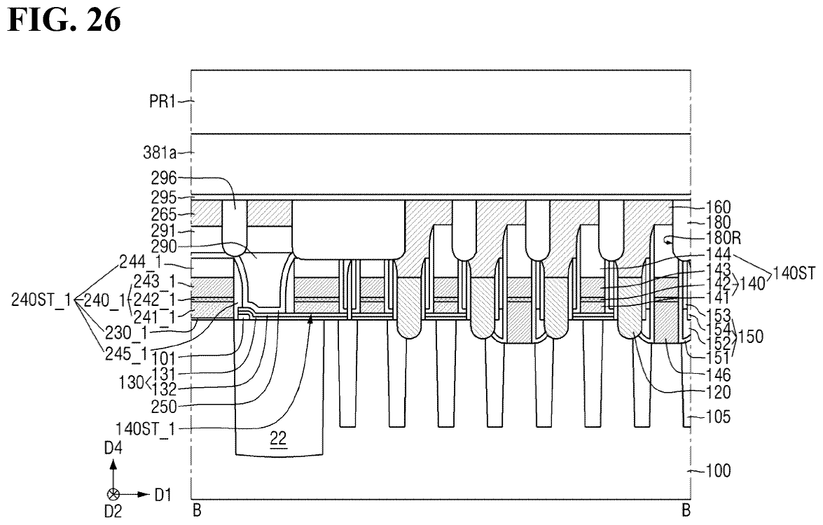

Referring to FIGS. 25 and 26, a first photoresist layer PR1 is formed on the second interlayer insulating layer 381a on the cell area 20 and the cell element isolation layer 22.

Next, a second peripheral contact plug 371 is formed in the second interlayer insulating layer 381a on the peripheral area 24. The second peripheral contact plug 371 may penetrate the second interlayer insulating layer 381a and may be connected to the first peripheral wiring line 265.

Next, the first photoresist layer PR1 is removed.

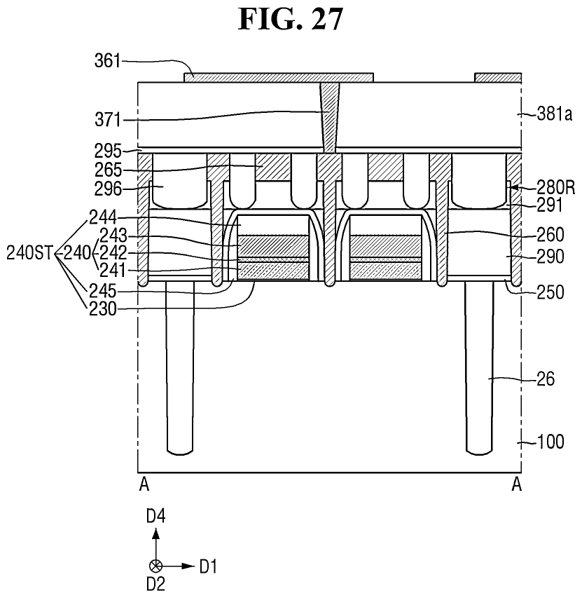

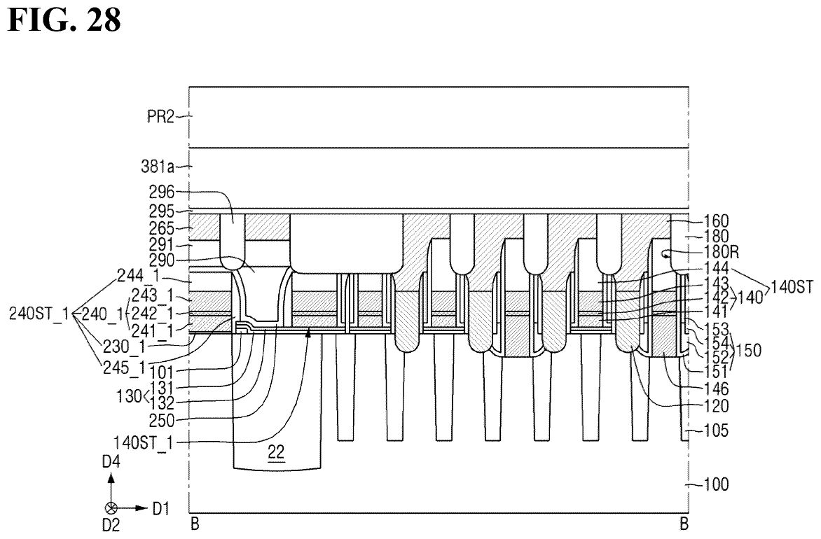

Referring to FIGS. 27 and 28, a second photoresist layer PR2 is formed on the second interlayer insulating layer 381a on the cell area 20 and the cell element isolation layer 22.

Next, a second peripheral wiring line 361 connected to the second peripheral contact plug 371 is formed on the second interlayer insulating layer 381a on the peripheral area 24.

Next, the second photoresist layer PR2 is removed.

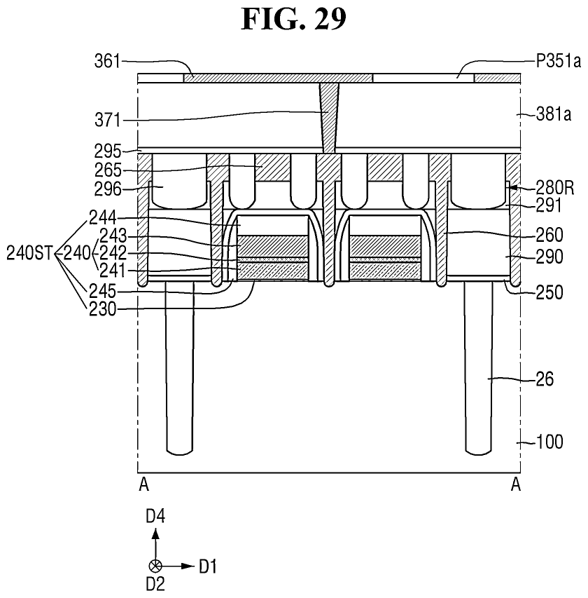

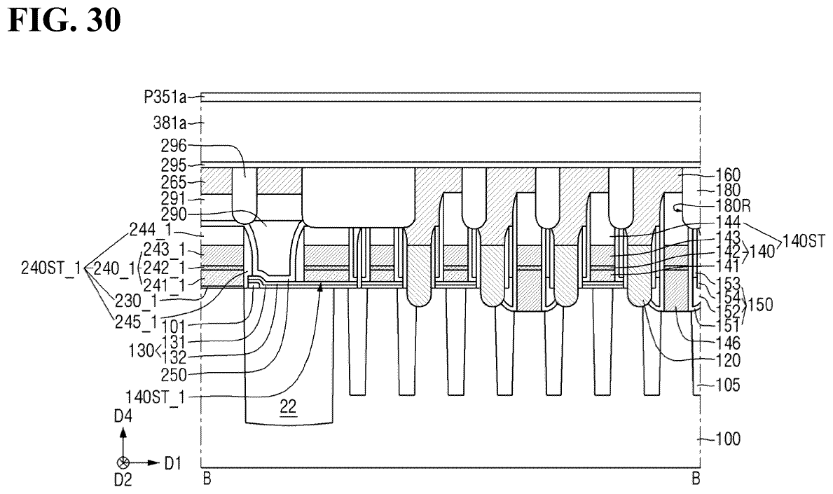

Referring to FIGS. 29 and 30, a first pre-insulating layer P351a is formed on the second interlayer insulating layer 381a on the cell area 20 and the cell element isolation layer 22. At the same time, the first pre-insulating layer P351a is formed on the second interlayer insulating layer 381a on the peripheral area 24. The second peripheral wiring line 361 may be formed in the first pre-insulating layer P351a. For example, the first pre-insulating layer P351a may be formed of or include silicon carbonitride (SiCN).

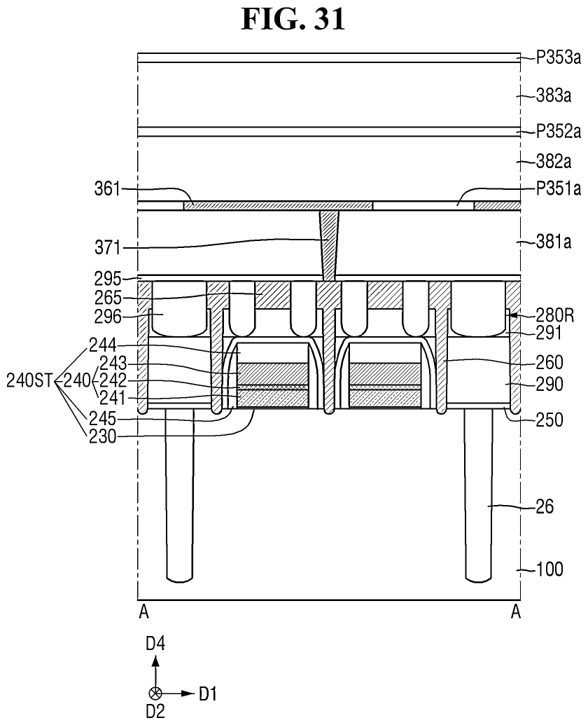

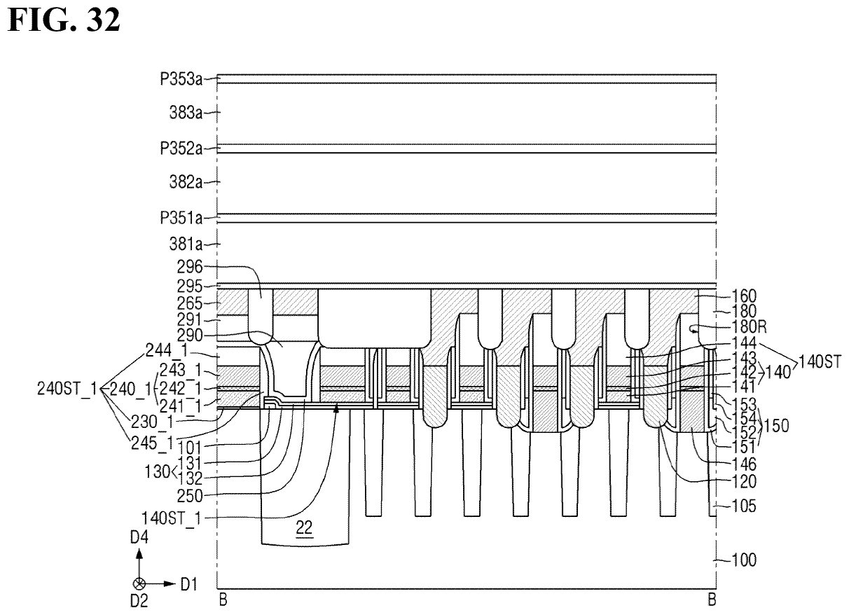

Referring to FIGS. 31 and 32, a fourth interlayer insulating layer 382a, a second pre-insulating layer P352a, a fifth interlayer insulating layer 383a, and a third pre-insulating layer P353a are sequentially formed on the first pre-insulating layer P351a on the cell area 20 and the cell element isolation layer 22.

The fourth interlayer insulating layer 382a, the second pre-insulating layer P352a, the fifth interlayer insulating layer 383a, and the third pre-insulating layer P353a are sequentially formed on the first pre-insulating layer P351a on the peripheral area 24.

For example, the first pre-insulating layer P351a, the second pre-insulating layer P352a, and the third pre-insulating layer P353a may be formed of or include silicon carbonitride (SiCN). For example, the fourth interlayer insulating layer 382a and the fifth interlayer insulating layer 383a may be formed of or include silicon oxide.

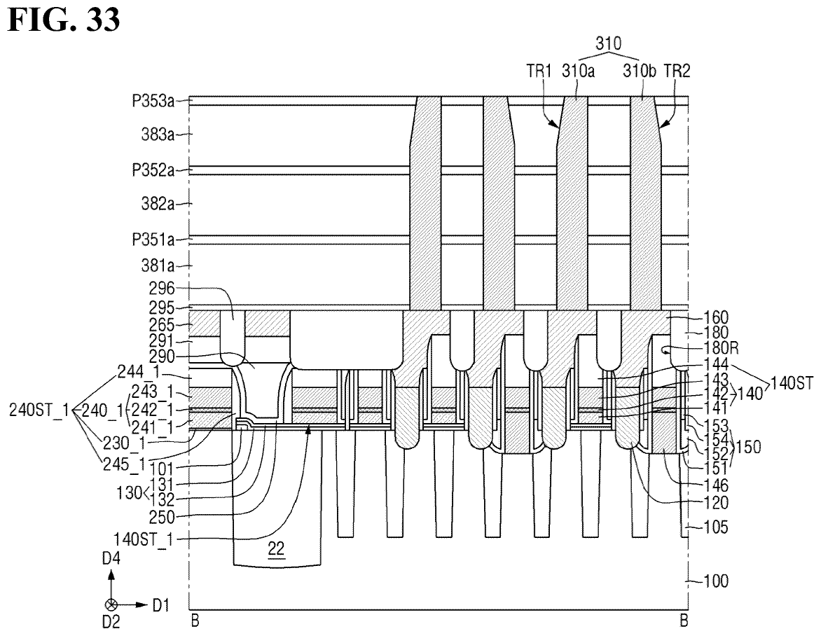

Referring to FIG. 33, first and second trenches TR1 and TR2 may be formed to penetrate the upper etch stop layer 295, the second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a.

Next, first and second lower electrodes 310a and 310b may be formed. For example, the first and second lower electrodes 310a and 310b may be formed of or include titanium nitride (TiN). The first lower electrode 310a may be formed in each of the first trenches TR1. The first lower electrode 310a may fill each of the first trenches TR1. The second lower electrode 310b may be formed in each of the second trenches TR2. The second lower electrode 310b may fill each of the second trenches TR2.

The first and second lower electrodes 310a and 310b may be formed on the storage pads 160. The first and second lower electrodes 310a and 310b may be connected to the storage pads 160. The first and second lower electrodes 310a and 310b may directly contact the storage pads 160.

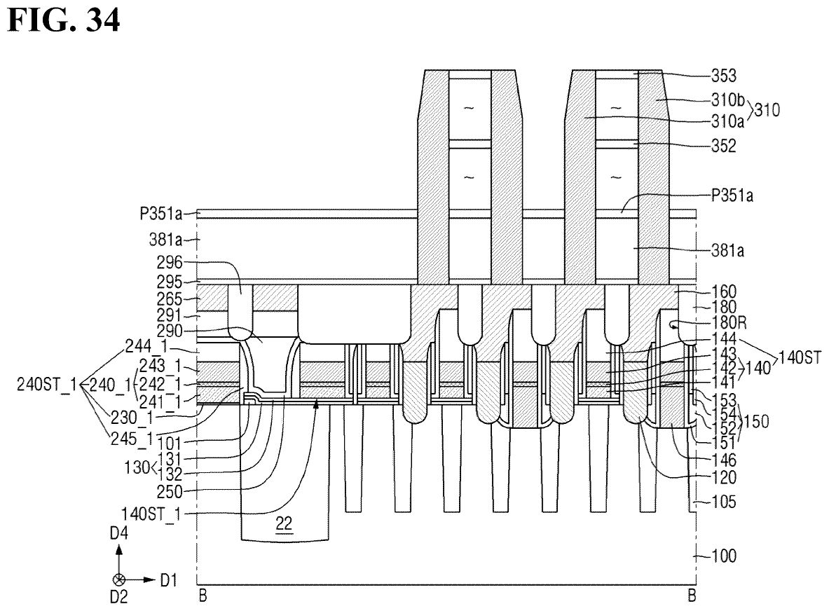

Referring to FIG. 34, the fourth interlayer insulating layer 382a, the second pre-insulating layer P352a, the fifth interlayer insulating layer 383a, and the third pre-insulating layer P353a may be patterned to form second and third support layers 352 and 353.

The fifth interlayer insulating layer 383a may be removed through areas where the third support layer 353 is not formed. The fourth interlayer insulating layer 382a may be removed through areas where the second support layer 352 is not formed.

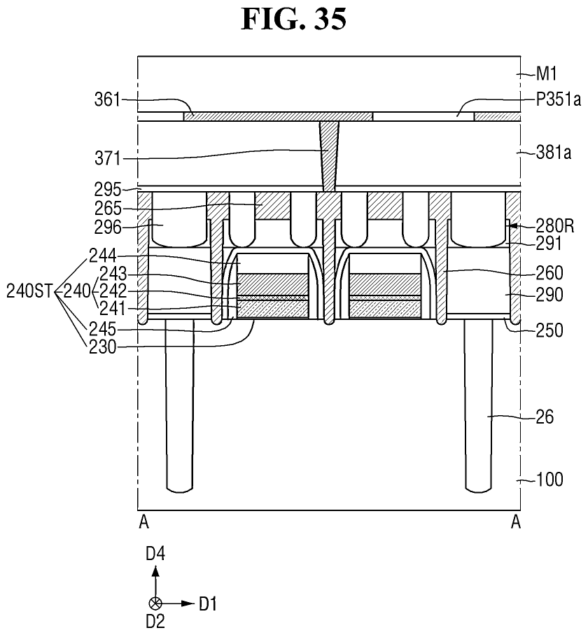

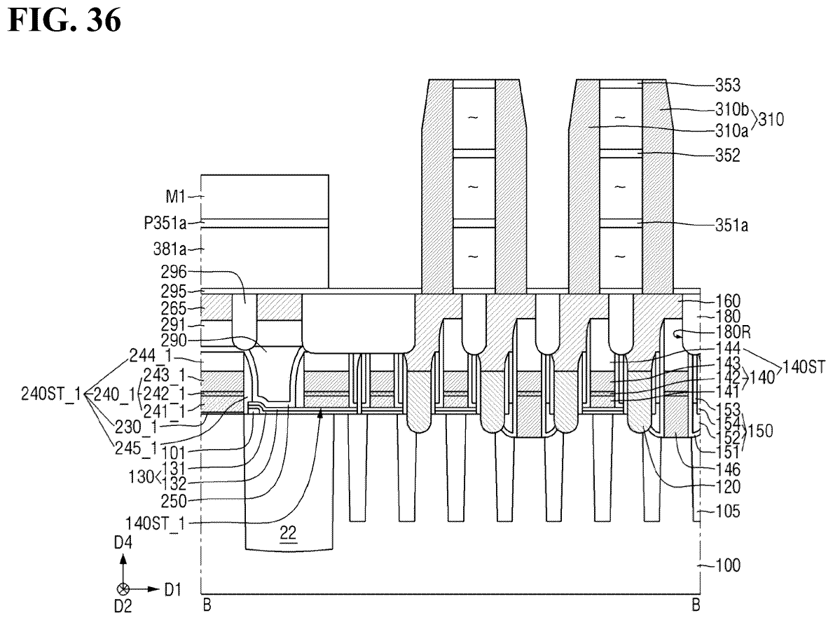

Referring to FIGS. 35 and 36, a mask MI may be formed on the first pre-insulating layer P351a on the peripheral area 24 and the cell element isolation layer 22.

A first support layer 351 may be formed by patterning thesecond interlayer insulating layer 381a and the first pre-insulating layer P351a. The second interlayer insulating layer 381a may be removed through areas where the first support layer 351 is not formed.

Next, the mask MI is removed.

Through the above process, the first through third support layers 351 through 353 connecting adjacent first and second lower electrodes 310a and 310b may be formed.

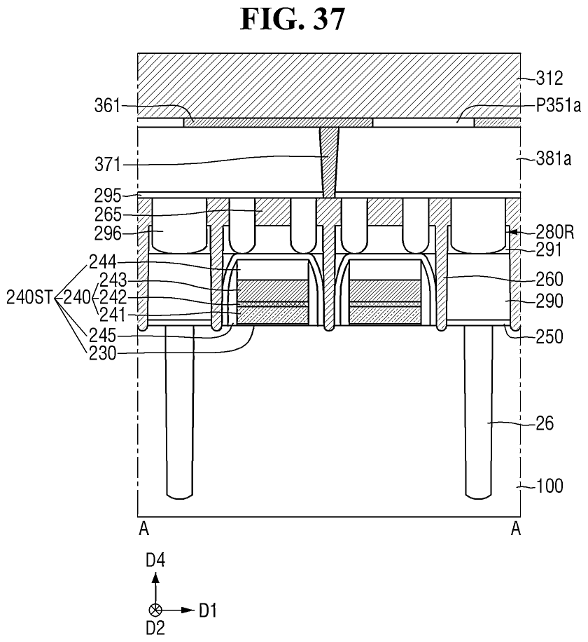

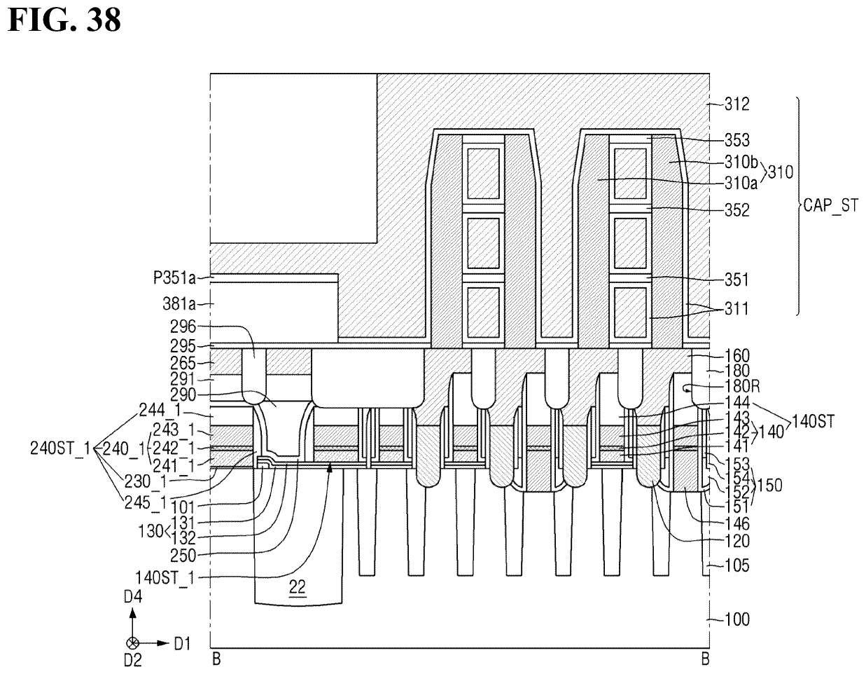

Referring to FIGS. 37 and 38, a capacitor dielectric layer 311 may be formed. The capacitor dielectric layer 311 may be formed on the pad isolation insulating layer 180, the storage pads 160, the lower electrodes 310, and the first through third support layers 351 through 353. The capacitor dielectric layer 311 may extend along upper surfaces of the pad isolation insulating layer 180 and the storage pads 160.

Next, an upper electrode 312 may be formed. The upper electrode 312 may be formed on the capacitor dielectric layer 311. The upper electrode 312 may extend between lower electrodes 310 that are not connected by the first through third support layers 351 through 353. For example, the upper electrode 312 may be made of silicon germanium (SiGe).

Through the above process, a capacitor structure CAP_ST may be formed.

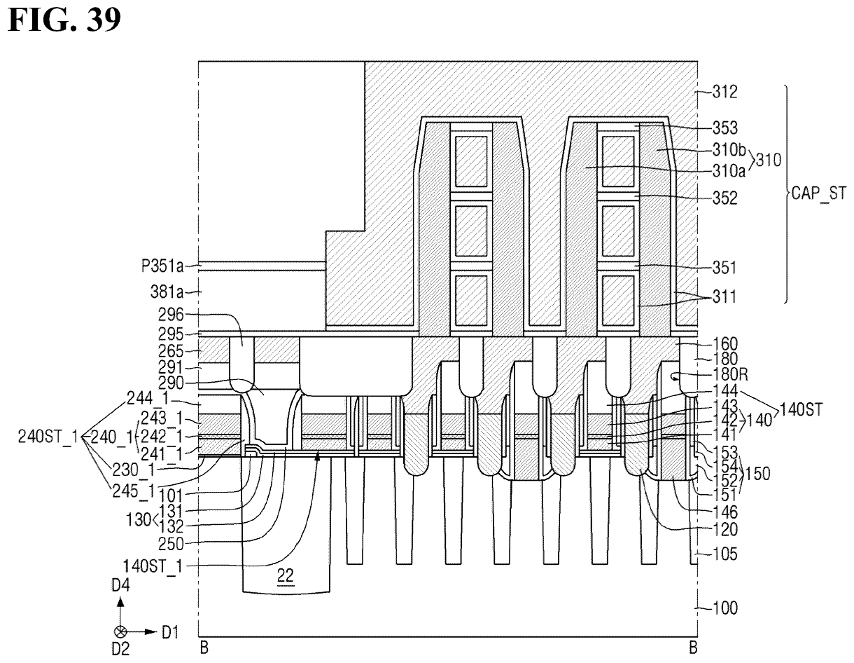

Referring to FIG. 39, the upper electrode 312 on the peripheral area 24 and the cell element isolation layer 22 may be removed.

Although not specifically illustrated, a mask may be formed on the capacitor structure CAP_ST in the cell area 20. The upper electrode 312 on the peripheral area 24 and the cell element isolation layer 22 on which the mask is not formed may be removed.

Next, referring also to FIGS. 5 and 6, a third interlayer insulating layer 481 may be formed on the first pre-insulating layer P351a. The third interlayer insulating layer 481 may be formed on the upper electrode 312. The third interlayer insulating layer 481 may cover the upper electrode 312.

The upper electrode 312 partially covering an upper surface of the first pre-insulating layer P351a may be removed. Accordingly, a sidewall of the second interlayer insulating layer 381a and a sidewall of a first insulating layer 351a may be aligned with a sidewall of the upper electrode 312.

A cell contact plug 410 connected to the upper electrode 312 may be formed on the cell area 20. A third peripheral contact plug 471 connected to the second peripheral wiring line 361 may be formed on the peripheral area 24.

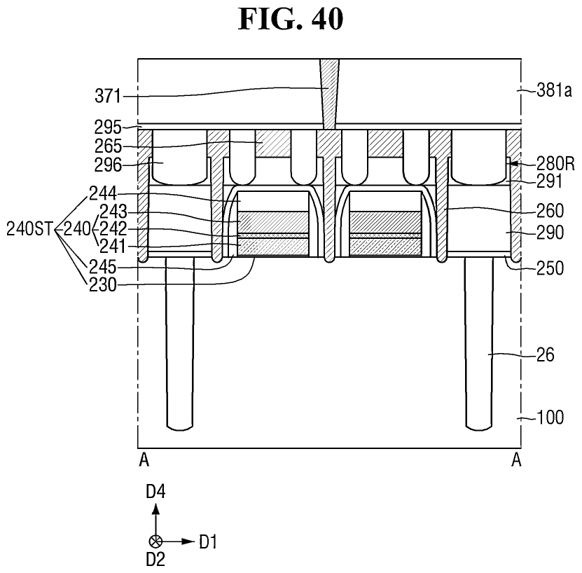

FIGS. 40 through 54 are views illustrating intermediate steps of a method of fabricating a semiconductor memory device according to embodiments. A description of the same elements and features as those described using FIG. 9 will be given briefly or omitted.

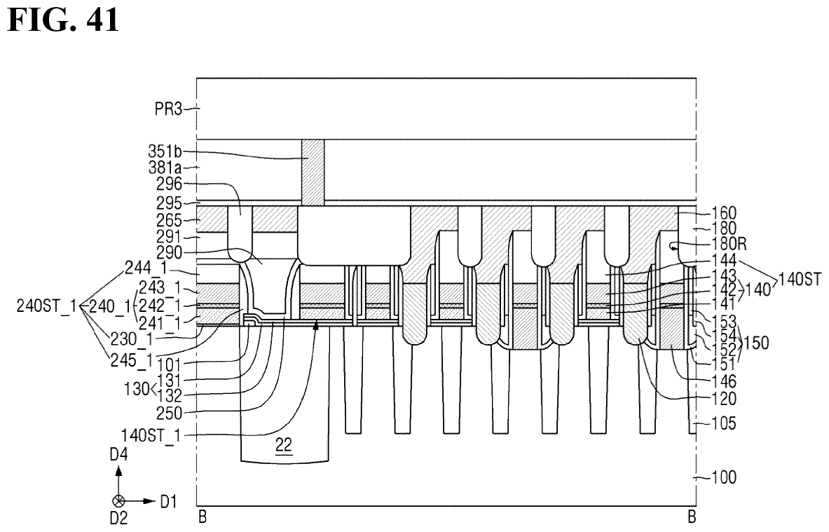

For reference, FIGS. 40 through 54 are views illustrating a method of fabricating the semiconductor memory device illustrated in FIG. 9. In addition, FIGS. 40 and 41 may be understood as drawings illustrating a fabrication method after FIGS. 23 and 24.

Referring to FIGS. 40 and 41, a barrier structure 351b is formed in a second interlayer insulating layer 381a on a cell element isolation layer 22. The barrier structure 351b may be formed to penetrate the second interlayer insulating layer 381a. At least a portion of the barrier structure 351b may be formed in an upper etch stop layer 295. The barrier structure 351b may be formed of or include a metal material. For example, the barrier structure 351b may include, but is not limited to, tungsten (W).

Next, a third photoresist layer PR3 is formed on the second interlayer insulating layer 381a on a cell area 20 and the cell element isolation layer 22.

Next, a second peripheral contact plug 371 is formed in the second interlayer insulating layer 381a on a peripheral area 24. The second peripheral contact plug 371 may penetrate the second interlayer insulating layer 381a and may be connected to a first peripheral wiring line 265.

Next, the third photoresist layer PR3 is removed.

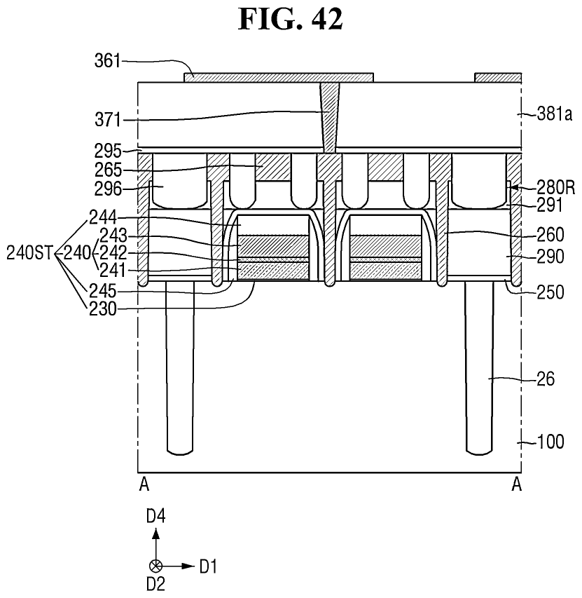

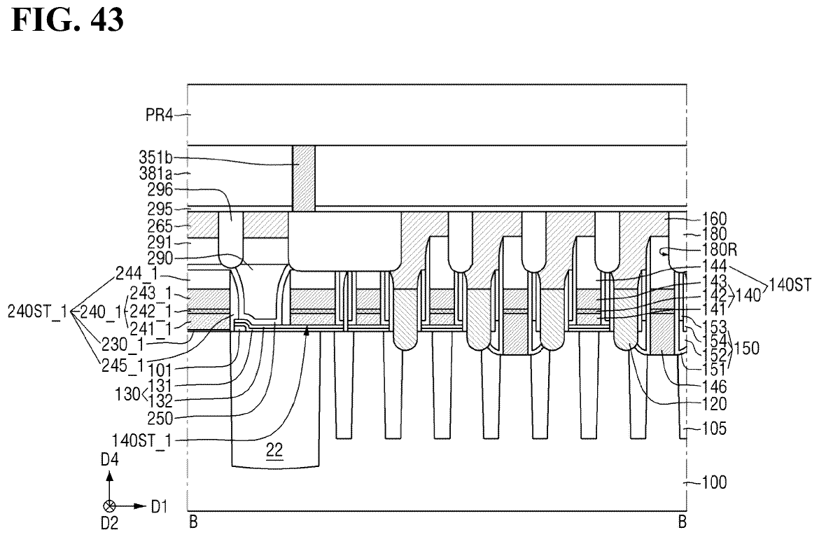

Referring to FIGS. 42 and 43, a fourth photoresist layer PR4 is formed on the second interlayer insulating layer 381a on the cell area 20 and the cell element isolation layer 22.

Next, a second peripheral wiring line 361 connected to the second peripheral contact plug 371 is formed on the second interlayer insulating layer 381a on the peripheral area 24.

Next, the fourth photoresist layer PR4 is removed.

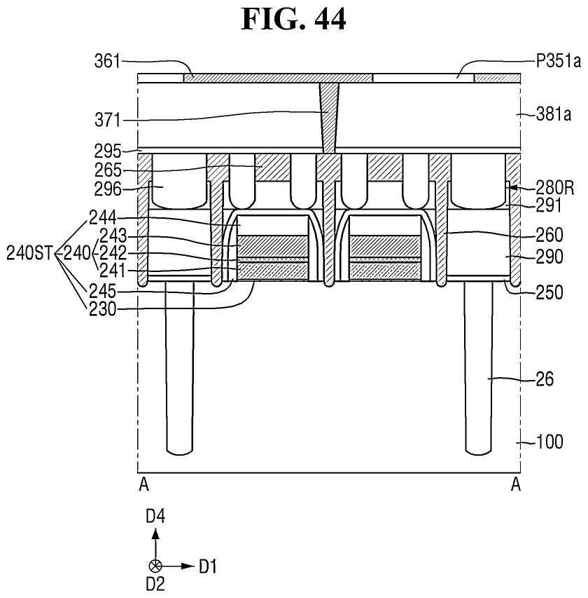

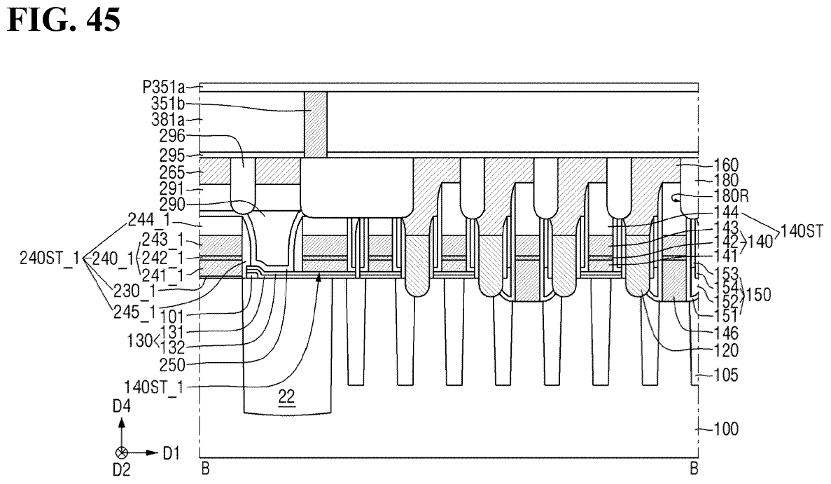

Referring to FIGS. 44 and 45, a first pre-insulating layer P351a is formed on the second interlayer insulating layer 381a on the cell area 20 and the cell element isolation layer 22. At the same time, the first pre-insulating layer P351a is formed on the second interlayer insulating layer 381a on the peripheral area 24.

The second peripheral wiring line 361 may be formed in the first pre-insulating layer P351a. The first pre-insulating layer P351a may be formed on an upper surface of the barrier structure 351b. For example, the first pre-insulating layer P351a may be formed of or include silicon carbonitride (SiCN).

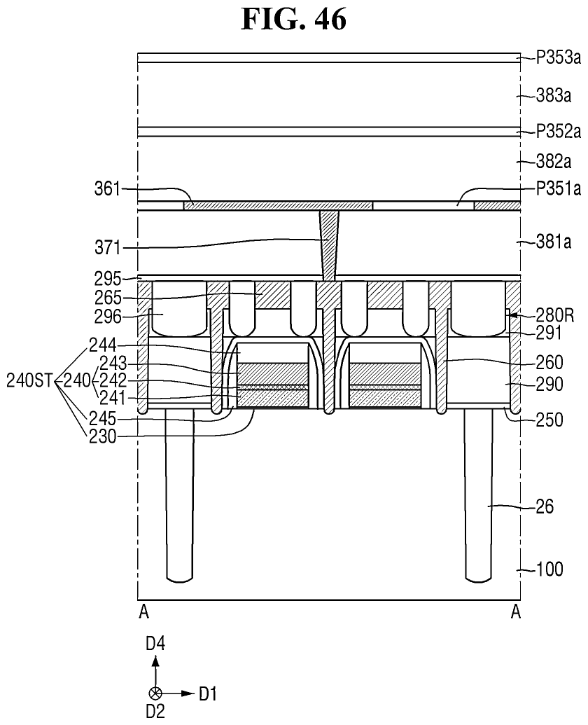

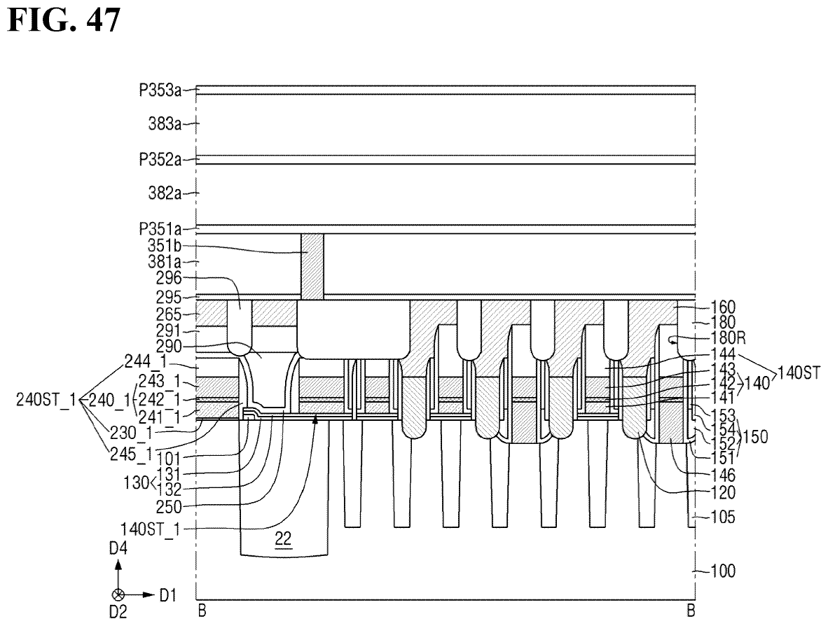

Referring to FIGS. 46 and 47, a fourth interlayer insulating layer 382a, a second pre-insulating layer P352a, a fifth interlayer insulating layer 383a, and a third pre-insulating layer P353a are sequentially formed on the first pre-insulating layer P351a on the cell area 20 and the cell element isolation layer 22.

At the same time, the fourth interlayer insulating layer 382a, the second pre-insulating layer P352a, the fifth interlayer insulating layer 383a, and the third pre-insulating layer P353a are sequentially formed on the first pre-insulating layer P351a on the peripheral area 24.

For example, the second pre-insulating layer P352a and the third pre-insulating layer P353a may be formed of or include silicon carbonitride (SiCN). For example, the fourth interlayer insulating layer 382a and the fifth interlayer insulating layer 383a may be formed of or include silicon oxide.

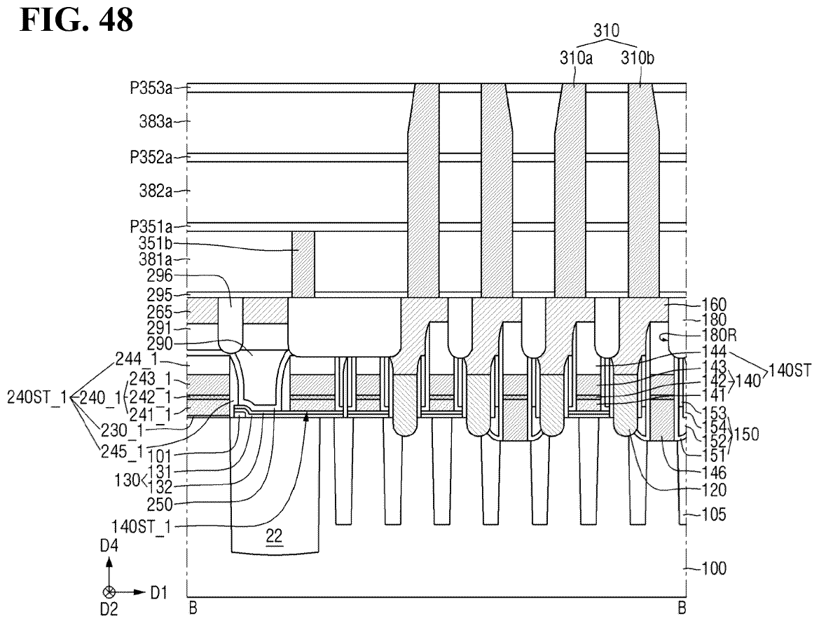

Referring to FIG. 48, first and second trenches may be formed to penetrate the upper etch stop layer 295, the second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a.

Next, first and second lower electrodes 310a and 310b may be formed in the first and second trenches, respectively. For example, the first and second lower electrodes 310a and 310b may be formed of or include titanium nitride (TiN).

The first and second lower electrodes 310a and 310b may be formed on storage pads 160.

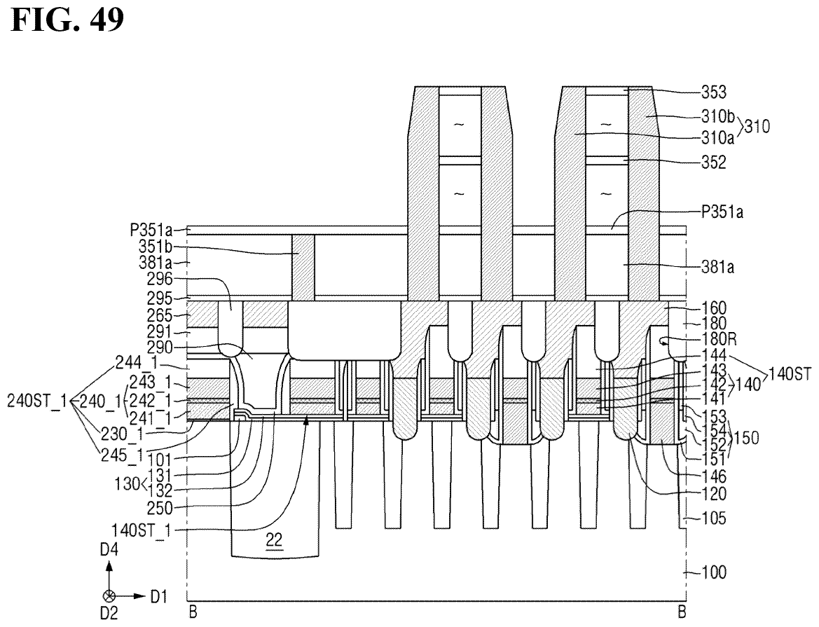

Referring to FIG. 49, the fourth interlayer insulating layer 382a, the second pre-insulating layer P352a, the fifth interlayer insulating layer 383a, and the third pre-insulating layer P353a may be patterned to form second and third support layers 352 and 353.

The fifth interlayer insulating layer 383a may be removed through areas where the third support layer 353 is not formed. The fourth interlayer insulating layer 382a may be removed through areas where the second support layer 352 is not formed.

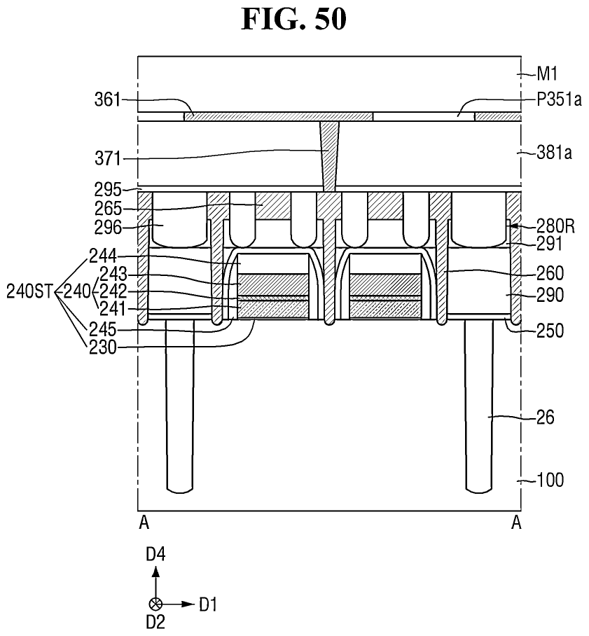

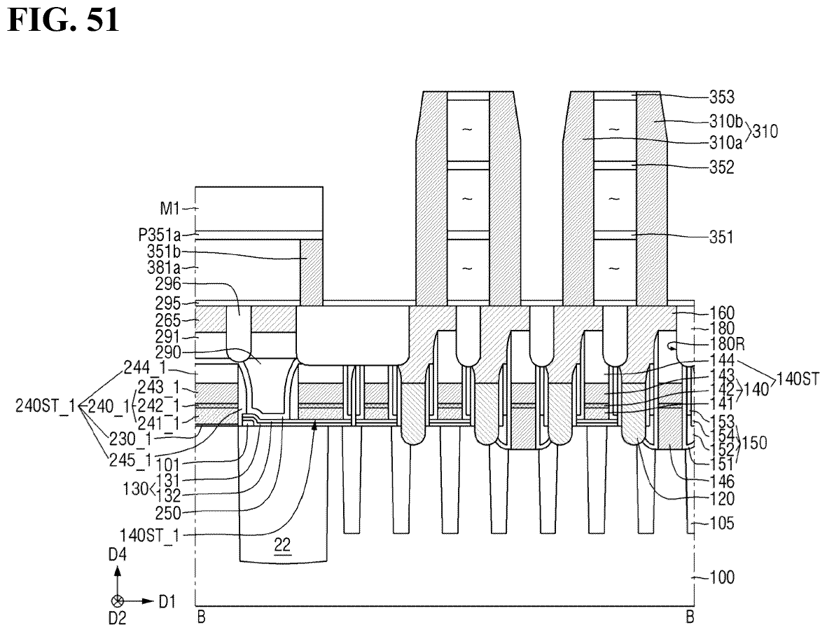

Referring to FIGS. 50 and 51, a mask MI may be formed on the first pre-insulating layer P351a on the peripheral area 24 and the cell element isolation layer 22.

A first support layer 351 may be formed by patterning the second interlayer insulating layer 381a and the first pre-insulating layer P351a. The second interlayer insulating layer 381a may be removed through areas where the first support layer 351 is not formed. A first sidewall of the barrier structure 351b may contact a sidewall of the second interlayer insulating layer 381a, and a second sidewall may be exposed.

Next, the mask MI is removed.

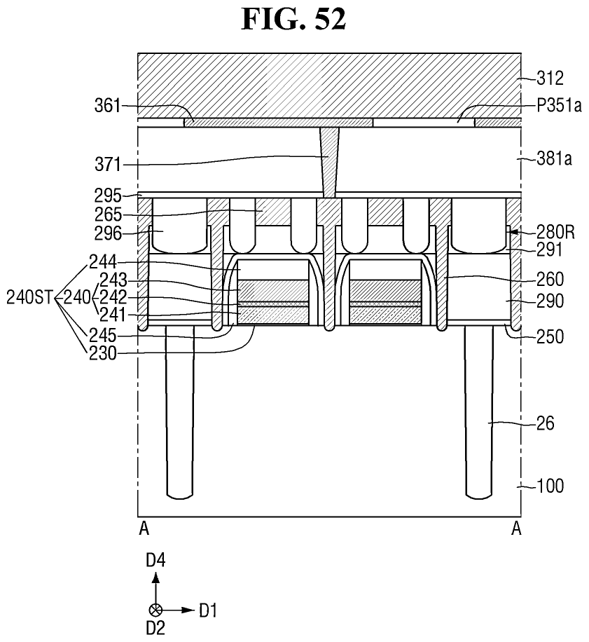

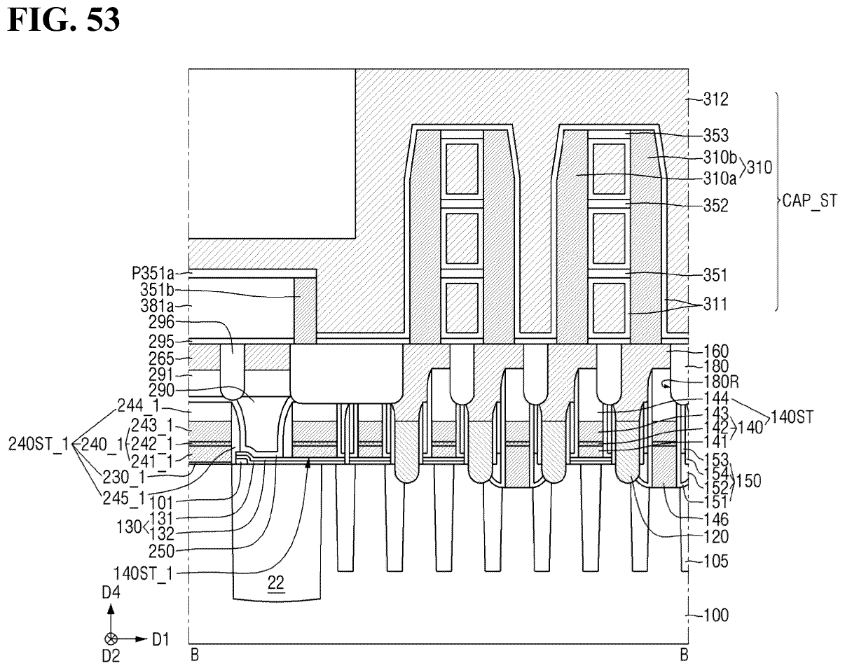

Through the above process, the first through third support layers 351 through 353 connecting adjacent first and second lower electrodes 310a and 310b may be formed. Referring to FIGS. 52 and 53, a capacitor dielectric layer 311 may be formed.

The capacitor dielectric layer 311 may be formed on a pad isolation insulating layer 180, the storage pads 160, the lower electrodes 310, and the first through third support layers 351 through 353. The capacitor dielectric layer 311 may extend along upper surfaces of the pad isolation insulating layer 180 and the storage pads 160. The capacitor dielectric layer 311 may be formed to contact the second sidewall of the barrier structure 351b.

Next, an upper electrode 312 may be formed. The upper electrode 312 may be formed on the capacitor dielectric layer 311. The upper electrode 312 may extend between lower electrodes 310 that are not connected by the first through third support layers 351 through 353. For example, the upper electrode 312 may be made of silicon germanium (SiGe). The upper electrode 312 may be formed to contact the second sidewall of the barrier structure 351b.

Through the above process, a capacitor structure CAP_ST may be formed.

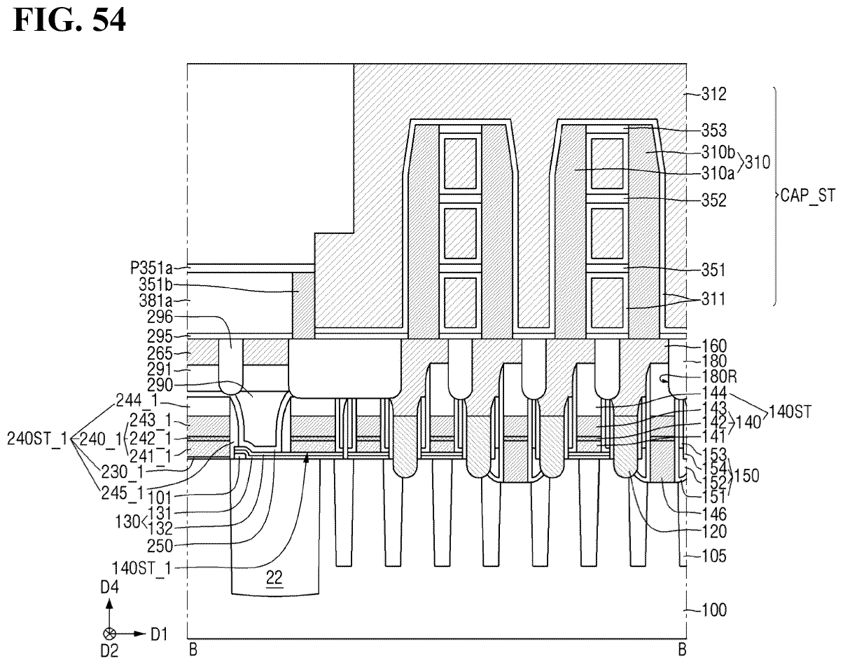

Referring to FIG. 54, the upper electrode 312 on the peripheral area 24 and the cell element isolation layer 22 may be removed.

Although not specifically illustrated, a mask may be formed on the capacitor structure CAP_ST on the cell area 20. The upper electrode 312 on the peripheral area 24 and the cell element isolation layer 22 on which the mask is not formed may be removed.

Next, referring also to FIG. 9, a third interlayer insulating layer 481 may be formed on the first pre-insulating layer P351a. The third interlayer insulating layer 481 may be formed on the upper electrode 312. The third interlayer insulating layer 481 may cover the upper electrode 312.

The upper electrode 312 partially covering an upper surface of the first pre-insulating layer P351a may be removed. Accordingly, a sidewall of the second interlayer insulating layer 381a, a sidewall of the first insulating layer 351a, and the second sidewall of the barrier structure 351b may be aligned with a sidewall of the upper electrode 312.

A cell contact plug 410 connected to the upper electrode 312 may be formed on the cell area 20. A third peripheral contact plug 471 connected to the second peripheral wiring line 361 may be formed on the peripheral area 24.

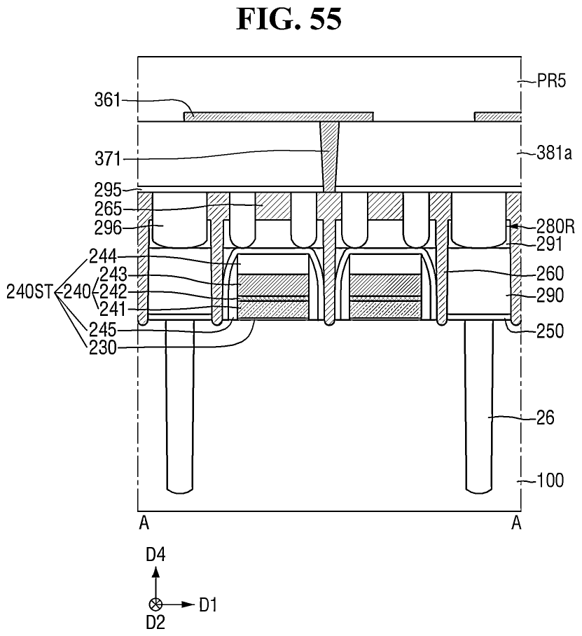

FIGS. 55 through 75 are views illustrating intermediate steps of a method of fabricating a semiconductor memory device according to embodiments. A description of the same elements and features as those described using FIG. 10 will be given briefly or omitted.

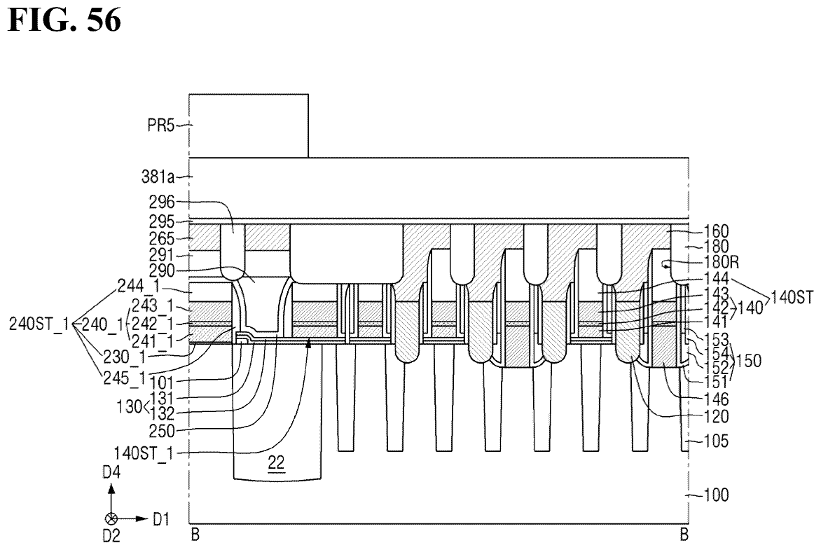

For reference, FIGS. 55 through 75 are views illustrating a method of fabricating the semiconductor memory device illustrated in FIG. 10. In addition, FIGS. 55 and 56 may be understood as drawings illustrating a fabrication method after FIGS. 27 and 28.

Referring to FIGS. 55 and 56, after a second photoresist layer PR2 (see FIGS. 27 and 28) is removed, a fifth photoresist layer PR5 is formed on a second interlayer insulating layer 381a on a peripheral area 24 where a second peripheral wiring line 361 is formed. The fifth photoresist layer PR5 is formed on the second interlayer insulating layer 381a on a cell element isolation layer 22.

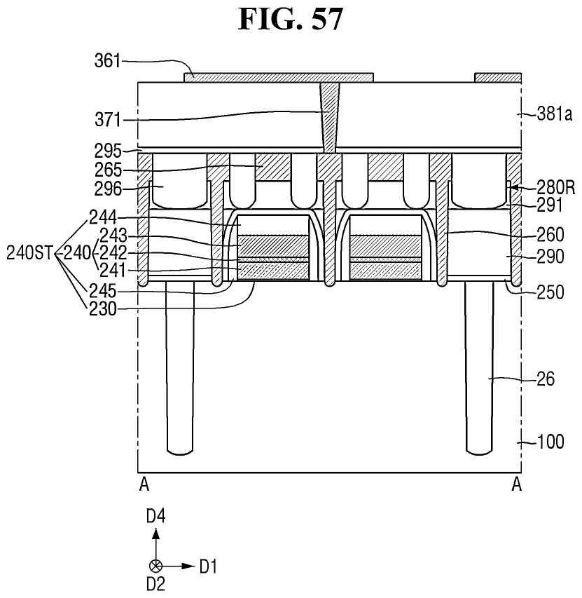

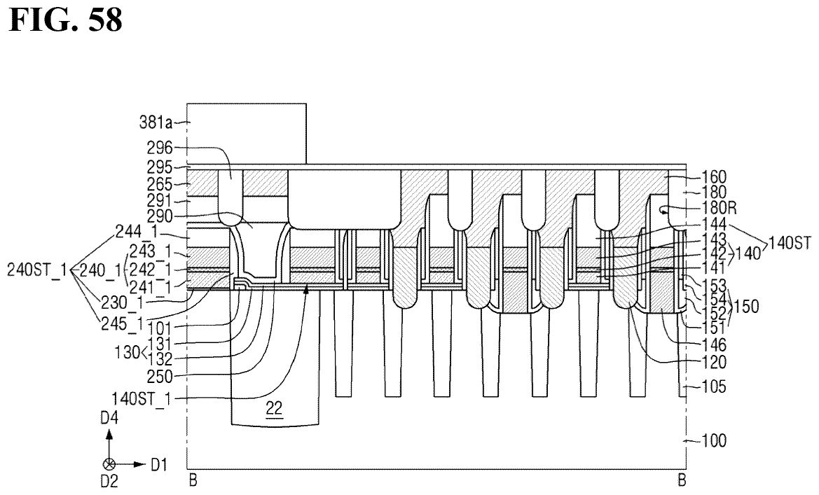

Referring to FIGS. 57 and 58, at least a portion of the second interlayer insulating layer 381a of a cell area 20 may be removed using the fifth photoresist layer PR5.

Next, the fifth photoresist layer PR5 is removed.

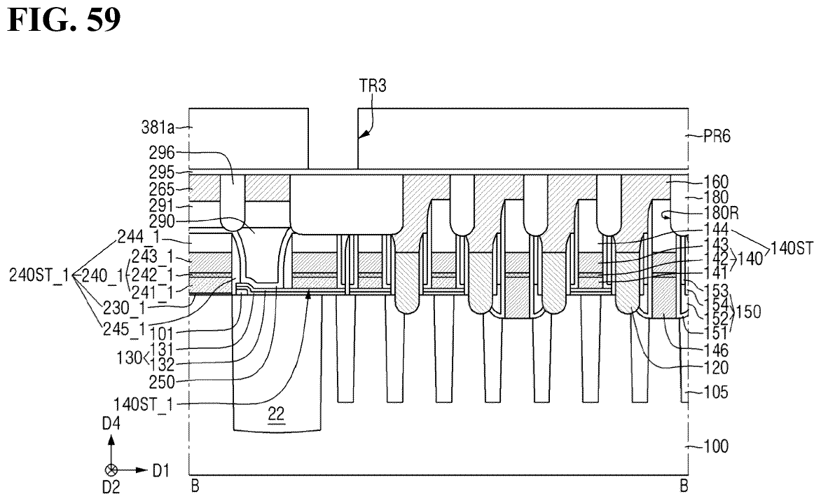

Referring to FIG. 59, a sixth photoresist layer PR6 is formed on an upper etch stop layer 295 on the cell area 20. The sixth photoresist layer PR6 is formed to be spaced apart from the second interlayer insulating layer 381a in the first direction D1. A third trench TR3 may be formed between the sixth photoresist layer PR6 and the second interlayer insulating layer 381a.

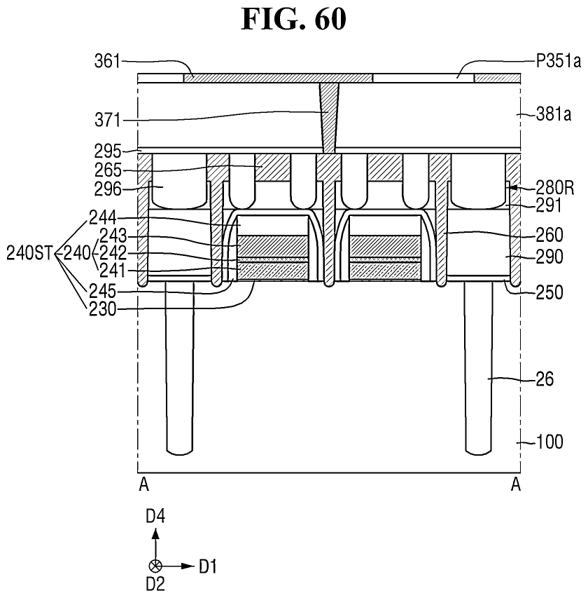

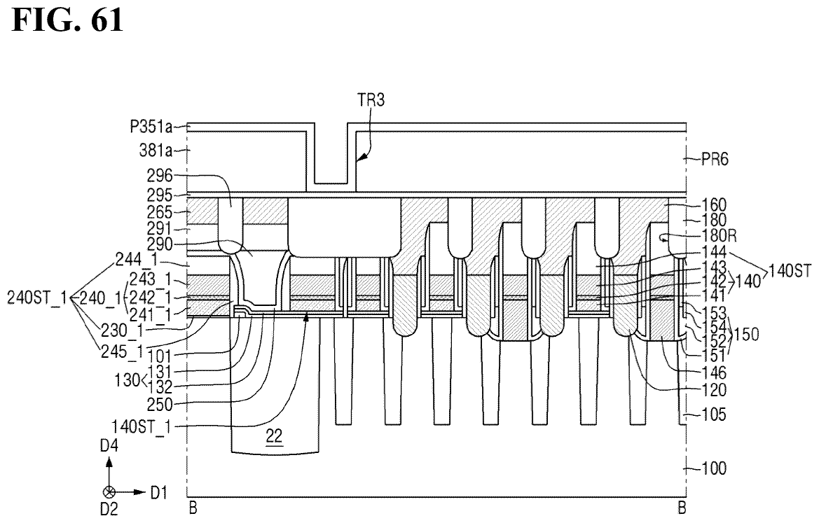

Referring to FIGS. 60 and 61, a first pre-insulating layer P351a is formed on the second interlayer insulating layer 381a and the sixth photoresist layer PR6 on the cell area 20 and the cell element isolation layer 22. At the same time, the first pre-insulating layer P351a is formed on the second interlayer insulating layer 381a on the peripheral area 24. For example, the first pre-insulating layer P351a may be formed of or include silicon carbonitride (SiCN).

The first pre-insulating layer P351a may be conformally formed along an upper surface of the second interlayer insulating layer 381a, sidewalls and a bottom surface of the third trench TR3, and an upper surface of the sixth photoresist layer PR6. Accordingly, a width W1 (see FIG. 10) of a barrier structure 351b, which will be described later, in the first direction D1 may be substantially equal to a thickness T1 (see FIG. 10) of a first insulating layer 351a on the cell element isolation layer 22 in the fourth direction D4.

The second peripheral wiring line 361 may be formed in the first pre-insulating layer P351a. For example, the first pre-insulating layer P351a may be formed of or include silicon carbonitride (SiCN).

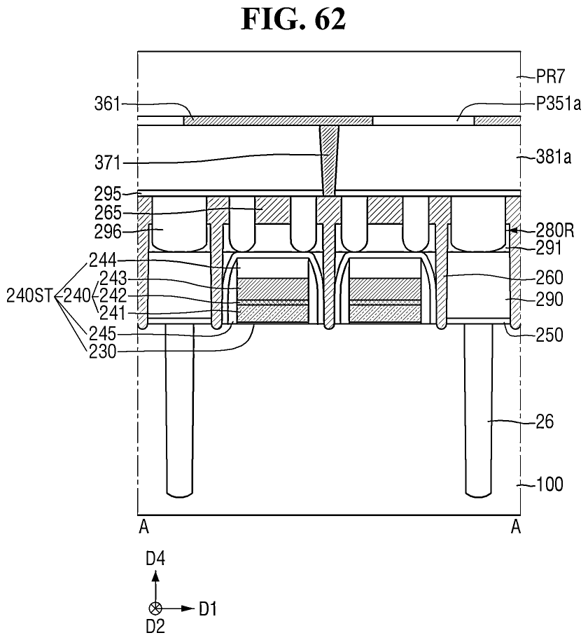

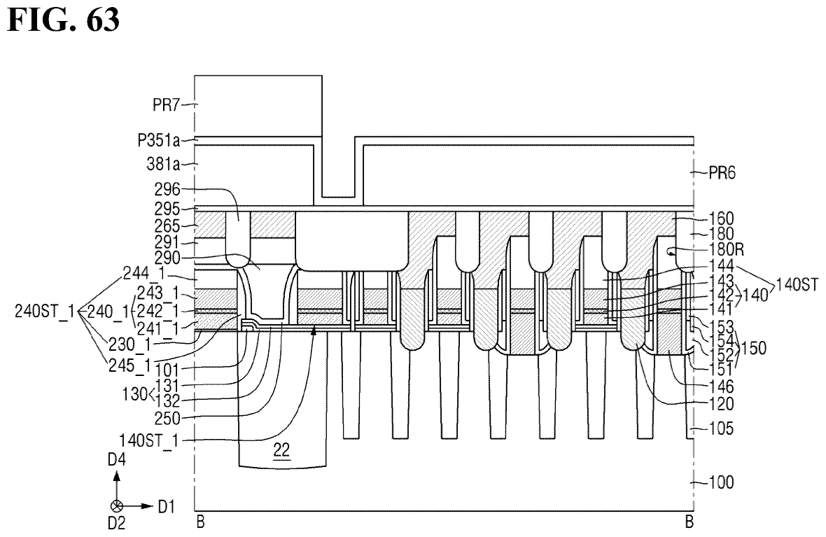

Referring to FIGS. 62 and 63, a seventh photoresist layer PR7 is formed on the first pre-insulating layer P351a on the peripheral area 24 and the cell element isolation layer 22. The first pre-insulating layer P351a of the cell area 20 may be exposed.

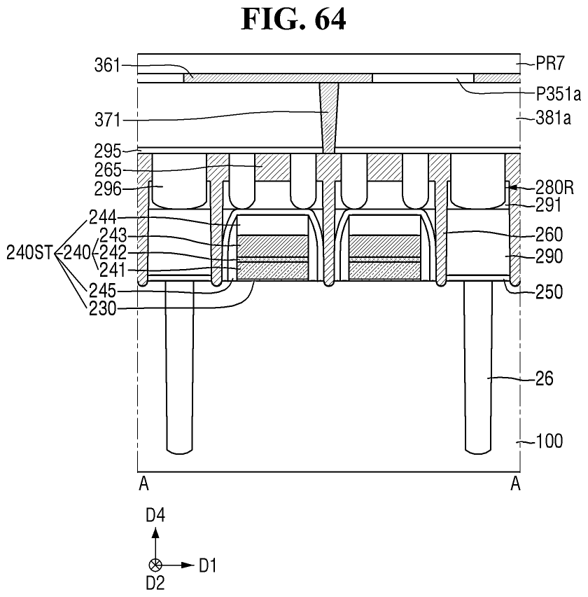

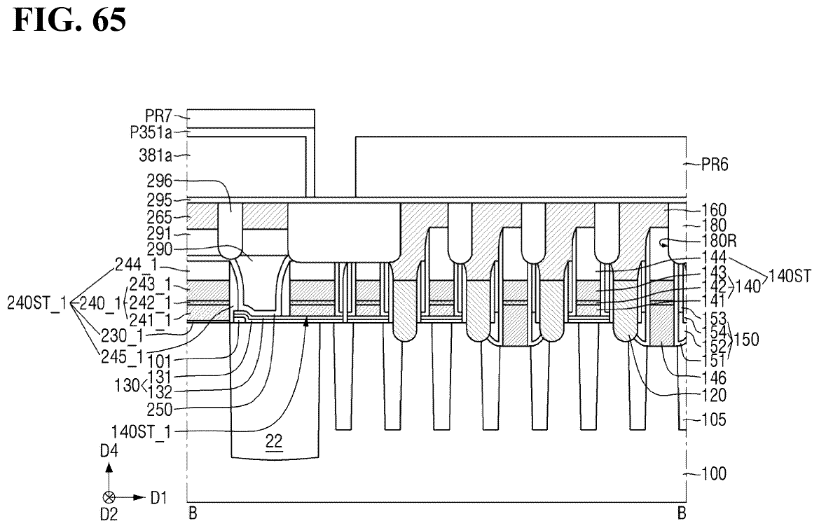

Referring to FIGS. 64 and 65, the first pre-insulating layer P351a of the cell area 20 is selectively removed using the seventh photoresist layer PR7, and the first pre-insulating layer P351a on the peripheral area 24 and the cell element isolation layer 22 is left unremoved. The selective removal of the first pre-insulating layer P351a of the cell area 20 may be performed using an etch-back process.

Accordingly, an upper surface of the upper etch stop layer 295 between the sixth photoresist layer PR6 and the second interlayer insulating layer 381a, a sidewall of the first pre-insulating layer P351a, a sidewall of the sixth photoresist layer PR6, and a sidewall of the seventh photoresist layer PR7 may be exposed.

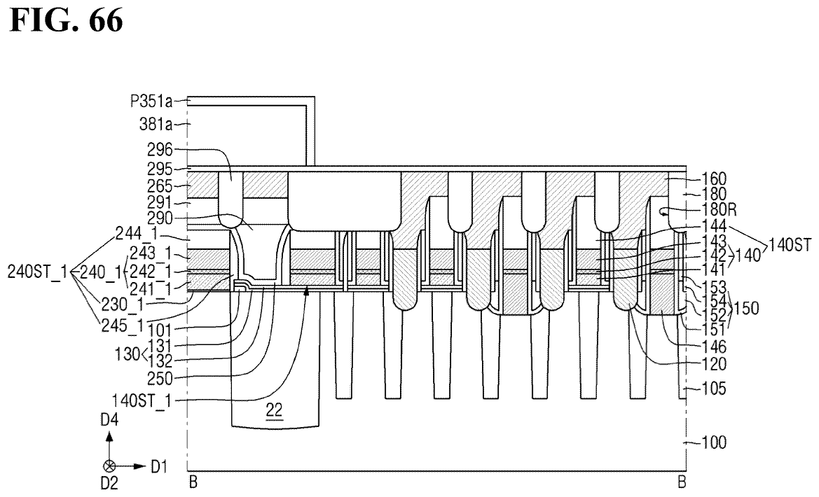

Referring to FIG. 66, the sixth photoresist layer PR6 on the cell area 20 and the seventh photoresist layer PR7 on the cell area 20 and the cell element isolation layer 22 are removed.

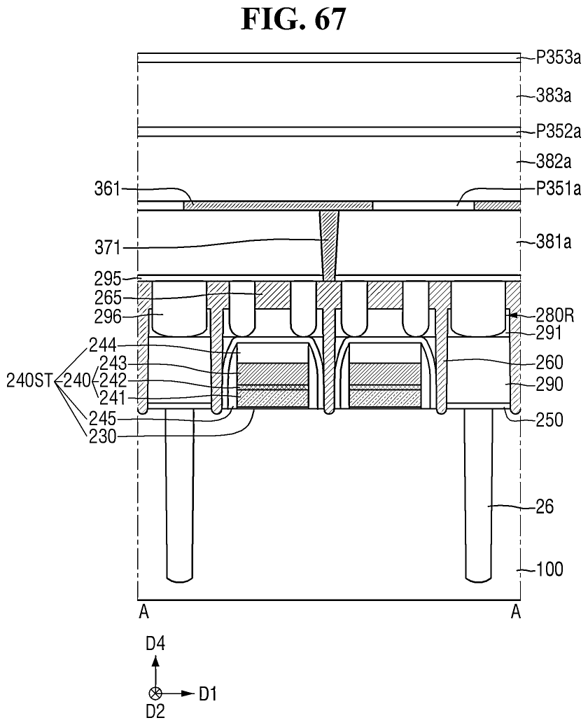

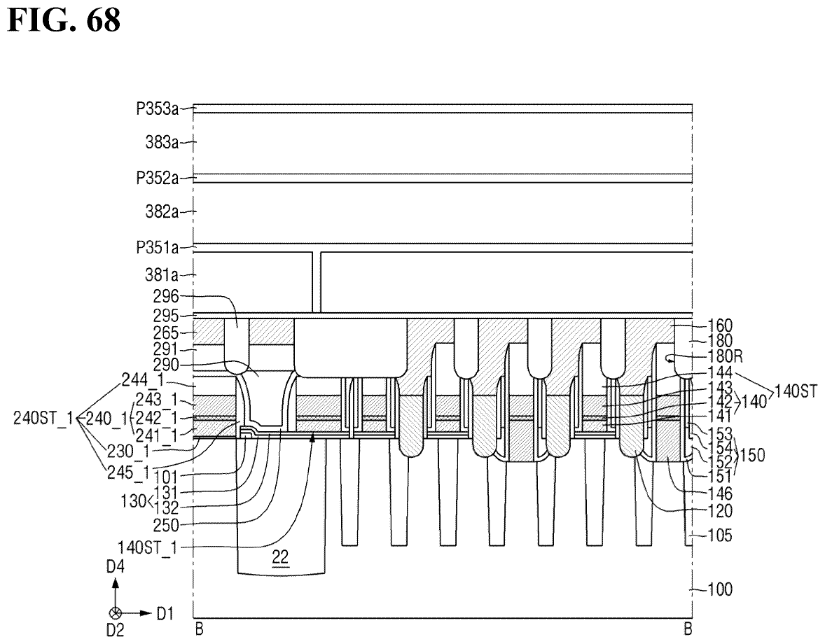

Referring to FIGS. 67 and 68, the second interlayer insulating layer 381a and the first pre-insulating layer P351a are formed on the cell area 20. The first pre-insulating layer P351a may be interposed between the second interlayer insulating layer 381a on the cell element isolation layer 22 and the second interlayer insulating layer 381a on the cell area 20. The first pre-insulating layer P351a may be formed on the upper surface of the second interlayer insulating layer 381a on the cell element isolation layer 22 and on the upper surface of the second interlayer insulating layer 381a on the cell area 20.

Next, a fourth interlayer insulating layer 382a, a second pre-insulating layer P352a, a fifth interlayer insulating layer 383a, and a third pre-insulating layer P353a are sequentially formed on the first pre-insulating layer P351a on the cell area 20 and the cell element isolation layer 22.

At the same time, the fourth interlayer insulating layer 382a, the second pre-insulating layer P352a, the fifth interlayer insulating layer 383a, and the third pre-insulating layer 353a are sequentially formed on the first pre-insulating layer P351a on the peripheral area 24.

For example, the second pre-insulating layer P352a and the third pre-insulating layer P353a may be formed of or include silicon carbonitride (SiCN). For example, the fourth interlayer insulating layer 382a and the fifth interlayer insulating layer 383a may be formed of or include silicon oxide.

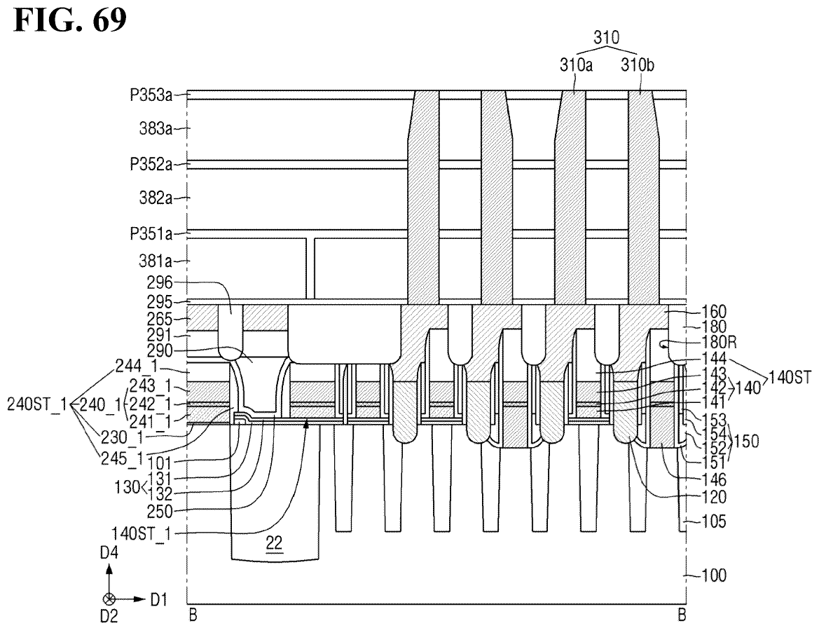

Referring to FIG. 69, first and second trenches may be formed to penetrate the upper etch stop layer 295, the second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a.

Next, first and second lower electrodes 310a and 310b may be formed in the first and second trenches, respectively. For example, the first and second lower electrodes 310a and 310b may include titanium nitride (TiN).

The first and second lower electrodes 310a and 310b may be formed on storage pads 160.

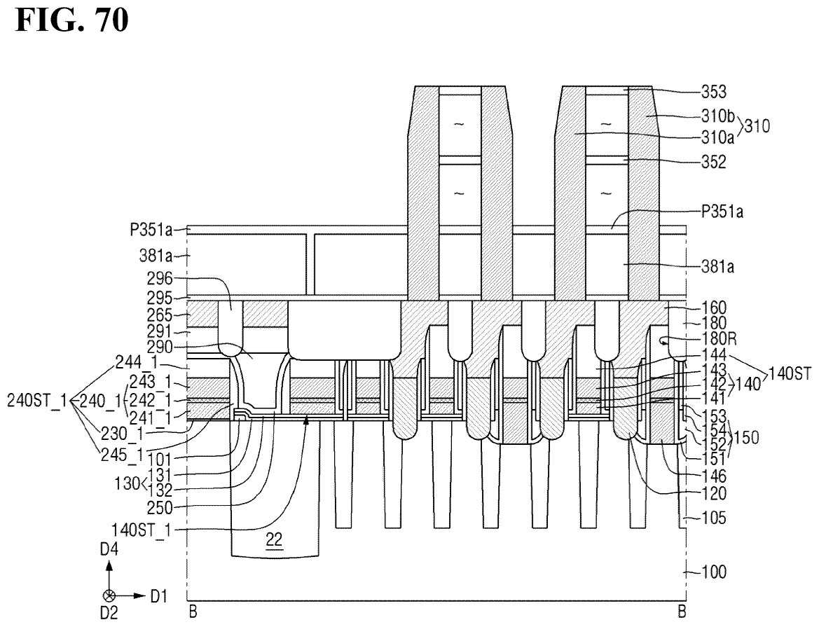

Referring to FIG. 70, the fourth interlayer insulating layer 382a, the second pre-insulating layer P352a, the fifth interlayer insulating layer 383a, and the third pre-insulating layer P353a may be patterned to form second and third support layers 352 and 353.

The fifth interlayer insulating layer 383a may be removed through areas where the third support layer 353 is not formed. The fourth interlayer insulating layer 382a may be removed through areas where the second support layer 352 is not formed.

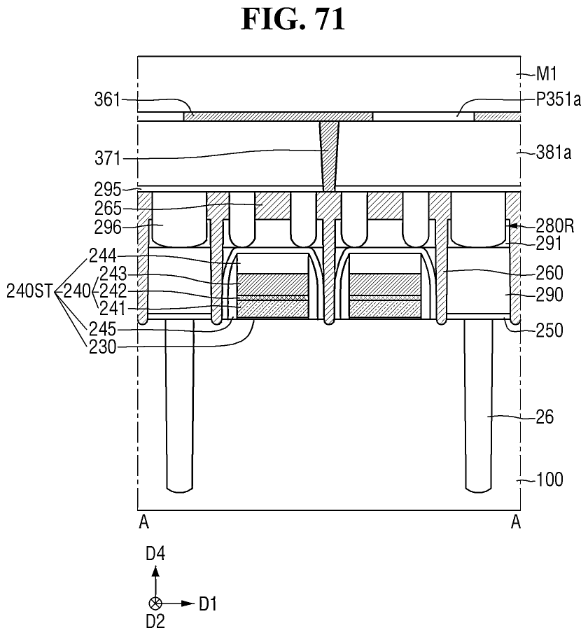

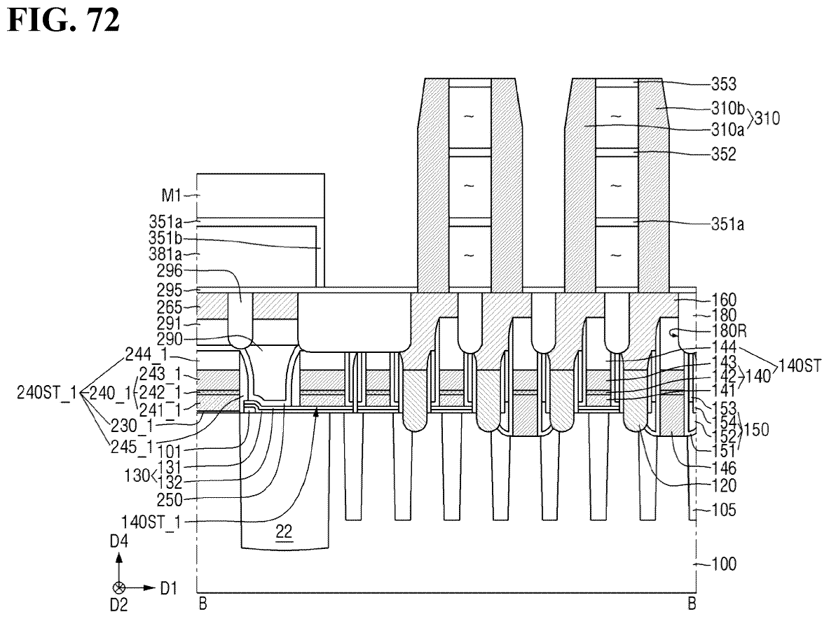

Referring to FIGS. 71 and 72, a mask MI may be formed on the first pre-insulating layer P351a on the peripheral area 24 and the cell element isolation layer 22.

A first support layer 351 may be formed by patterning the second interlayer insulating layer 381a and the first pre-insulating layer P351a. The second interlayer insulating layer 381a and the first pre-insulating layer P351a may be at least partially removed through areas where the first support layer 351 is not formed. At least a portion of the first pre-insulating layer P351a may be removed to expose a sidewall of the barrier structure 351b. A first sidewall of the barrier structure 351b may contact a sidewall of the second interlayer insulating layer 381a, and a second sidewall may be exposed.

Next, the mask MI is removed.

Through the above process, the first through third support layers 351 through 353 connecting adjacent first and second lower electrodes 310a and 310b may be formed.

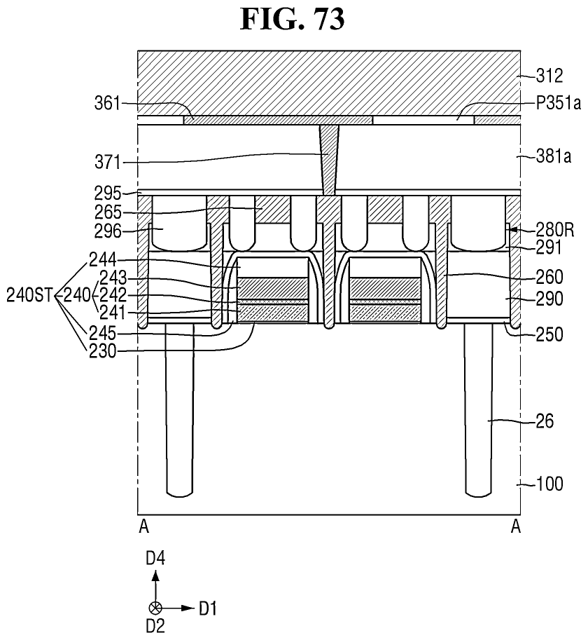

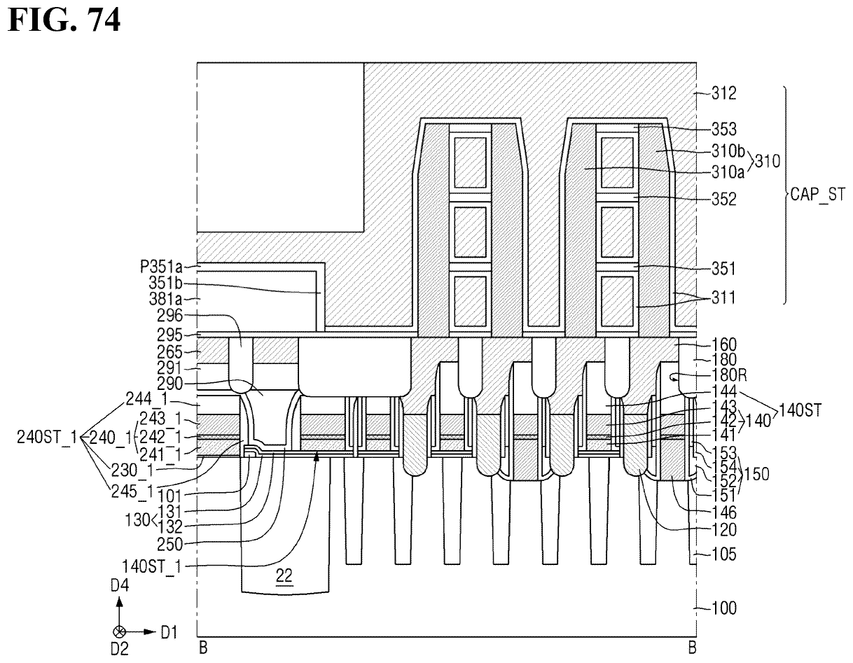

Referring to FIGS. 73 and 74, a capacitor dielectric layer 311 may be formed. The capacitor dielectric layer 311 may be formed on a pad isolation insulating layer 180, the storage pads 160, the lower electrodes 310, and the first through third support layers 351 through 353. The capacitor dielectric layer 311 may extend along upper surfaces of the pad isolation insulating layer 180 and the storage pads 160. The capacitor dielectric layer 311 may be formed to contact the second sidewall of the barrier structure 351b.

Next, an upper electrode 312 may be formed. The upper electrode 312 may be formed on the capacitor dielectric layer 311. The upper electrode 312 may extend between lower electrodes 310 that are not connected by the first through third support layers 351 through 353. For example, the upper electrode 312 may be made of silicon germanium (SiGe). The upper electrode 312 may be formed to contact the second sidewall of the barrier structure 351b.

Through the above process, a capacitor structure CAP_ST may be formed.

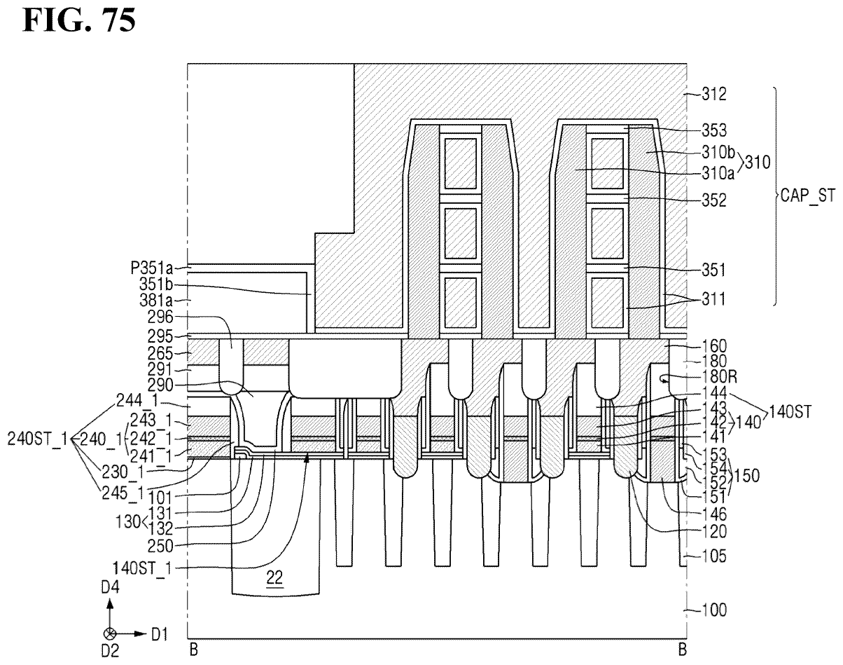

Referring to FIG. 75, the upper electrode 312 on the peripheral area 24 and the cell element isolation layer 22 may be removed.

Although not specifically illustrated, a mask may be formed on the capacitor structure CAP_ST on the cell area 20. The upper electrode 312 on the peripheral area 24 and the cell element isolation layer 22 on which the mask is not formed may be removed.

Next, referring also to FIG. 10, a third interlayer insulating layer 481 may be formed on the first pre-insulating layer P351a. The third interlayer insulating layer 481 may be formed on the upper electrode 312. The third interlayer insulating layer 481 may cover the upper electrode 312.

The upper electrode 312 partially covering an upper surface of the first pre-insulating layer P351a may be removed. Accordingly, a sidewall of the second interlayer insulating layer 381a, a sidewall of the first insulating layer 351a, and the second sidewall of the barrier structure 351b may be aligned with a sidewall of the upper electrode 312.

A cell contact plug 410 connected to the upper electrode 312 may be formed on the cell area 20. A third peripheral contact plug 471 connected to the second peripheral wiring line 361 may be formed on the peripheral area 24.

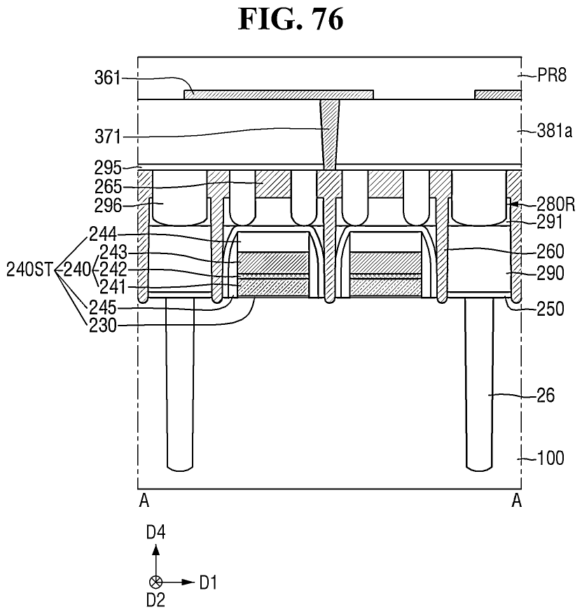

FIGS. 76 through 90 are views illustrating intermediate steps of a method of fabricating a semiconductor memory device according to embodiments. A description of the same elements and features as those described using FIG. 11 will be given briefly or omitted.

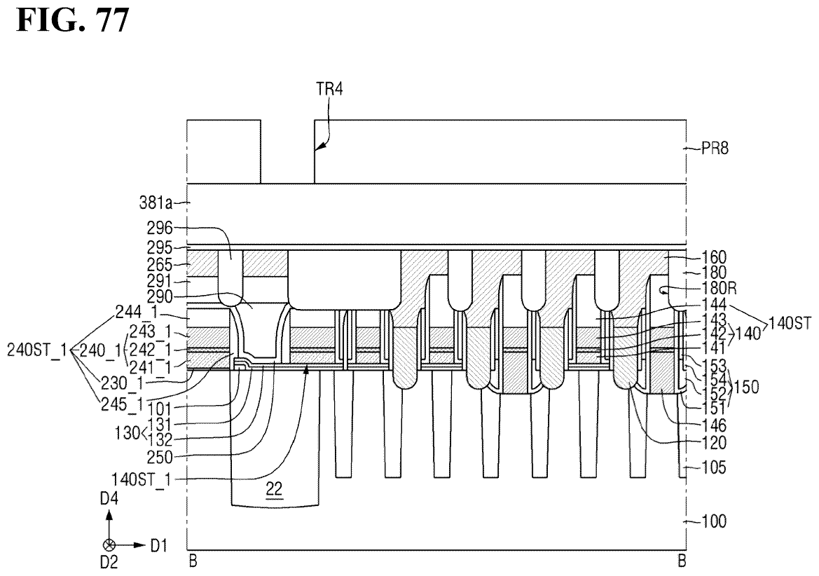

For reference, FIGS. 76 through 90 are views illustrating a method of fabricating the semiconductor memory device illustrated in FIG. 11. In addition, FIGS. 76 and 77 may be understood as drawings illustrating a fabrication method after FIGS. 27 and 28.

Referring to FIGS. 76 and 77, after a second photoresist layer PR2 (see FIGS. 27 and 28) is removed, an eighth photoresist layer PR8 is formed on a second interlayer insulating layer 381a on a peripheral area 24 where a second peripheral wiring line 361 is formed. The eighth photoresist layer PR8 is formed on the second interlayer insulating layer 381a on a cell area 20 and a cell element isolation layer 22. A fourth trench TR4 exposing a portion of an upper surface of the second interlayer insulating layer 381a may be formed between the eighth photoresist layer PR8 on the cell element isolation layer 22 and the eighth photoresist layer PR8 of the cell area 20.

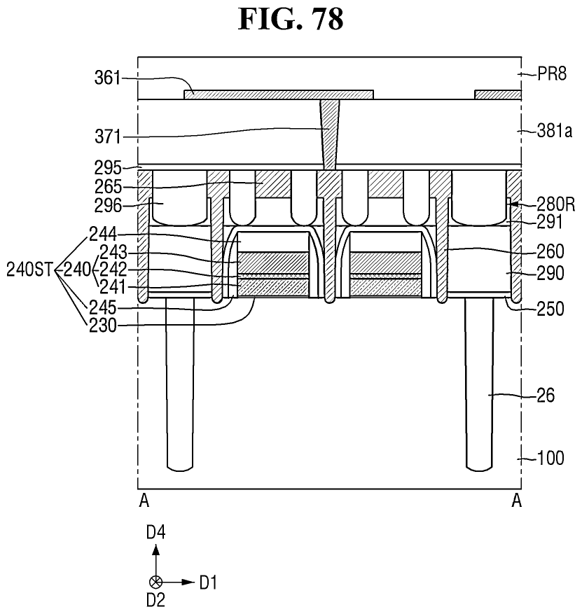

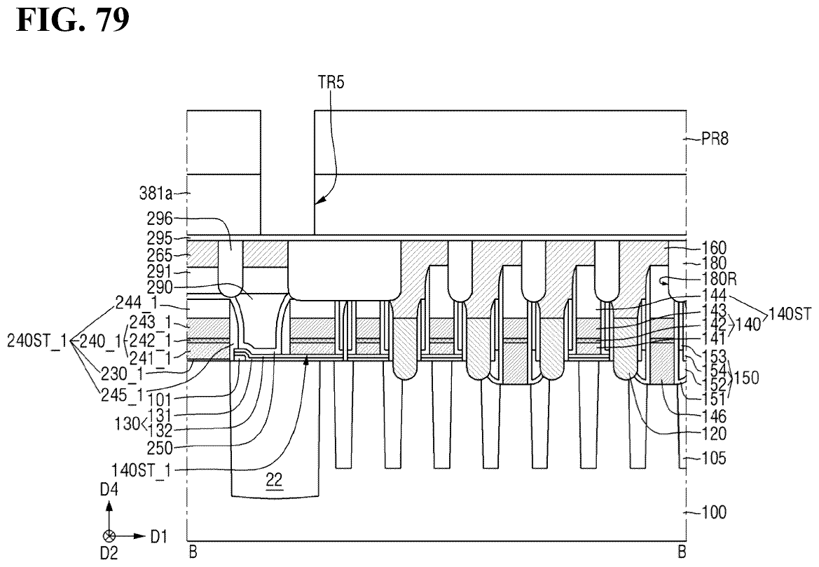

Referring to FIGS. 78 and 79, the second interlayer insulating layer 381a is etched using the eighth photoresist layer PR8 on the cell element isolation layer 22. As the second interlayer insulating layer 381a is removed, a fifth trench TR5 may be formed to expose an upper etch stop layer 295.

Next, the eighth photoresist layer PR8 is removed.

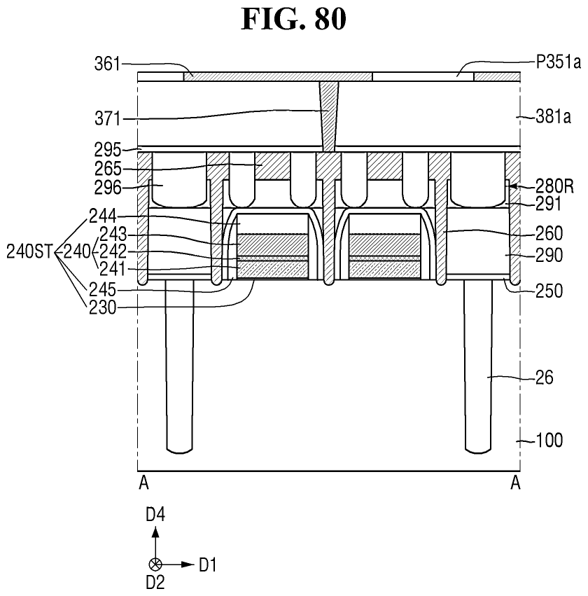

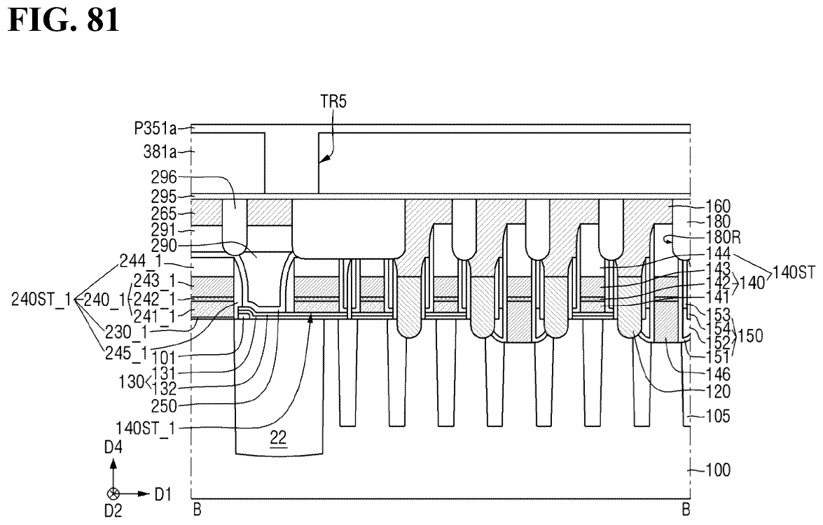

Referring to FIGS. 80 and 81, a first pre-insulating layer P351a is formed on the second interlayer insulating layer 381a on the cell area 20 and the cell element isolation layer 22. At the same time, the first pre-insulating layer P351a is formed on the second interlayer insulating layer 381a on the peripheral area 24. For example, the first pre-insulating layer P351a may be formed of or include silicon carbonitride (SiCN).

The first pre-insulating layer P351a may fill the fifth trench TR5. The first pre-insulating layer P351a may be formed on the upper surface of the second interlayer insulating layer 381a and sidewalls and a bottom surface of the fifth trench TR5 in a bottom-up manner. Accordingly, a width W2 (see FIG. 11) of a barrier structure 351b, which will be described later, in the first direction D1 may be greater than a thickness T2 (see FIG. 11) of a first insulating layer 351a on the cell element isolation layer 22 in the fourth direction D4.

The second peripheral wiring line 361 may be formed in the first pre-insulating layer P351a. For example, the first pre-insulating layer P351a may be formed of or include silicon carbonitride (SiCN).

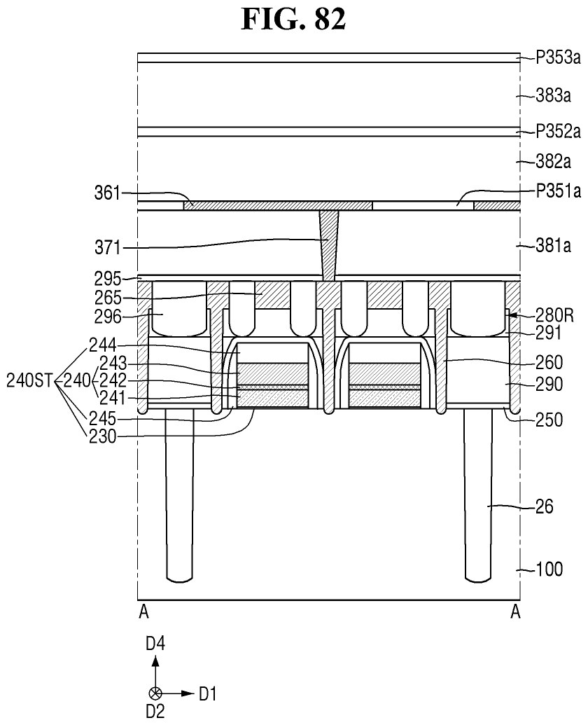

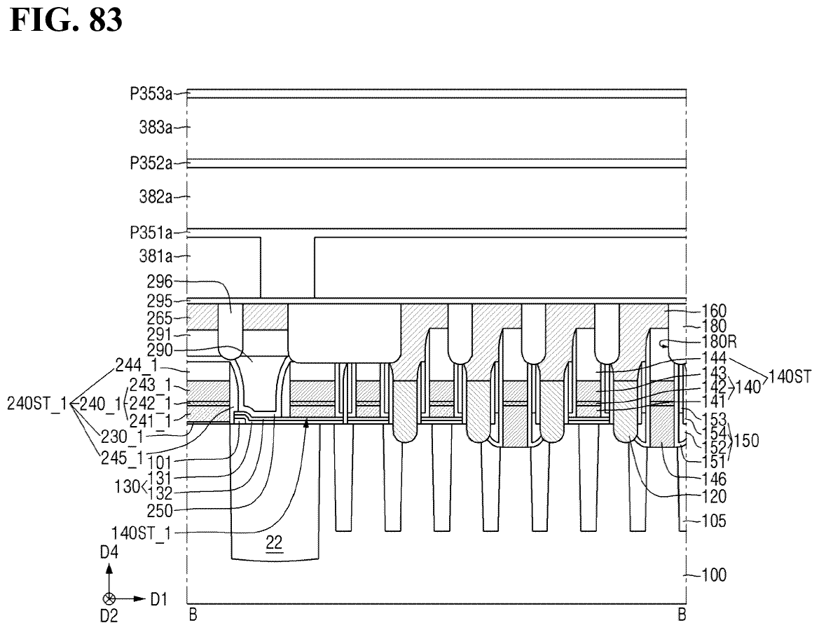

Referring to FIGS. 82 and 83, a fourth interlayer insulating layer 382a, a second pre-insulating layer P352a, a fifth interlayer insulating layer 383a, and a third pre-insulating layer P353a are sequentially formed on the first pre-insulating layer P351a on the cell area 20 and the cell element isolation layer 22.

At the same time, the fourth interlayer insulating layer 382a, the second pre-insulating layer P352a, the fifth interlayer insulating layer 383a, and the third pre-insulating layer P353a are sequentially formed on the first pre-insulating layer P351a on the peripheral area 24.

For example, the second pre-insulating layer P352a and the third pre-insulating layer P353a may be formed of or include silicon carbonitride (SiCN). For example, the fourth interlayer insulating layer 382a and the fifth interlayer insulating layer 383a may be formed of or include silicon oxide.

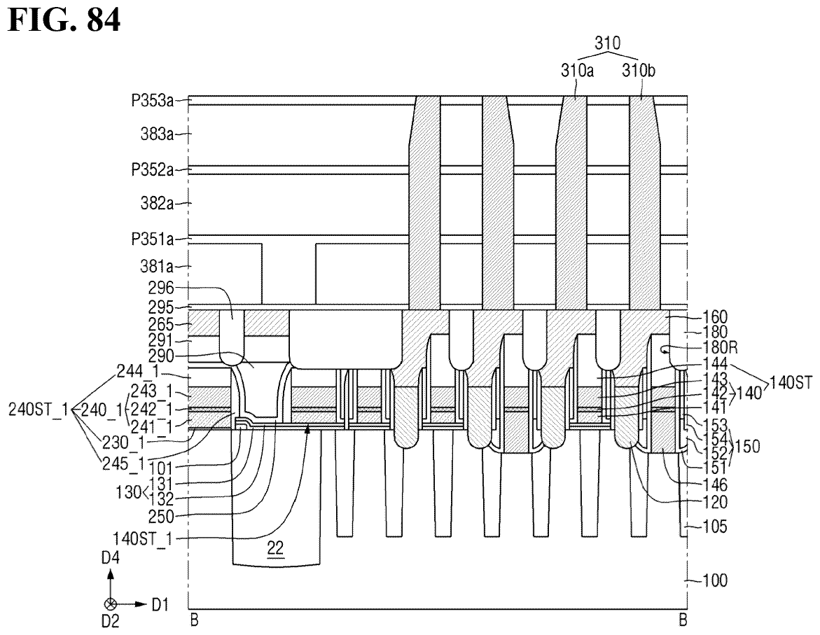

Referring to FIG. 84, first and second trenches may be formed to penetrate the upper etch stop layer 295, the second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a.

Next, first and second lower electrodes 310a and 310b may be formed in the first and second trenches, respectively. For example, the first and second lower electrodes 310a and 310b may be formed of or include titanium nitride (TiN).

The first and second lower electrodes 310a and 310b may be formed on storage pads 160.

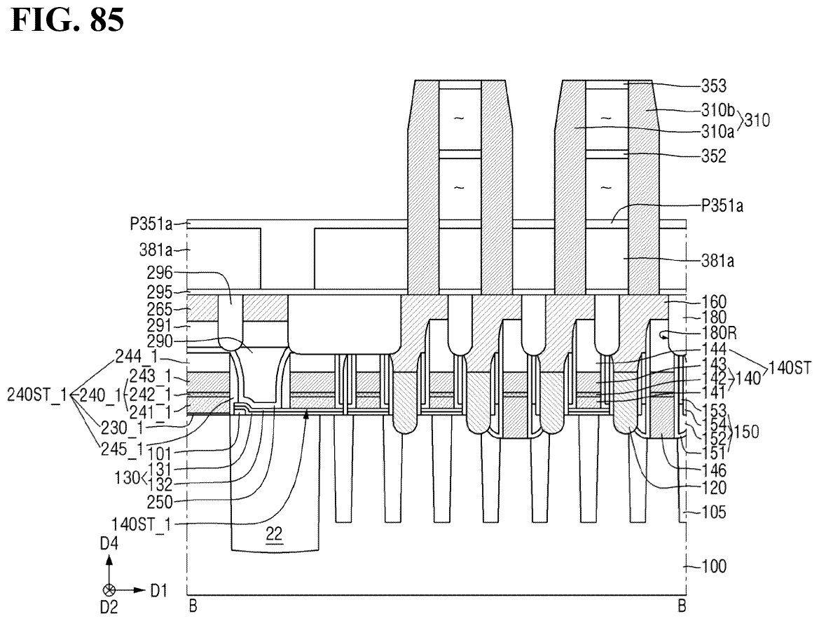

Referring to FIG. 85, the fourth interlayer insulating layer 382a, the second pre-insulating layer P352a, the fifth interlayer insulating layer 383a, and the third pre-insulating layer P353a may be patterned to form second and third support layers 352 and 353.

The fifth interlayer insulating layer 383a may be removed through areas where the third support layer 353 is not formed. The fourth interlayer insulating layer 382a may be removed through areas where the second support layer 352 is not formed.

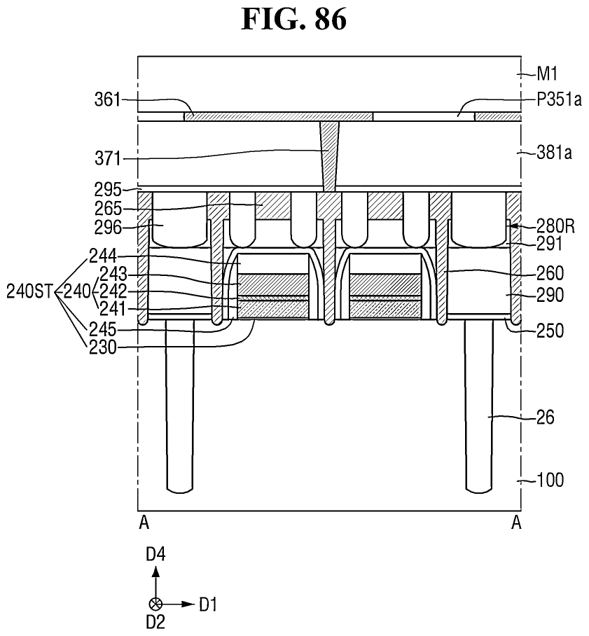

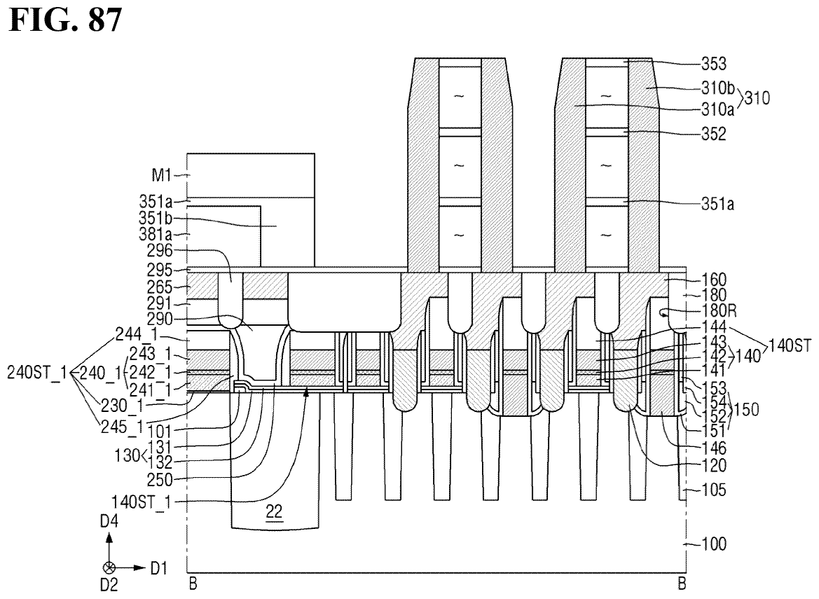

Referring to FIGS. 86 and 87, a mask MI may be formed on the first pre-insulating layer P351a on the peripheral area 24 and the cell element isolation layer 22.

A first support layer 351 may be formed by patterning the second interlayer insulating layer 381a and the first pre-insulating layer P351a. The second interlayer insulating layer 381a and the first pre-insulating layer P351a may be at least partially removed through areas where the first support layer 351 is not formed. At least a portion of the first pre-insulating layer P351a may be removed to expose a sidewall of the barrier structure 351b. A first sidewall of the barrier structure 351b may contact a sidewall of the second interlayer insulating layer 381a, and a second sidewall may be exposed.

Next, the mask MI is removed.

Through the above process, the first through third support layers 351 through 353 connecting adjacent first and second lower electrodes 310a and 310b may be formed.

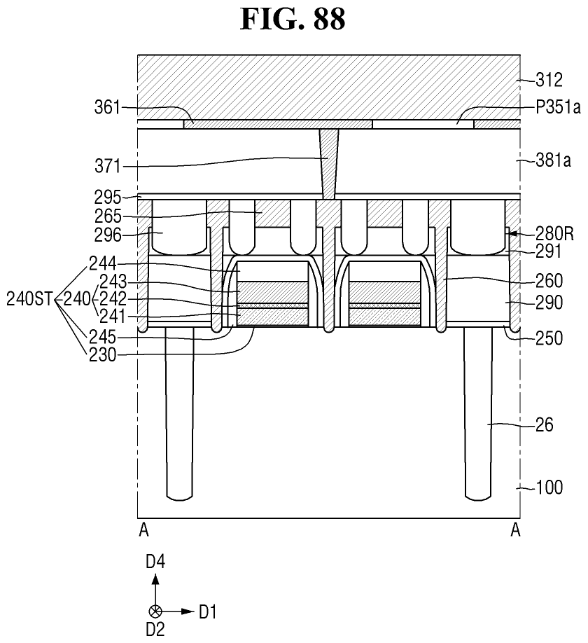

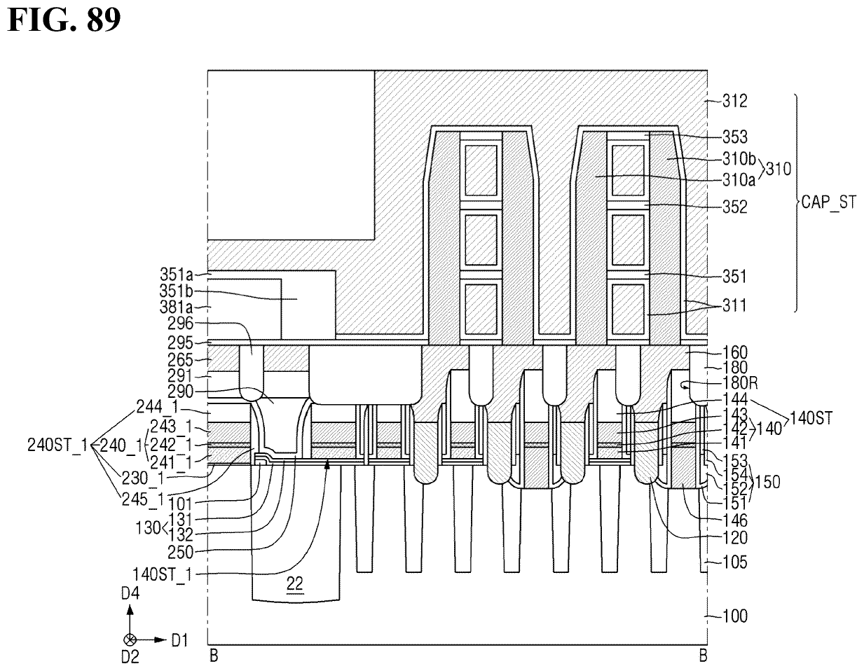

Referring to FIGS. 88 and 89, a capacitor dielectric layer 311 may be formed. The capacitor dielectric layer 311 may be formed on a pad isolation insulating layer 180, the storage pads 160, the lower electrodes 310, and the first through third support layers 351 through 353. The capacitor dielectric layer 311 may extend along upper surfaces of the pad isolation insulating layer 180 and the storage pads 160. The capacitor dielectric layer 311 may be formed to contact the second sidewall of the barrier structure 351b.

Next, an upper electrode 312 may be formed. The upper electrode 312 may be formed on the capacitor dielectric layer 311. The upper electrode 312 may extend between lower electrodes 310 that are not connected by the first through third support layers 351 through 353. For example, the upper electrode 312 may be made of silicon germanium (SiGe). The upper electrode 312 may be formed to contact the second sidewall of the barrier structure 351b.

Through the above process, a capacitor structure CAP_ST may be formed.

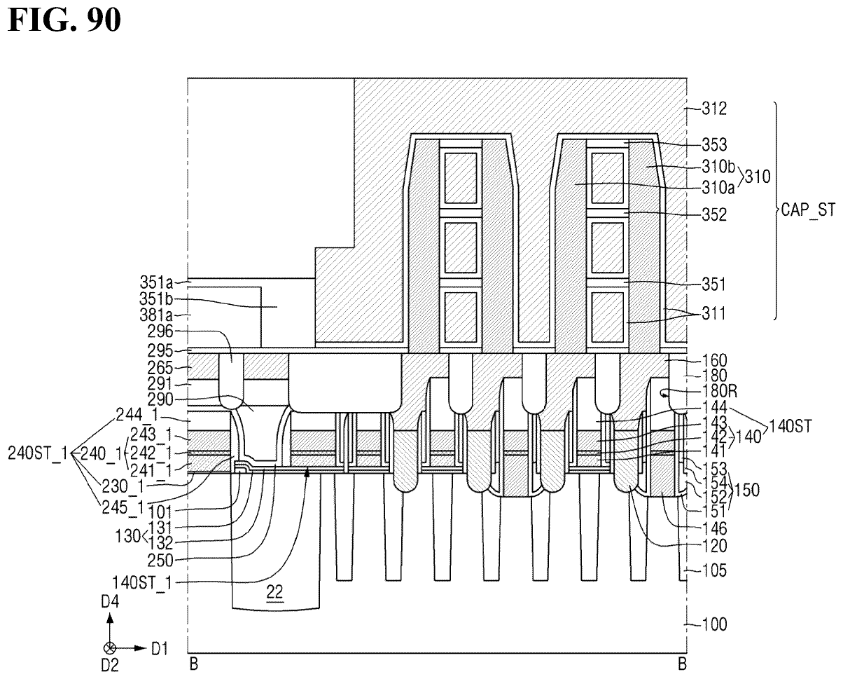

Referring to FIG. 90, the upper electrode 312 on the peripheral area 24 and the cell element isolation layer 22 may be removed.

Although not specifically illustrated, a mask may be formed on the capacitor structure CAP_ST in the cell area 20. The upper electrode 312 on the peripheral area 24 and the cell element isolation layer 22 on which the mask is not formed may be removed.

Next, referring also to FIG. 11, a third interlayer insulating layer 481 may be formed on the first pre-insulating layer P351a. The third interlayer insulating layer 481 may be formed on the upper electrode 312. The third interlayer insulating layer 481 may cover the upper electrode 312.

The upper electrode 312 partially covering an upper surface of the first pre-insulating layer P351a may be removed. Accordingly, a sidewall of the second interlayer insulating layer 381a, a sidewall of the first insulating layer 351a, and the second sidewall of the barrier structure 351b may be aligned with a sidewall of the upper electrode 312.

A cell contact plug 410 connected to the upper electrode 312 may be formed on the cell area 20. A third peripheral contact plug 471 connected to the second peripheral wiring line 361 may be formed on the peripheral area 24.

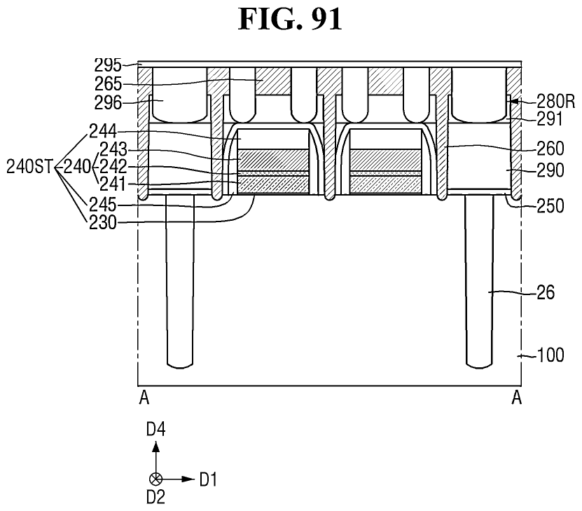

FIGS. 91 through 110 are views illustrating intermediate steps of a method of fabricating a semiconductor memory device according to embodiments. A description of the same elements and features as those described using FIGS. 12 and 13 will be given briefly or omitted.

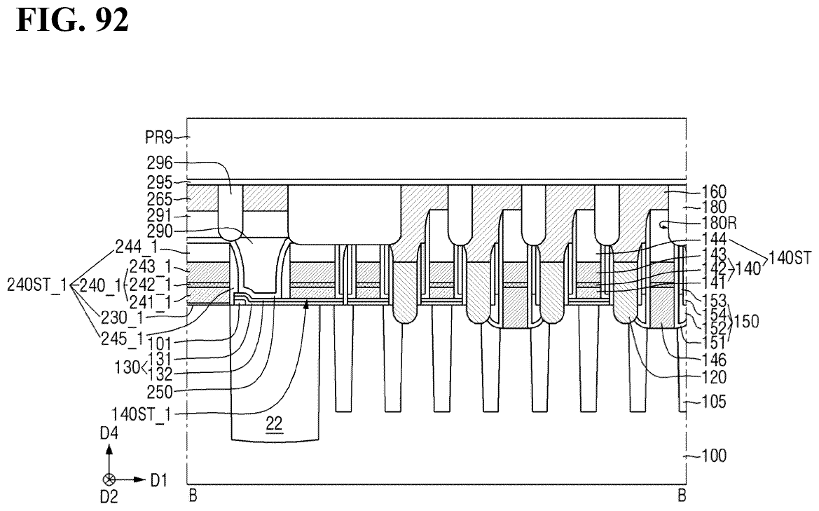

For reference, FIGS. 91 through 110 are views illustrating a method of fabricating the semiconductor memory device illustrated in FIGS. 12 and 13. In addition, FIGS. 91 and 92 may be understood as drawings illustrating a fabrication method after FIGS. 21 and 22.

Referring to FIGS. 91 and 92, a ninth photoresist layer PR9 is formed on an upper etch stop layer 295 on a cell area 20 and a cell element isolation layer 22. The ninth photoresist layer PR9 may not be formed on the upper etch stop layer 295 on a peripheral area 24.

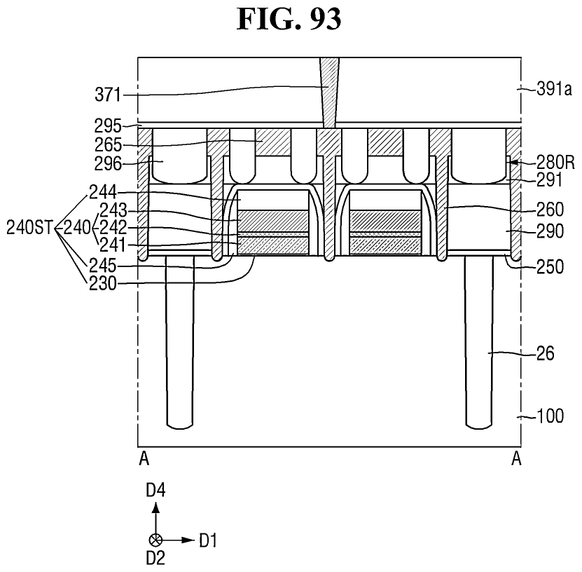

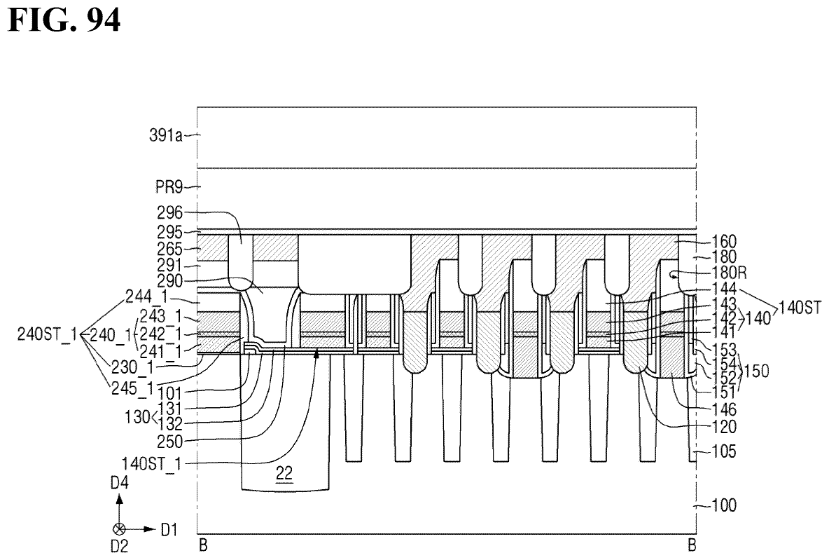

Referring to FIGS. 93 and 94, an intermediate insulating layer 391a is formed on the ninth photoresist layer PR9 on the cell area 20 and the cell element isolation layer 22. The intermediate insulating layer 391a is formed on the upper etch stop layer 295 on the peripheral area 24.

Next, a second peripheral contact plug 371 is formed in the intermediate insulating layer 391a on the peripheral area 24. The second peripheral contact plug 371 may penetrate the intermediate insulating layer 391a of the peripheral area 24 and may be connected to a first peripheral wiring line 265.

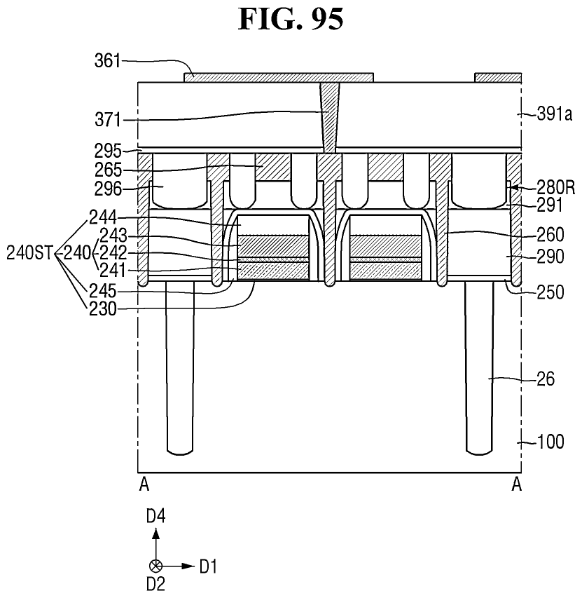

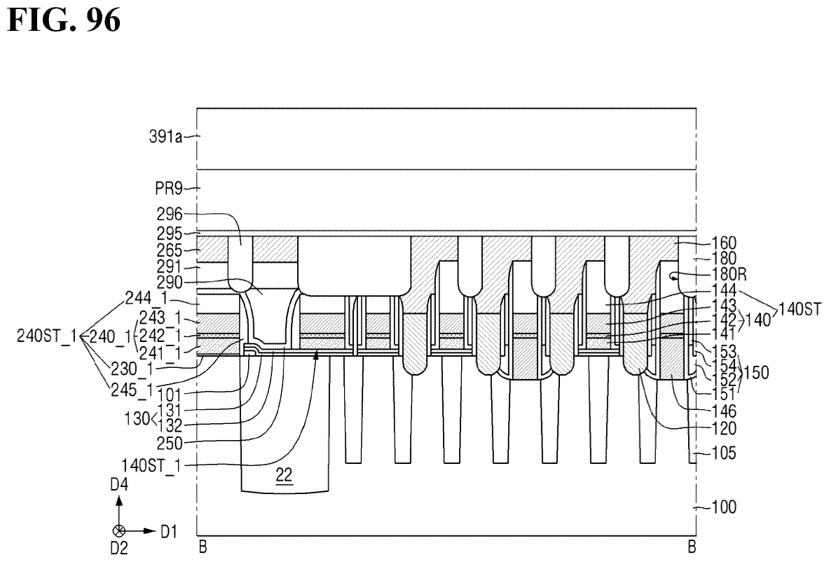

Referring to FIGS. 95 and 96, a second peripheral wiring line 361 connected to the second peripheral contact plug 371 is formed on the intermediate insulating layer 391a on the peripheral area 24.

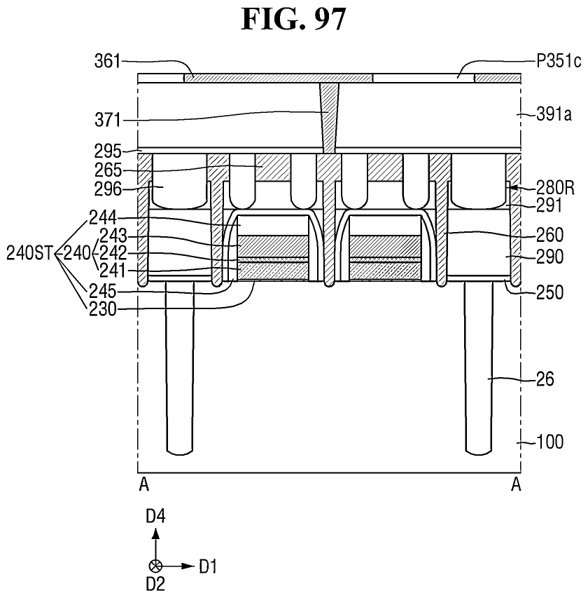

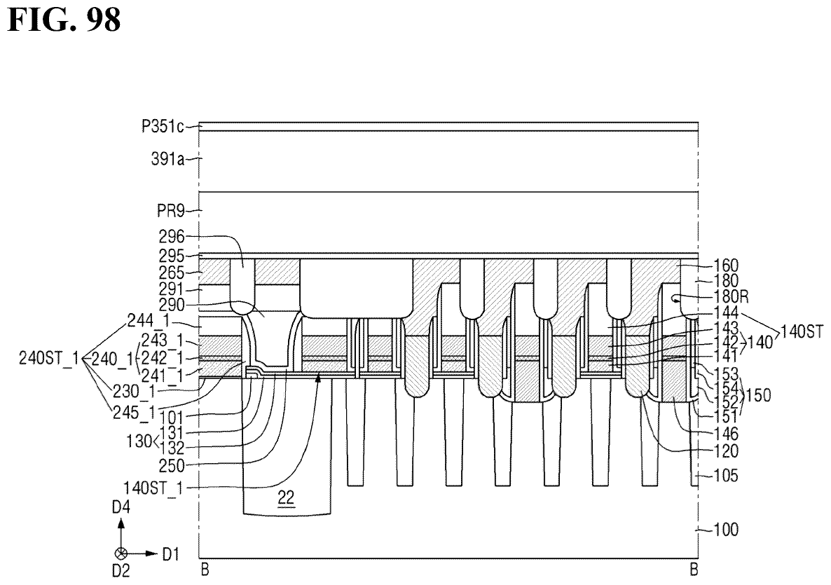

Referring to FIGS. 97 and 98, a pre-lower insulating layer P351c is formed on the intermediate insulating layer 391a on the cell area 20 and the cell element isolation layer 22. At the same time, the pre-lower insulating layer P351c is formed on the intermediate insulating layer 391a on the peripheral area 24. The second peripheral wiring line 361 may be formed in the pre-lower insulating layer P351c and may be spaced apart from other second peripheral wiring lines 361. For example, the pre-lower insulating layer P351c may be formed of or include silicon boron nitride (SiBN).

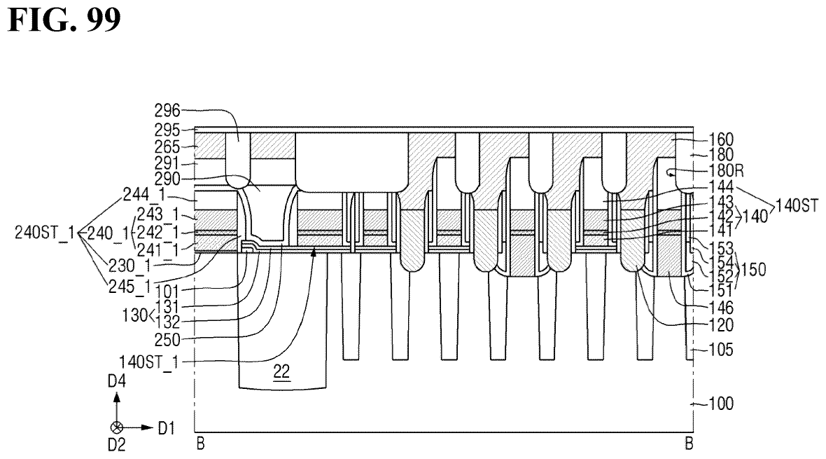

Referring to FIG. 99, the pre-lower insulating layer P351c, the intermediate insulating layer 391a, and the ninth photoresist layer PR9 on the cell area 20 and the cell element isolation layer 22 may be selectively removed to expose the upper etch stop layer 295. The pre-lower insulating layer P351c and the intermediate insulating layer 391a may remain on the peripheral area 24.

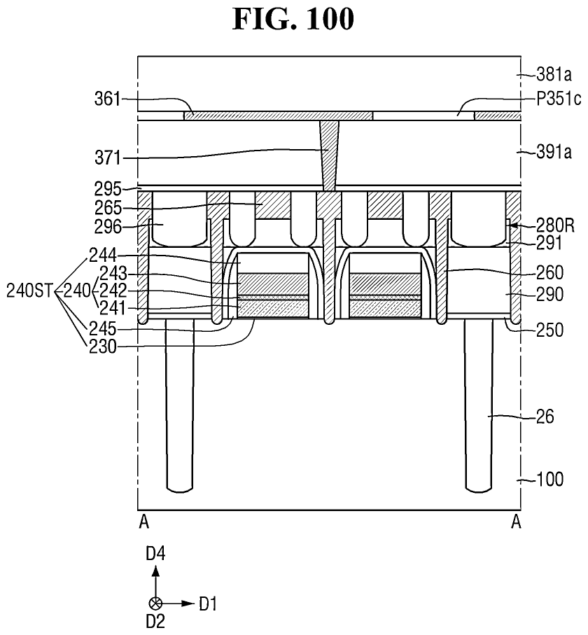

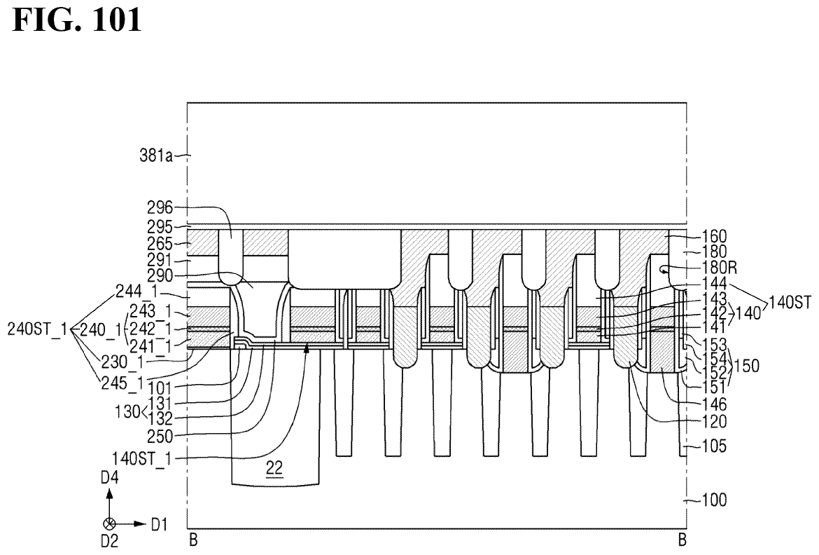

Referring to FIGS. 100 and 101, a second interlayer insulating layer 381a is formed on the upper etch stop layer 295 on the cell area 20 and the cell element isolation layer 22. The second interlayer insulating layer 381a is formed on the pre-lower insulating layer P351c on the peripheral area 24.

Next, an upper surface of the second interlayer insulating layer 381a on the cell area 20 and the cell element isolation layer 22 and an upper surface of the second interlayer insulating layer 381a on the peripheral area 24 may be placed on the same plane by a chemical mechanical polishing (CMP) process.

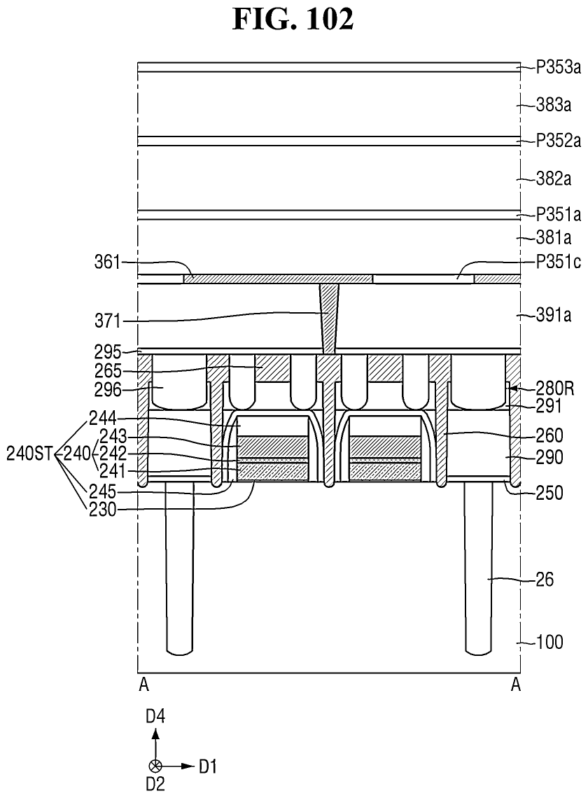

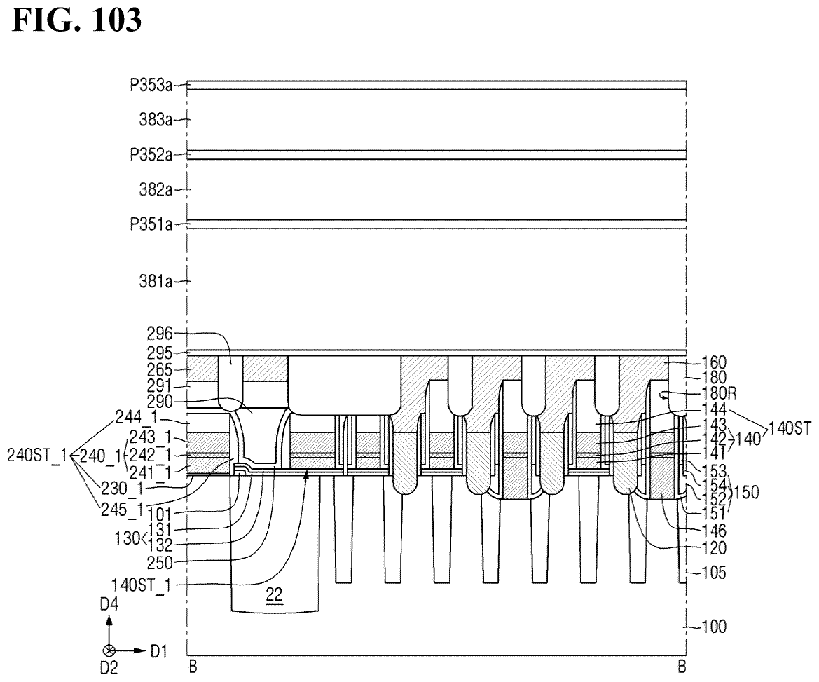

Referring to FIGS. 102 and 103, a first pre-insulating layer P351a, a fourth interlayer insulating layer 382a, a second pre-insulating layer P352a, a fifth interlayer insulating layer 383a, and a third pre-insulating layer P353a are sequentially formed on the second interlayer insulating layer 381a on the cell area 20 and the cell element isolation layer 22.

The second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a are sequentially formed on the pre-lower insulating layer P351c on the peripheral area 24.

For example, the first pre-insulating layer P351a, the second pre-insulating layer P352a, and the third pre-insulating layer P353a may be formed of or include silicon carbonitride (SiCN). For example, the fourth interlayer insulating layer 382a and the fifth interlayer insulating layer 383a may be formed of or include silicon oxide.

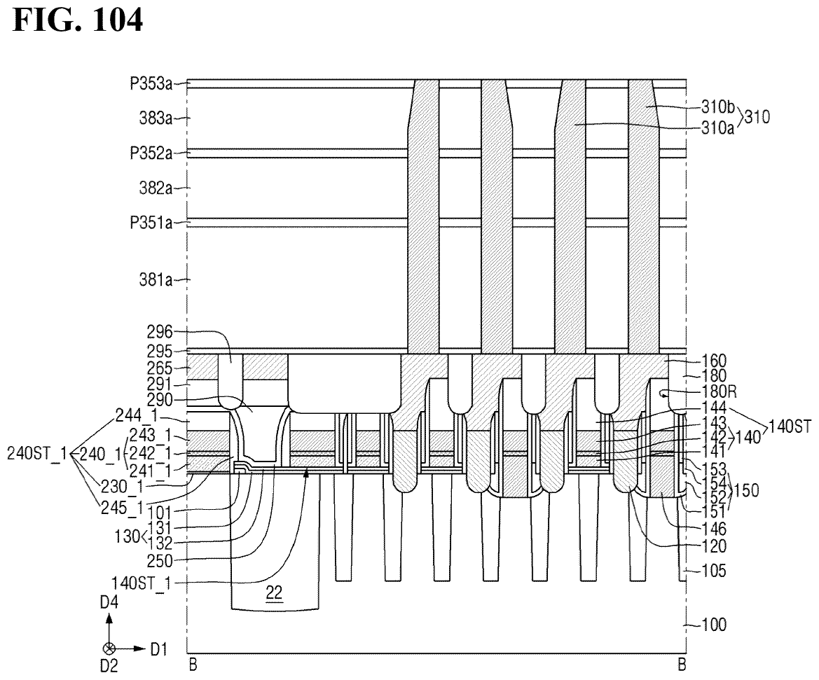

Referring to FIG. 104, first and second trenches may be formed to penetrate the upper etch stop layer 295, the second interlayer insulating layer 381a, the first pre-insulating layer P351a, the fourth interlayer insulating layer 382a, the second pre-insulating layer P352a, the fifth interlayer insulating layer 383a, and the third pre-insulating layer P353a.

Next, first and second lower electrodes 310a and 310b may be formed in the first and second trenches, respectively. For example, the first and second lower electrodes 310a and 310b may be formed of or include titanium nitride (TiN).

The first and second lower electrodes 310a and 310b may be formed on storage pads 160. The first and second lower electrodes 310a and 310b may be connected to the storage pads 160. The first and second lower electrodes 310a and 310b may directly contact the storage pads 160.

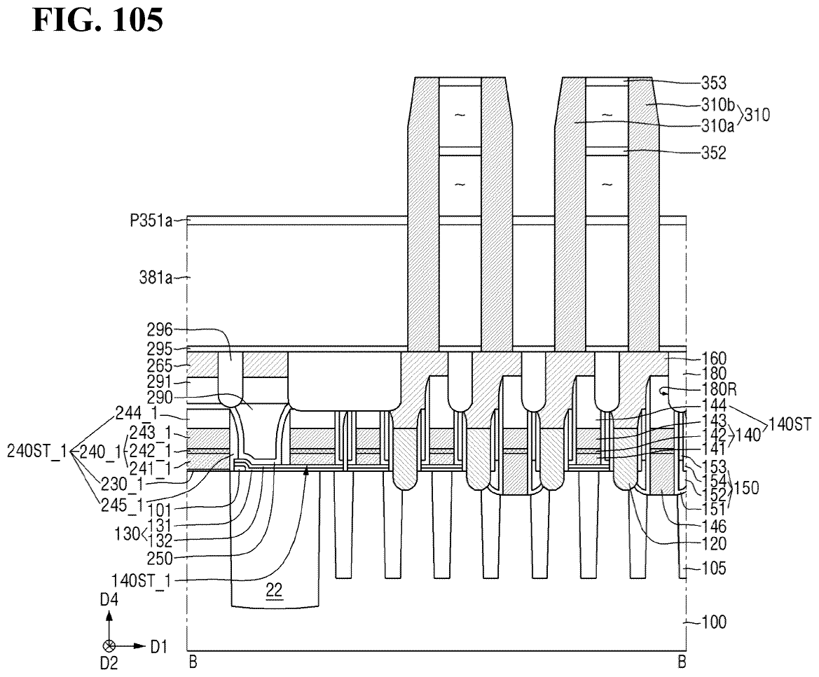

Referring to FIG. 105, the fourth interlayer insulating layer 382a, the second pre-insulating layer P352a, the fifth interlayer insulating layer 383a, and the third pre-insulating layer P353a may be patterned to form second and third support layers 352 and 353.

The fifth interlayer insulating layer 383a may be removed through areas where the third support layer 353 is not formed. The fourth interlayer insulating layer 382a may be removed through areas where the second support layer 352 is not formed.

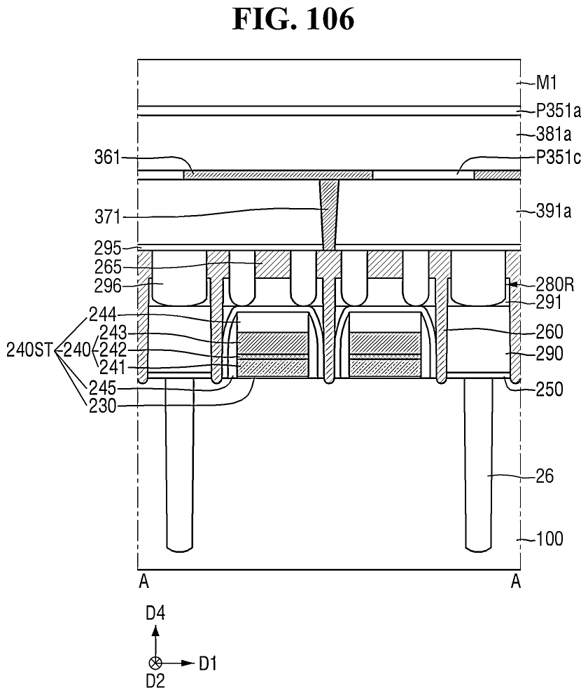

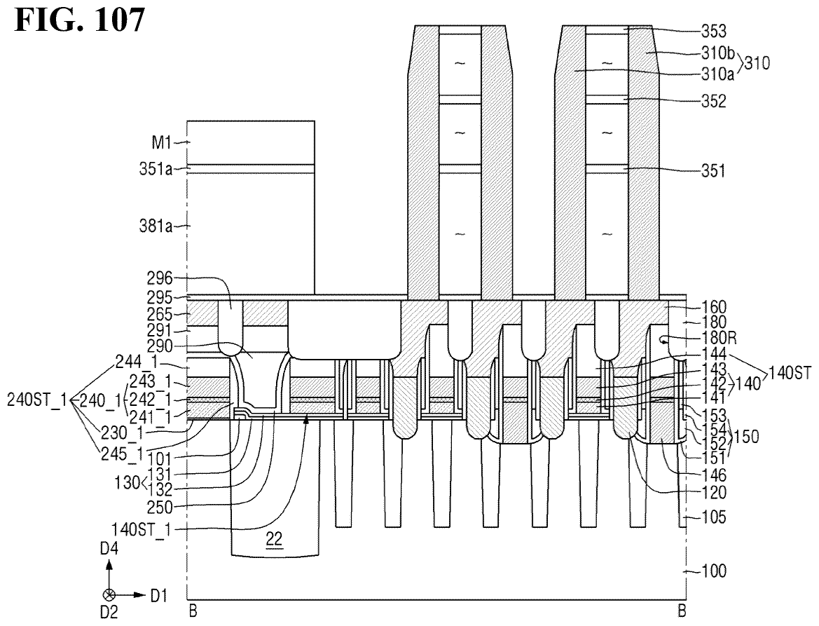

Referring to FIGS. 106 and 107, a mask MI may be formed on the first pre-insulating layer P351a on the peripheral area 24 and the cell element isolation layer 22.

A first support layer 351 may be formed by patterning the second interlayer insulating layer 381a and the first pre-insulating layer P351a. The second interlayer insulating layer 381a may be removed through areas where the first support layer 351 is not formed.

Next, the mask MI is removed.

Through the above process, the first through third support layers 351 through 353 connecting adjacent first and second lower electrodes 310a and 310b may be formed.

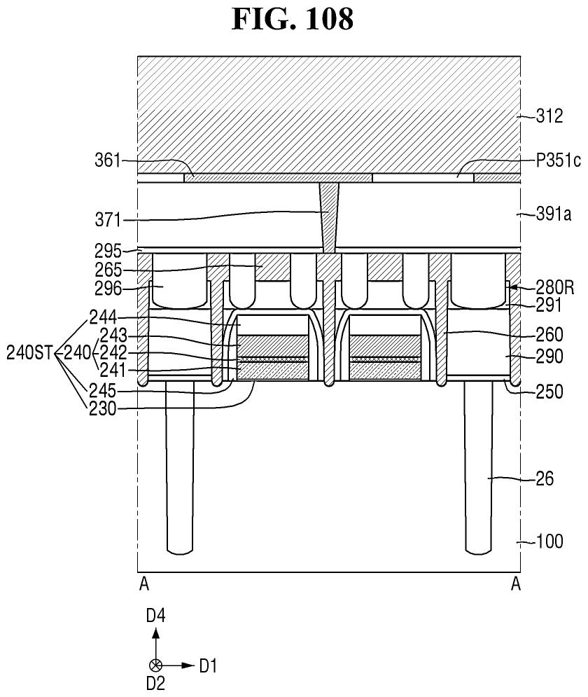

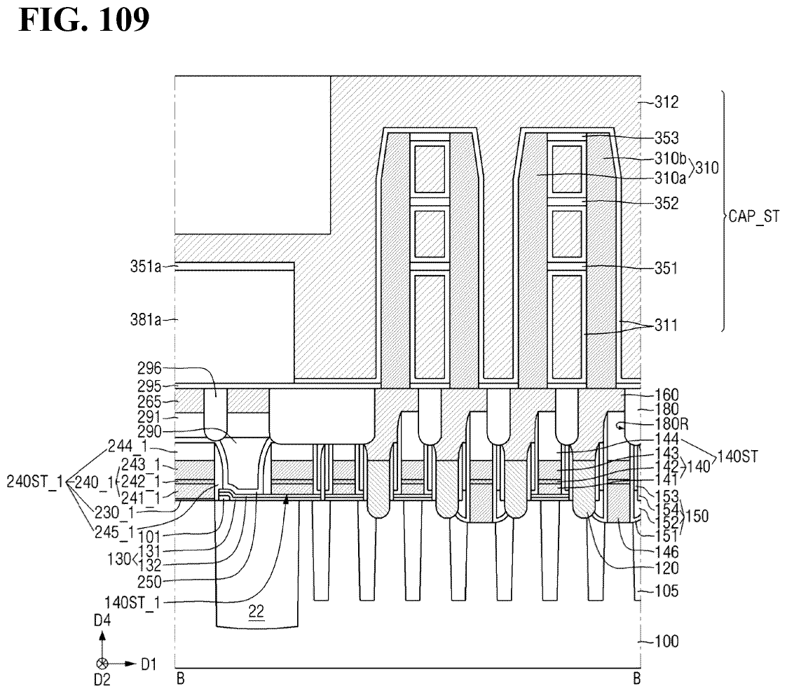

Referring to FIGS. 108 and 109, a capacitor dielectric layer 311 may be formed. The capacitor dielectric layer 311 may be formed on a pad isolation insulating layer 180, the storage pads 160, the lower electrodes 310, and the first through third support layers 351 through 353. The capacitor dielectric layer 311 may extend along upper surfaces of the pad isolation insulating layer 180 and the storage pads 160.

Next, an upper electrode 312 may be formed. In the peripheral area 24, the upper electrode 312 may be formed on the pre-lower insulating layer P351c on the intermediate insulating layer 391a. On the cell element isolation layer 22, the upper electrode 312 may be formed on the first pre-insulating layer P351a on the second interlayer insulating layer 381a.

The upper electrode 312 may be formed on the capacitor dielectric layer 311. The upper electrode 312 may extend between lower electrodes 310 that are not connected by the first through third support layers 351 through 353. For example, the upper electrode 312 may be made of silicon germanium (SiGe).

Through the above process, a capacitor structure CAP_ST may be formed.

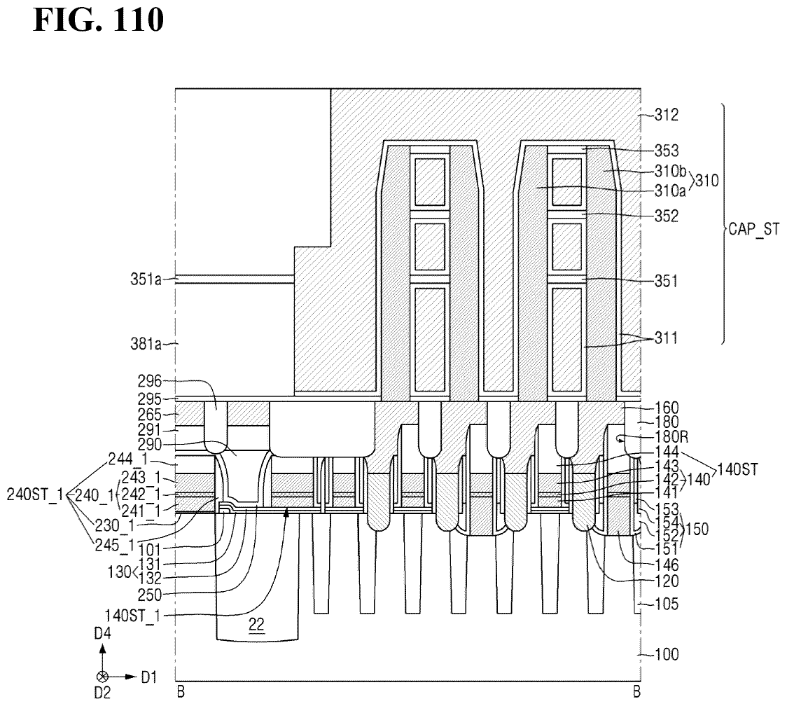

Referring to FIG. 110, the upper electrode 312 on the peripheral area 24 and the cell element isolation layer 22 may be removed.

Although not specifically illustrated, a mask may be formed on the capacitor structure CAP_ST on the cell area 20. The upper electrode 312 on the peripheral area 24 and the cell element isolation layer 22 on which the mask is not formed may be removed.

Next, referring also to FIGS. 12 and 13, a third interlayer insulating layer 481 may be formed on the first pre-insulating layer P351a. The third interlayer insulating layer 481 may be formed on the upper electrode 312. The third interlayer insulating layer 481 may cover the upper electrode 312.

The upper electrode 312 partially covering an upper surface of the first pre-insulating layer P351a may be removed. Accordingly, a sidewall of the second interlayer insulating layer 381a and a sidewall of a first insulating layer 351a may be aligned with a sidewall of the upper electrode 312.

A cell contact plug 410 connected to the upper electrode 312 may be formed on the cell area 20. A third peripheral contact plug 471 connected to the second peripheral wiring line 361 may be formed on the peripheral area 24.

While the present disclosure has been particularly illustrated and described with reference to example embodiments thereof, it will be understood by those of ordinary skill in the art that various changes in form and detail may be made therein without departing from the spirit and scope of the present disclosure. The example embodiments should be considered in a descriptive sense only and not for purposes of limitation.

What is claimed is:

1. A semiconductor memory device comprising:
a substrate which comprises a cell area, a peripheral area defined around the cell area, and a boundary area between the cell area and the peripheral area, wherein the cell area comprises an active area defined by an element isolation layer;
a storage pad connected to the active area in the cell area;
a capacitor which comprises a lower electrode connected to the storage pad, a first electrode support layer supporting the lower electrode, a capacitor dielectric layer extending along the lower electrode, and an upper electrode on the capacitor dielectric layer;
a peripheral gate on the peripheral area of the substrate;
first peripheral contact plugs on both sides of the peripheral gate, the first peripheral contact plugs being connected to the substrate;
a first interlayer insulating layer on the storage pad and the first peripheral contact plugs, a first peripheral wiring line being formed in the first interlayer insulating layer;
a second interlayer insulating layer on the first interlayer insulating layer, a second peripheral contact plug connected to the first peripheral wiring line being formed in the second interlayer insulating layer; and
a first insulating layer on the second interlayer insulating layer, a second peripheral wiring line being formed in the first insulating layer,
wherein the first insulating layer extends on the boundary area of the substrate such that a sidewall of the first insulating layer contacts the upper electrode, and a height of the first insulating layer is equal to or less than a height of the first electrode support layer.

2. The semiconductor memory device of claim 1, wherein a height of the second peripheral wiring line is equal to or less than the height of the first electrode support layer.

3. The semiconductor memory device of claim 1, further comprising an upper contact plug on the first insulating layer on the peripheral area, and the upper contact plug being connected to the second peripheral wiring line.

4. The semiconductor memory device of claim 3, wherein a lower surface of the upper contact plug is at the same height as an upper surface of the first electrode support layer.

5. The semiconductor memory device of claim 1, further comprising a barrier structure on the boundary area of the substrate.

6. The semiconductor memory device of claim 5, wherein the barrier structure comprises a metal.

7. The semiconductor memory device of claim 5, wherein the barrier structure comprises the same material as the first electrode support layer.

8. The semiconductor memory device of claim 1, wherein the first insulating layer on the peripheral area is at a lower height than the first electrode support layer, and the second peripheral wiring line is at a lower height than the first electrode support layer.

9. The semiconductor memory device of claim 8, wherein the first insulating layer on the peripheral area is at a lower height than the first insulating layer on the boundary area, and the first insulating layer on the peripheral area comprises a different material from the first insulating layer on the boundary area.

10. The semiconductor memory device of claim 1, wherein the first electrode support layer and the first insulating layer comprise carbonitride, the first interlayer insulating layer comprises nitride, and the second interlayer insulating layer comprises oxide.

11. A semiconductor memory device comprising:
a substrate which comprises a cell area, a peripheral area defined around the cell area, and a boundary area between the cell area and the peripheral area, wherein the cell area comprises an active area defined by an element isolation layer;
a storage pad connected to the active area in the cell area;
a capacitor which comprises a lower electrode connected to the storage pad, the lower electrode extending perpendicular to the substrate, and an electrode support structure supporting the lower electrode, wherein the electrode support structure comprises a first electrode support layer and a second electrode support layer on the first electrode support layer;
a peripheral gate on the peripheral area of the substrate;
first peripheral contact plugs on both sides of the peripheral gate, the first peripheral contact plugs being connected to the substrate;
a first interlayer insulating layer on the storage pad and the first peripheral contact plugs, a first peripheral wiring line being formed in the first interlayer insulating layer;
a second interlayer insulating layer on the first interlayer insulating layer, a second peripheral contact plug connected to the first peripheral wiring line being formed in the second interlayer insulating layer;
a first insulating layer on the second interlayer insulating layer, a second peripheral wiring line being formed in the first insulating layer; and
a third peripheral contact plug on the first insulating layer of the peripheral area, the third peripheral contact plug being connected to the second peripheral wiring line,
wherein a height of the first insulating layer on the boundary area is equal to or less than a height of the first electrode support layer, a height of the first insulating layer on the peripheral area is equal to or less than the height of the first insulating layer on the boundary area, and a lower surface of the third peripheral contact plug contacts an upper surface of the first insulating layer on the peripheral area.

12. The semiconductor memory device of claim 11, wherein the first electrode support layer, the first insulating layer on the boundary area, and the first insulating layer on the peripheral area are at the same height.

13. The semiconductor memory device of claim 11, wherein the second peripheral wiring line and the first electrode support layer are at the same height.

14. The semiconductor memory device of claim 11, wherein the lower surface of the third peripheral contact plug is at a lower height than the upper surface of the first insulating layer of the boundary area.

15. The semiconductor memory device of claim 11, wherein the capacitor further comprises:
a capacitor dielectric layer extending along a profile of the lower electrode and upper and lower surfaces of each of the first and second electrode support layers; and
an upper electrode disposed on the capacitor dielectric layer.

16. The semiconductor memory device of claim 15, further comprising a barrier structure between the upper electrode and the second interlayer insulating layer on the boundary area of the substrate, wherein the barrier structure comprises a metal.

17. The semiconductor memory device of claim 15, further comprising a barrier structure between the upper electrode and the second interlayer insulating layer on the boundary area of the substrate, wherein the barrier structure comprises the same material as the first insulating layer of the boundary area.

18. The semiconductor memory device of claim 17, wherein a width of the barrier structure in a horizontal direction is greater than a thickness of the first insulating layer on the boundary area in a vertical direction.

19. The semiconductor memory device of claim 11, further comprising:
a third interlayer insulating layer on the second interlayer insulating layer, the third peripheral contact plug being formed in the third interlayer insulating layer;
a second insulating layer on the third interlayer insulating layer, a third peripheral wiring line connected to the third peripheral contact plug being formed in the second insulating layer;
a fourth interlayer insulating layer on the second insulating layer, a fourth peripheral contact plug connected to the third peripheral wiring line being formed in the fourth interlayer insulating layer; and
a third insulating layer on the fourth interlayer insulating layer, a fourth peripheral wiring line connected to the fourth peripheral contact plug being formed in the third insulating layer,
wherein the electrode support structure further comprises a third electrode support layer on the second electrode support layer,
wherein the second electrode support layer, the second insulating layer of the boundary area and the second insulating layer of the peripheral area are at the same height, and
wherein the third electrode support layer, the third insulating layer of the boundary area and the third insulating layer of the peripheral area are at the same height.

20. A semiconductor memory device comprising:
a substrate which comprises a cell area and a peripheral area defined around the cell area, wherein the cell area comprises an active area defined by an element isolation layer;
a cell isolation layer in the substrate to define the cell area;
a bit line on the cell area of the substrate, the bit line comprising a cell conductive line and a cell line capping layer on the cell conductive line;
a cell gate electrode in the cell area of the substrate, the cell gate electrode crossing the cell conductive line;
a storage pad on a side surface of the bit line, the storage pad being connected to the active area in the cell area;
a capacitor which comprises a lower electrode connected to the storage pad, an electrode support layer supporting the lower electrode, a capacitor dielectric layer extending along a profile of the lower electrode and upper and lower surfaces of the electrode support layer, and an upper electrode on the capacitor dielectric layer;
a peripheral gate on the peripheral area of the substrate;
first peripheral contact plugs on both sides of the peripheral gate, the first peripheral contact plugs being connected to the substrate;
a first interlayer insulating layer on the storage pad and the first peripheral contact plugs, a first peripheral wiring line being formed in the first interlayer insulating layer;
a second interlayer insulating layer on the first interlayer insulating layer, a second peripheral contact plug connected to the first peripheral wiring line being formed in the second interlayer insulating layer; and
a first insulating layer on the second interlayer insulating layer, a second peripheral wiring line being formed in the first insulating layer,
wherein at least a portion of each of the second interlayer insulating layer and the first insulating layer extends on the cell isolation layer,
wherein the electrode support layer and the first insulating layer are at the same height, and
wherein each of the electrode support layer and the first insulating layer comprises carbonitride.
